(19) United States
(12) Patent Application Publication
(10) Pub. No.: US 2026/0215081 A1
(43) Pub. Date: Jul. 23, 2026

(54) LIGHT-EMITTING DEVICE

(71) Applicant: SEMICONDUCTOR ENERGY LABORATORY CO., LTD., Atsugi-shi, Kanagawa-ken (JP)

(72) Inventors: Nobuharu OHSAWA, Zama, Kanagawa (JP); Toshiki SASAKI, Kawasaki, Kanagawa (JP); Hiromi SEO, Sagamihara, Kanagawa (JP)

(21) Appl. No.: 19/140,835

(22) PCT Filed: Dec. 21, 2023
(86) PCT No.: PCT/IB2023/063064

§ 371 Date: Jun. 18, 2025

(30) Foreign Application Priority Data
Dec. 28, 2022 (JP) 2022-212568

(51) Int. Cl. H10K 50/15; H10K 50/16; H10K 101/30; H10K 101/40

(52) U.S. Cl. CPC H10K 50/15; H10K 50/16; H10K 2101/30; H10K 2101/40

(57) ABSTRACT

A light-emitting device with a high efficiency and high reliability is provided. The light-emitting device includes a light-emitting layer, a first layer, and a second layer between an anode and a cathode. Specifically, the light-emitting device includes the light-emitting layer between the anode and the first layer, and the second layer between the first layer and the cathode. In addition, the light-emitting layer contains alight-emitting substance. The first layer is a mixed layer containing a first organic compound and a second organic compound, the first organic compound has strong basicity with pKₐ greater than or equal to 8, and the second organic compound has an electron-transport property. A LUMO level of the first organic compound is higher than a LUMO level of the second organic compound. The second layer contains a first hole-transport organic compound and a first material having an acceptor property with respect to the first hole-transport organic compound.

### TECHNICAL FIELD

One embodiment of the present invention relates to an organic compound, a light-emitting device, a light-emitting apparatus, a light-emitting and light-receiving apparatus, a display apparatus, an electronic apparatus, a lighting device, and an electronic device. Note that one embodiment of the present invention is not limited to the above technical field. The technical field of one embodiment of the invention disclosed in this specification and the like relates to an object, a driving method, or a manufacturing method. Alternatively, one embodiment of the present invention relates to a process, a machine, manufacture, or a composition of matter. Specific examples of the technical field of one embodiment of the present invention disclosed in this specification include a semiconductor device, a display apparatus, a liquid crystal display device, a light-emitting apparatus, a lighting device, a power storage device, a memory device, an imaging device, a driving method thereof, and a manufacturing method thereof.

### BACKGROUND ART

Light-emitting devices (organic EL devices) including organic compounds and utilizing electroluminescence (EL) have been put to more practical use. In the basic structure of such light-emitting devices, an organic compound layer containing a light-emitting material (an EL layer) is held between a pair of electrodes. Carriers are injected by application of a voltage to the element, and light emission can be obtained from the light-emitting material by using the recombination energy of the carriers.

Such light-emitting devices are of self-light-emitting type and thus have advantages over liquid crystal, such as high visibility and no need for backlight when used in pixels of a display, and are suitable as flat panel display elements. Displays including such light-emitting devices are also highly advantageous in that they can be thin and lightweight. Another feature is an extremely fast response speed.

Since light-emitting layers of such light-emitting devices can be formed two-dimensionally and continuously, planar light emission can be obtained. This feature is difficult to realize with point light sources typified by incandescent lamps or LEDs or linear light sources typified by fluorescent lamps; thus, such light-emitting devices also have a great potential as planar light sources which can be applied to lighting and the like.

Such displays or lighting devices including light-emitting devices can be suitably used for a variety of electronic apparatuses. Therefore, research and development of light-emitting devices has been progressed for more favorable characteristics.

In a known method for manufacturing a high-resolution light-emitting device among a variety of known methods for manufacturing light-emitting devices, a light-emitting layer is formed without using a fine metal mask. An example is a method for manufacturing an organic EL display having a step of forming a first light-emitting layer as a continuous film across a display region including an electrode array by deposition of a first luminescent organic material containing a mixture of a host material and a dopant material over the electrode array that is formed over an insulating substrate and includes a first pixel electrode and a second pixel electrode; a step of irradiating part of the first light-emitting layer positioned over the second pixel electrode with ultraviolet light while part of the first light-emitting layer positioned over the first pixel electrode is not irradiated with ultraviolet light; a step of forming a second light-emitting layer as a continuous film across a display region by deposition of a second luminescent organic material that contains a mixture of a host material and a dopant material but differs from the first luminescent organic material, over the first light-emitting layer; and a step of forming a counter electrode over the second light-emitting layer (Patent Document 1).

In addition, as one of organic EL devices, Non-Patent Document 1 discloses a method for manufacturing an organic optoelectronic device using standard UV photolithography (Non-Patent Document 1).

### REFERENCE

### Patent Document

[Patent Document 1] Japanese Published Patent Application No. 2012-160473

### Non-Patent Document

[Non-Patent Document 1] B. Lamprecht et al., “Organic optoelectronic apparatus fabrication using standard UV photolithography”, phys. stat. sol. (RRL) 2, No. 1, pp. 16-18 (2008).

### SUMMARY OF THE INVENTION

### Problems to be Solved by the Invention

In general, an alkali metal with a low work function, such as lithium (Li), or a compound of such an alkali metal is used in an electron-injection layer of a light-emitting device. By using the alkali metal or a compound of the alkali metal, an excellent electron-injection property can be ensured. Interaction of the alkali metal or the compound of the alkali metal with an electron-transport material ensures charge-generation capability and enables electron injection to an electron-transport layer. In this manner, the use of the alkali metal or the compound of the alkali metal in the electron-injection layer lowers the voltage of the light-emitting device.

However, the alkali metal or the compound of the alkali metal is easily oxidized and is an unstable material. Thus, any reaction of the alkali metal or the compound of the alkali metal with, for example, an atmospheric component such as water or oxygen in the manufacturing process of the light-emitting device causes a problem such as a significant driving voltage increase or a significant emission efficiency decrease in the light-emitting device. For this reason, an organic EL device needs to be manufactured under a vacuum or in an atmosphere of an inert gas such as nitrogen.

In recent years, as a method for forming an organic compound layer in a predetermined shape, a vacuum evaporation method with a metal mask (mask vapor deposition) is widely used. However, in these days of higher density and higher resolution, mask vapor deposition has come close to the limit of increasing the resolution for various reasons such as the alignment accuracy and the distance between the mask and the substrate. Meanwhile, when a lithography method (e.g., an X-ray lithography method, an electron beam lithography method, a multiphoton lithography method, an interference lithography method, a nanoimprinting method, or the like) is used to process the shape of an organic compound film, a finer pattern can be formed. Moreover, because of the ease of large-area processing in this method, the processing of an organic compound film by a photolithography method is being researched.

In the case of manufacturing a light-emitting device by a lithography method, an EL layer included in the light-emitting device is exposed to the air, a resist resin, water, a chemical solution, or the like during a processing step. This step causes deterioration of an n-type layer that contains an alkali metal or a compound of the alkali metal and is included in an EL layer, resulting in significant deterioration of device characteristics. That is, the layer containing the alkali metal or the compound of the alkali metal in the EL layer subjected to the lithography process causes a significant increase in driving voltage and a significant decrease in emission efficiency.

An object of one embodiment of the present invention is to provide a novel light-emitting device. Another object of one embodiment of the present invention is to provide a light-emitting device with high efficiency. Another object of one embodiment of the present invention is to provide a light-emitting device with high reliability. Another object of one embodiment of the present invention is to provide a light-emitting device with high reliability and efficiency.

Another object of one embodiment of the present invention is to provide a novel organic compound that is highly convenient, useful, or reliable. Another object of one embodiment of the present invention is to provide a semiconductor device with high design flexibility. Another object of one embodiment of the present invention is to provide a light-emitting device with high design flexibility in a manufacturing process. An object of another embodiment of the present invention is to provide a light-emitting device with high reliability. Another object of one embodiment of the present invention is to provide a light-emitting device, a light-emitting apparatus, an electronic apparatus, a display apparatus, and an electronic device each having low power consumption. Another object of one embodiment of the present invention is to provide a light-emitting device, a light-emitting apparatus, an electronic apparatus, a display apparatus, and an electronic device each having low power consumption and high reliability.

Note that the objects of one embodiment of the present invention are not limited to the objects listed above. The objects listed above do not preclude the existence of other objects. Note that the other objects are objects that are not described in this section and are described below. The objects that are not described in this section are derived from the description of the specification, the drawings, and the like and can be extracted as appropriate from the description by those skilled in the art. Note that one embodiment of the present invention is to achieve at least one of the above objects and the other objects. Note that one embodiment of the present invention is to achieve at least one of the objects listed above and the other objects and does not necessarily achieve all of the objects listed above and the other objects.

### Means for Solving the Problems

(1)

One embodiment of the present invention is a light-emitting device including a light-emitting layer, a first layer, and a second layer between an anode and a cathode. Specifically, the light-emitting layer is provided between the anode and the first layer, and the second layer is provided between the first layer and the cathode. The light-emitting layer contains a light-emitting substance. The first layer is a mixed layer containing a first organic compound and a second organic compound, the first organic compound has strong basicity with pKₐ greater than or equal to 8, and the second organic compound has an electron-transport property. Note that a LUMO level of the first organic compound is higher than a LUMO level of the second organic compound. The second layer comprises a first hole-transport organic compound and a first material having an acceptor property with respect to the first hole-transport organic compound.

(2)

Another embodiment of the present invention is a light-emitting device including a light-emitting layer, a first layer, a second layer, and a third layer between an anode and a cathode. Specifically, the light-emitting layer is provided between the anode and the first layer, the second layer is provided between the first layer and the cathode, and the third layer is provided between the first layer and the second layer. The light-emitting layer contains a light-emitting substance. The first layer is a mixed layer comprising a first organic compound and a second organic compound, the first organic compound has strong basicity with pKₐ greater than or equal to 8, and the second organic compound has an electron-transport property. Note that a LUMO level of the first organic compound is higher than a LUMO level of the second organic compound. The second layer comprises a first hole-transport organic compound and a first material having an acceptor property with respect to the first hole-transport organic compound. The third layer comprises a material having a LUMO level higher than or equal to −4.30 eV and lower than or equal to −3.00 eV.

(3)

Another embodiment of the present invention according to above (1) or (2) may have a structure in which a HOMO level of the first organic compound is higher than a HOMO level of the second organic compound.

(4)

Another embodiment of the present invention according to above (1) or (2) may have a structure in which the second layer is a mixed layer of the first hole-transport organic compound and the first material.

(5)

Another embodiment of the present invention according to above (1) or (2) may have a structure in which the second layer is a stack of a layer comprising the first hole-transport organic compound and a layer comprising the first material.

(6)

Another embodiment of the present invention according to above (5) may have a structure in which the layer including the first hole-transport organic compound between the layer comprising the first material and the cathode.

(7)

Another embodiment of the present invention according to above (1) or (2) may have a structure in which the second layer and the cathode are in contact with each other.

(8)

Another embodiment of the present invention according to (1) or (2) may have a structure in which the second organic compound has a π-electron deficient heteroaromatic ring.

(9)

Another embodiment of the present invention according to above (1) or (2) may have a structure in which a fourth layer is provided between the anode and the light-emitting layer. In particular, the fourth layer contains a second hole-transport organic compound and a second material having an acceptor property with respect to the second hole-transport organic compound.

(10)

Another embodiment of the present invention according to above (1) or (2) may have a structure in which the first organic compound has a higher LUMO level than the second organic compound by 0.05 eV or more.

(11)

Another embodiment of the present invention according to above (1) or (2) may have a structure in which the first organic compound has a higher LUMO level than the second organic compound by 0.05 eV or more, and the first organic compound has a higher HOMO level than the second organic compound by 0.05 eV or more.

(12)

Another embodiment of the present invention according to above (1) or (2) may have a structure in which the LUMO level of the first organic compound is higher than or equal to −2.50 eV and lower than or equal to −1.00 eV.

(13)

Another embodiment of the present invention according to above (1) or (2) may have a structure in which the LUMO level of the first organic compound is higher than or equal to −2.50 eV and lower than or equal to −1.00 eV and a HOMO level of the first organic compound is higher than or equal to −5.7 eV and lower than or equal to −4.8 eV.

(14)

Another embodiment of the present invention according to above (1) or (2) may have a structure in which the LUMO level of the first organic compound is higher than or equal to −2.50 eV and lower than or equal to −1.00 eV, and the LUMO level of the second organic compound is higher than or equal to −3.25 eV and lower than or equal to −2.50 eV.

(15)

Another embodiment of the present invention according to above (1) or (2) may have a structure in which the LUMO level of the first organic compound is higher than or equal to −2.50 eV and lower than or equal to −1.00 eV, the LUMO level of the second organic compound is higher than or equal to −3.25 eV and lower than or equal to −2.50 eV, a HOMO level of the first organic compound is higher than or equal to −5.7 eV and lower than or equal to −4.8 eV, and a HOMO level of the second organic compound is higher than or equal to −6.5 eV and lower than or equal to −5.7 eV.

(16)

Another embodiment of the present invention according to above (1) or (2) may have a structure in which the second organic compound is a material having basicity with an acid dissociation constant pKₐ greater than or equal to 4 and less than or equal to 8.

(17)

Another embodiment of the present invention according to (1) or (2) may have a structure in which the first organic compound does not have an electron-donating property with respect to the second organic compound.

(18)

Another embodiment of the present invention according to (1) or (2) may have a structure in which a mixed layer comprising the first organic compound and the second organic compound has spin density lower than or equal to 1×10¹⁷ spins/cm³ measured by an electron spin resonance method.

### Effect of the Invention

One embodiment of the present invention can provide a novel light-emitting device. Another embodiment of the present invention can provide a light-emitting device with high efficiency. Another embodiment of the present invention can provide a light-emitting device with high reliability. Another embodiment of the present invention can provide a light-emitting device with high reliability and efficiency.

According to one embodiment of the present invention, a novel organic compound that is highly convenient, useful, or reliable can be provided. According to another embodiment of the present invention, a semiconductor device with high design flexibility can be provided. According to another embodiment of the present invention, a light-emitting device with high design flexibility in a manufacturing process. According to another embodiment of the present invention, a light-emitting device with high reliability can be provided. According to another embodiment of the present invention, a light-emitting device, a light-emitting apparatus, an electronic apparatus, a display apparatus, and an electronic device each having low power consumption can be provided. According to another embodiment of the present invention, a light-emitting device, a light-emitting apparatus, an electronic apparatus, a display apparatus, an electronic device, and a lighting device each having low power consumption and high reliability.

Note that the effects of one embodiment of the present invention are not limited to the effects listed above. The effects listed above do not preclude the existence of other effects. The other effects are effects that are not described in this section and will be described below. The effects that are not described in this section can be derived from the description of the specification, the drawings, and the like and can be extracted as appropriate from the description by those skilled in the art. One embodiment of the present invention has at least one of the effects listed above and the other effects. Accordingly, one embodiment of the present invention does not have all effects listed above in some cases.

### BRIEF DESCRIPTION OF THE DRAWINGS

FIG. 1A to FIG. 1D are diagrams illustrating structure examples of light-emitting devices.

FIG. 2A and FIG. 2B are band diagrams illustrating a driving mechanism of a light-emitting device of the present invention.

FIG. 3A to FIG. 3C are diagrams illustrating structure examples of light-emitting devices.

FIG. 4A and FIG. 4B are diagrams illustrating structure examples of light-emitting devices.

FIG. 5A and FIG. 5B are a top view and a cross-sectional view of a structure example of a light-emitting apparatus.

FIG. 6 is a cross-sectional view of a structure example of a light-emitting apparatus.

FIG. 7A to FIG. 7D are cross-sectional views illustrating structure examples of a light-emitting device.

FIG. 8A to FIG. 8E are cross-sectional views illustrating an example of a method for manufacturing a light-emitting apparatus.

FIG. 9A to FIG. 9E are cross-sectional views illustrating an example of a method for manufacturing a light-emitting apparatus.

FIG. 10A to FIG. 10C are cross-sectional views illustrating an example of a method for manufacturing a light-emitting apparatus.

FIG. 11A to FIG. 11C are cross-sectional views illustrating an example of a method for manufacturing a light-emitting apparatus.

FIG. 12A to FIG. 12C are cross-sectional views illustrating an example of a method for manufacturing a light-emitting apparatus.

FIG. 13A to FIG. 13C are cross-sectional views illustrating an example of a method for manufacturing a light-emitting apparatus.

FIG. 14A to FIG. 14C are cross-sectional views illustrating an example of a method for manufacturing a light-emitting apparatus.

FIG. 15A to FIG. 15G are top views illustrating structure examples of pixels.

FIG. 16A to FIG. 16I are top views illustrating structure examples of a pixel.

FIG. 17A and FIG. 17B are perspective views illustrating a structure example of a display module.

FIG. 18A and FIG. 18B are cross sectional views illustrating structure examples of a light-emitting apparatus.

FIG. 19 is a perspective view illustrating a structure example of a light-emitting apparatus.

FIG. 20A is a cross-sectional view illustrating a structure example of a light-emitting apparatus.

FIG. 20B and FIG. 20C are cross-sectional views illustrating structure examples of transistors.

FIG. 21 is a cross-sectional view illustrating a structure example of a light-emitting apparatus.

FIG. 22A to FIG. 22D are cross sectional views illustrating structure examples of a light-emitting apparatus.

FIG. 23A to FIG. 23D are diagrams illustrating examples of electronic apparatuses.

FIG. 24A to FIG. 24F are diagrams illustrating examples of electronic apparatuses.

FIG. 25A to FIG. 25D are diagrams illustrating examples of electronic apparatuses.

FIG. 26A to FIG. 26G are diagrams illustrating examples of an electronic apparatuses.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. Furthermore, the same hatch pattern is used for the portions having similar functions, and the portions are not especially denoted by reference numerals in some cases.

The position, size, range, and the like of each component illustrated in drawings do not represent the actual position, size, range, and the like in some cases for easy understanding. Thus, the disclosed invention is not necessarily limited to the position, size, range, and the like disclosed in the drawings.

In this specification and the like, a light-emitting device (also referred to as a light-emitting element) includes an EL layer between a pair of electrodes. The EL layer includes at least a light-emitting layer. In this specification and the like, a light-receiving device (also referred to as a light-receiving element) includes at least an active layer functioning as a photoelectric conversion layer between a pair of electrodes. In this specification and the like, one of the pair of electrodes may be referred to as a pixel electrode and the other may be referred to as a common electrode.

Note that the light-emitting apparatus in this specification includes, in its category, an image display device that uses an organic EL device. The light-emitting apparatus may also include a module in which an organic EL device is provided with a connector (e.g., an anisotropic conductive film or a TCP (tape carrier package)), a module in which a printed wiring board is provided at the end of a TCP, and a module in which an IC (integrated circuit) is directly mounted on an organic EL device by a COG (chip on glass) method. Furthermore, a lighting device or the like may include the light-emitting apparatus.

### Embodiment 1

A light-emitting device includes an organic compound layer containing a light-emitting substance between electrodes (between an anode and a cathode), and energy generated by recombination of carriers (holes and electrons) injected to the organic compound layer from the electrodes causes light emission.

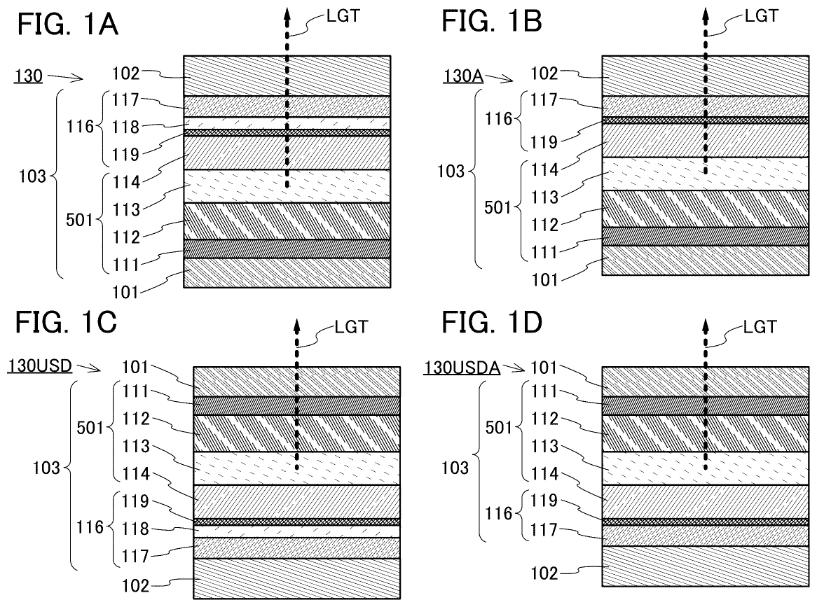

FIG. 1A illustrates a light-emitting device 130 of one embodiment of the present invention. The light-emitting device 130 includes an anode 101 and a cathode 102. The light-emitting device 130 includes an organic compound layer 103 between the anode 101 and the cathode 102. The organic compound layer 103 includes a light-emitting unit 501 including a light-emitting layer 113 and a layer 116. Specifically, the layer 116 includes an electron-injection buffer region 119 (hereinafter referred to as a first layer in some cases), an electron-relay region 118 (hereinafter referred to as a third layer or an electron-relay layer in some cases), and a charge-generation region 117 (hereinafter referred to as a second layer or a P-type layer in some cases). In particular, the electron-injection buffer region 119 is positioned between the light-emitting layer 113 and the electron-relay region 118, the electron-relay region 118 is positioned between the electron-injection buffer region 119 and the charge-generation region 117, and the charge-generation region 117 is positioned between the electron-relay region 118 and the cathode 102. The charge-generation region 117 is preferably in contact with the cathode 102. Note that the term “light-emitting unit” is sometimes replaced with the term “EL layer”.

In particular, the electron-relay region 118 is a functional layer for smooth donation and acceptance of electrons between the electron-injection buffer region 119 and the charge-generation region 117.

There is no particular limitation on the color gamut of light emitted from the light-emitting layer in the light-emitting unit 501. In addition, the light-emitting layer may have a single-layer structure or a stacked-layer structure. For example, the light-emitting unit 501 may have a stacked-layer structure including a light-emitting layer emitting light in a red region, a light-emitting layer emitting light in a green region, and a light-emitting layer emitting light in a blue region. With this structure, white light emission can be obtained from the light-emitting unit 501.

FIG. 1A schematically illustrates the light-emitting device 130 where light LGT generated in the light-emitting layer 113 is emitted to above the light-emitting device 130 through the cathode 102 as one example. In that case, when a transparent electrode is used as the cathode 102, the transparent electrode preferably has a visible light (e.g., light with a wavelength greater than or equal to 400 nm and less than 750 nm) transmittance higher than or equal to 40%. In the case where a transflective electrode is used as the cathode 102, the reflectance of the transflective electrode is preferably higher than or equal to 10% and lower than or equal to 95%, further preferably higher than or equal to 30% and lower than or equal to 80%. Note that the light-emitting device 130 may emit light not only to above the light-emitting device 130 through the cathode 102 but also to below the light-emitting device through the anode 101 (not illustrated). Note that the light-emitting device can be provided in a dual-emission display apparatus, for example.

In a display apparatus including a pixel circuit provided over a substrate and the light-emitting device 130 included in the pixel circuit, a structure in which light generated in the light-emitting layer 113 of the light-emitting device 130 is emitted without passing through the substrate is sometimes referred to as atop-emission display apparatus. A structure in which light generated in the light-emitting layer 113 of the light-emitting device 130 is emitted through the substrate is sometimes referred to as a bottom-emission display device.

Here, it is preferable that at least the electron-injection buffer region 119 include a mixed layer containing at least two kinds of organic compounds: a first organic compound having strong basicity (preferably having an acid dissociation constant pKₐ greater than or equal to 8) and a second organic compound the lowest unoccupied molecular orbital level (LUMO level) of which is lower than that of the first organic compound. That is, the LUMO level of the first organic compound having strong basicity is preferably higher than the LUMO level of the second organic compound. This structure can inhibit occurrence of the problems due to an alkali metal or a compound of the alkali metal, which has been conventionally used.

In the light-emitting device of one embodiment of the present invention, when an organic compound having a strong basicity with a large acid dissociation constant pKₐ (preferably, pKₐ greater than or equal to 8) is used for the layer 116, holes injected from the anode 101 side pass through the light-emitting unit 501 and are trapped or blocked by the organic compound having strong basicity and then, electrons are injected from the charge-generation region 117 toward the electron-injection buffer region 119, whereby the light-emitting device is driven.

Note that the organic compound having strong basicity blocks holes because a large pKₐ material has a large dipole moment. When this dipole moment interacts with holes, the electron-injection buffer region 119 can block holes.

An organic compound having strong basicity has high nucleophilicity. That is, a highly nucleophilic material may react with a molecule that has become a cation radical by receiving a hole, in which case a new molecule or an intermediate state may be generated. This reaction consumes holes and reduces the hole-transport property of the electron-injection buffer region 119 in some cases.

It is preferable that the above organic compound having strong basicity not have a skeleton having an electron-transport property. When the above organic compound having strong basicity does not have a skeleton having an electron-transport property, recombination of electrons injected to the electron-injection buffer region 119 and holes trapped by the organic compound having strong basicity can be inhibited; thus, electrons can be efficiently injected to the light-emitting unit 501.

When holes and electrons are injected to the highest occupied molecular orbital level (HOMO level) and LUMO level of the organic compound having strong basicity, carriers are recombined in the electron-injection buffer region 119 and an unstable excided state is easily formed, so that the reliability is lowered and the characteristics of the light-emitting device are decreased.

In view of the above, when the second organic compound having electron transport property is mixed to the electron-injection buffer region 119 which includes the first organic compound having strong basicity, the first organic compound's function of trapping or blocking holes and the second organic compound's function of making electrons flow can be separated; accordingly, recombination probability of carriers in the electron-injection buffer region 119 can be reduced and formation of an unstable excited state can be inhibited, leading to improving reliability of the organic compound. In other words, when the mixed layer (the electron-injection buffer region 119) that is included in the layer 116 contains the first organic compound for trapping holes and the second organic compound for transporting electrons, formation of an unstable excited state can be inhibited and the reliability of the light-emitting device can be improved.

Thus, the second organic compound having an electron-transport property preferably has a lower LUMO level than the first organic compound having strong basicity. The second organic compound having an electron-transport property preferably has a lower HOMO level than the first organic compound having strong basicity.

Note that a larger thickness of the electron-injection buffer region 119 causes accumulated holes to be more distant from electrons attracted from the charge-generation region 117 in the electron-injection buffer region 119, whereby the electric field of an electric double layer may be relieved and the voltage of the manufactured light-emitting device may be increased. Thus, the electron-injection buffer region 119 is preferably provided to have a thickness greater than or equal to 2 nm and less than or equal to 13 nm, further preferably greater than or equal to 5 nm and less than or equal to 10 nm.

As the first organic compound, an organic compound having a LUMO level higher than that of the second organic compound by greater than or equal to 0.05 eV is preferably used. Alternatively, the first organic compound is preferably an organic compound having a LUMO level higher than that of the second organic compound by, preferably greater than or equal to 0.1 eV, further preferably greater than or equal to 0.2 eV. Such a LUMO level difference between the first organic compound and the second organic compound enables reduction of the probability that the first organic compound accepts electrons owing to energy of room temperature, the influence of an electric field, or the like can be reduced.

In addition, as the first organic compound, an organic compound having a HOMO level higher than that of the second organic compound by greater than or equal to 0.05 eV is preferably used. Alternatively, the first organic compound is preferably an organic compound having a HOMO level higher than that of the second organic compound by, preferably, greater than or equal to 0.1 eV, further preferably, greater than or equal to 0.2 eV. Such a HOMO level difference between the first organic compound and the second organic compound enables reduction of the probability that the second organic compound accepts holes owing to energy of room temperature, the influence of an electric field, or the like can be reduced.

### <First Organic Compound>

The LUMO level of the first organic compound is preferably greater than or equal to −2.50 eV and less than or equal to −1.00 eV. The HOMO level of the first organic compound is preferably greater than or equal to −5.7 eV and less than or equal to −4.8 eV.

It is preferable that the first organic compound not have a skeleton having an electron-transport property. The first organic is, for example, an organic compound whose aromatic ring contains no nitrogen atom (N).

The first organic compound is preferably an organic compound having strong basicity with an acid dissociation constant pKₐ greater than or equal to 8. By including the organic compound having strong basicity with an acid dissociation constant pKₐ greater than or equal to 8, the first organic compound can block holes and accumulate holes at a first electron-transport layer.

The first organic compound is preferably an organic compound with an acid dissociation constant pKₐ greater than or equal to 8, further preferably greater than 10. The acid dissociation constant pKₐ of the first organic compound is still further preferably greater than or equal to 12, yet still further preferably greater than 13.

As the acid dissociation constant pKₐ of a basic skeleton, the acid dissociation constant value of the organic compound formed by substituting hydrogen for part of the skeleton can be used. As an indicator of acidity of an organic compound having a basic skeleton, the acid dissociation constant pKₐ of the basic skeleton can be used. In the case of an organic compound having a plurality of basic skeletons, the acid dissociation constant pKₐ of the basic skeleton having the highest acid dissociation constant pKₐ can be used as the acidity indicator for the organic compound.

Alternatively, the acid dissociation constant pKₐ of an organic compound may be calculated in the following manner.

First, the initial structure of a molecule serving as a calculation model is the most stable structure (a singlet ground state) obtained from first-principles calculation.

For the first-principles calculation, Jaguar, which is the quantum chemical computational software produced by Schrödinger, Inc., is used, and the most stable structure in the singlet ground state is calculated by the density functional theory (DFT). As a basis function, 6-31G** is used, and as a functional, B3LYP-D3 is used. The structure subjected to quantum chemical calculation is sampled by conformational analysis in Mixed torsional/Low-mode sampling with Maestro GUI produced by Schrödinger, Inc.

In the calculation of pKₐ, one or more atoms in each molecule are designated as basic sites, Macro Model is used to search for the stable structure of the protonated molecule in water, conformational search is performed with OPLS2005 force field, and a conformational isomer having the lowest energy is used. Jaguar's pKₐ calculation module is used. After structure optimization is performed by B3LYP/6-31G*, single point calculation is performed by cc-pVTZ(+) and the pKₐ value is calculated using empirical correction for functional group(s). In the case where one or more atoms are designated as basic sites in a molecule, the largest of obtained values is used as a pKₐ value.

As specific examples of the organic compound which has a high acid dissociation constant pKₐ and can be used as the first organic compound, organic compounds having basic skeletons represented by Structural Formulae (120) to (123) below can be given.

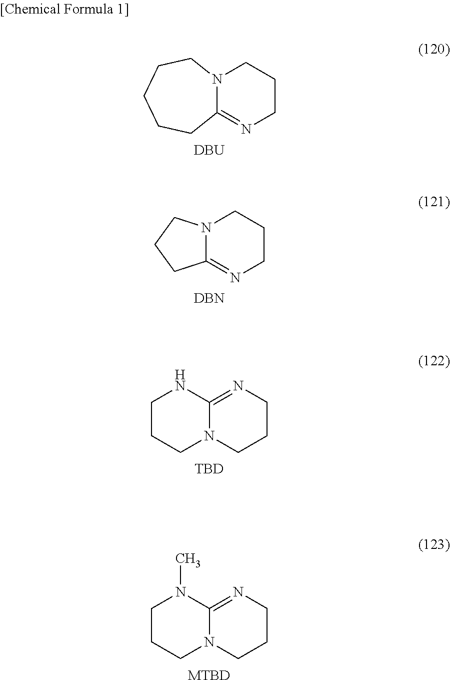

It is preferable that the first organic compound be specifically an organic compound that includes a bicyclo ring structure having 2 or more nitrogen atoms in the bicyclo ring and a heteroaromatic hydrocarbon ring having 2 to 30 carbon atoms in the ring or an aromatic hydrocarbon ring having 6 to 30 carbon atoms in the ring, and more specifically be an organic compound that includes a 1,3,4,6,7,8-hexahydro-2H-pyrimido[1,2-a]pyrimidine skeleton and a heteroaromatic hydrocarbon ring having 2 to 30 carbon atoms in the ring or an aromatic hydrocarbon ring having 6 to 30 carbon atoms in the ring. An organic compound that includes a bicyclo ring structure having 2 or more nitrogen atoms in the bicyclo ring and a heteroaromatic hydrocarbon ring having 2 to 30 carbon atoms in the ring, more specifically an organic compound that includes a 1,3,4,6,7,8-hexahydro-2H-pyrimido[1,2-a]pyrimidine skeleton and a heteroaromatic hydrocarbon ring having 2 to 30 carbon atoms in the ring is further preferable. Alternatively, an organic compound having a guanidine skeleton is preferably used.

Further specifically, the first organic compound is preferably an organic compound represented by General Formula (G1) below.

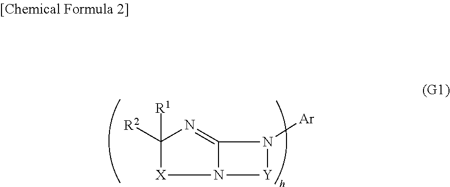

In the organic compound represented by General Formula (G1) above, X represents a group represented by General Formula (G1-1) below, and Y represents a group represented by General Formula (G1-2) below. Furthermore, R¹ and R² each independently represent hydrogen or deuterium, h represents an integer of 1 to 6, and Ar represents a substituted or unsubstituted heteroaromatic hydrocarbon ring having 2 to 30 carbon atoms in the ring or a substituted or unsubstituted aromatic hydrocarbon ring having 6 to 30 carbon atoms in the ring. Ar is preferably the substituted or unsubstituted heteroaromatic hydrocarbon ring having 2 to 30 carbon atoms in the ring.

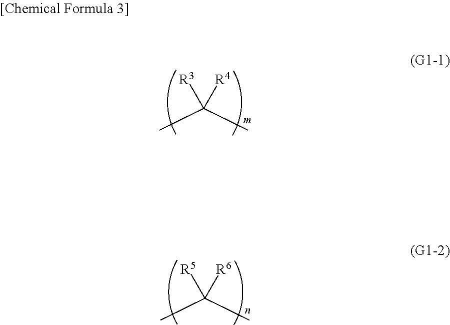

In General Formulae (G1-1) and (G1-2) above, R³ to R⁶ each independently represent hydrogen or deuterium, m represents an integer of 0 to 4, n represents an integer of 1 to 5, and m+1≥n is satisfied. In the case where m or n is 2 or more, R³s to R⁶s may be the same as or different from each other. In the case where m is 0, carbon (C) and nitrogen (N) are preferably bonded to each other in General Formula (G1) above.

The organic compound represented by General Formula (G1) above is preferably any one of compounds represented by General Formulae (G2-1) to (G2-6) below.

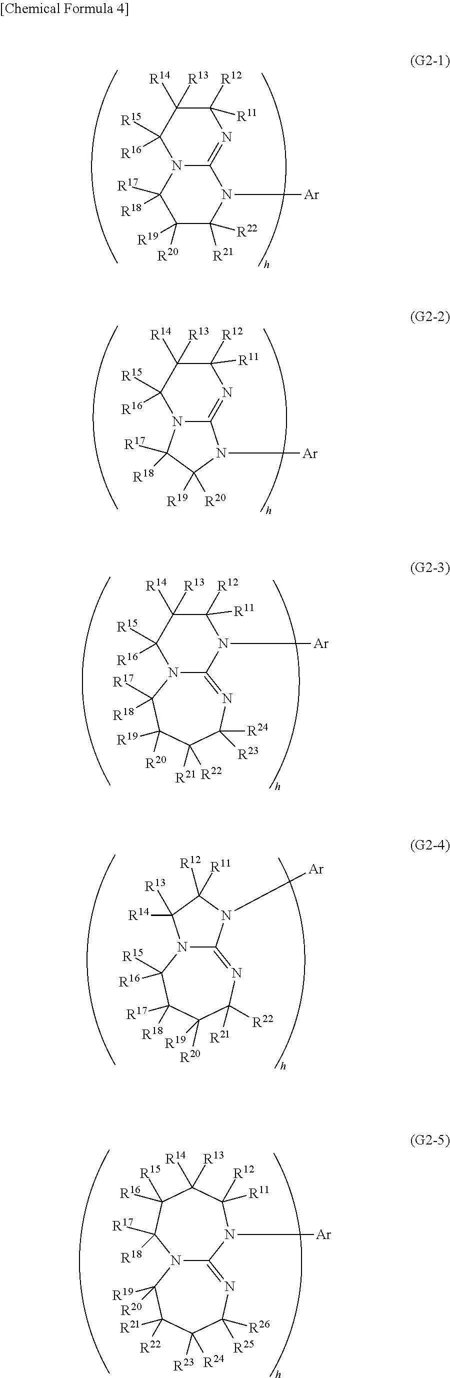

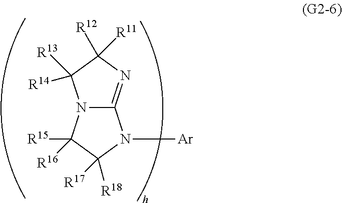

In the organic compounds, R¹¹ to R²⁶ each independently represent hydrogen or deuterium, h represents an integer of 1 to 6, and Ar represents a substituted or unsubstituted heteroaromatic hydrocarbon ring having 2 to 30 carbon atoms in the ring or a substituted or unsubstituted aromatic hydrocarbon ring having 6 to 30 carbon atoms in the ring. Ar is preferably the substituted or unsubstituted heteroaromatic hydrocarbon ring having 2 to 30 carbon atoms in the ring.

In General Formula (G1) and General Formulae (G2-1) to (G2-6) above, the substituted or unsubstituted heteroaromatic hydrocarbon ring having 2 to 30 carbon atoms in the ring or the substituted or unsubstituted aromatic hydrocarbon ring having 6 to 30 carbon atoms in the ring that is represented by Ar is specifically a pyridine ring, a bipyridine ring, a pyrimidine ring, a bipyrimidine ring, a pyrazine ring, a bipyrazine ring, a triazine ring, a quinoline ring, an isoquinoline ring, a benzoquinoline ring, a phenanthroline ring, a quinoxaline ring, a benzoquinoxaline ring, a dibenzoquinoxaline ring, an azafluorene ring, a diazafluorene ring, a carbazole ring, a benzocarbazole ring, a dibenzocarbazole ring, a dibenzofuran ring, a benzonaphthofuran ring, a dinaphthofuran ring, a dibenzothiophene ring, a benzonaphthothiophene ring, a dinaphthothiophene ring, a benzofuropyridine ring, a benzofuropyrimidine ring, a benzothiopyridine ring, a benzothiopyrimidine ring, a naphthofuropyridine ring, a naphthofuropyrimidine ring, a naphthothiopyridine ring, a naphthothiopyrimidine ring, a dibenzoquinoxaline ring, an acridine ring, a xanthene ring, a phenothiazine ring, a phenoxazine ring, a phenazine ring, a triazole ring, an oxazole ring, an oxadiazole ring, a thiazole ring, a thiadiazole ring, an imidazole ring, a benzimidazole ring, a pyrazole ring, a pyrrole ring, or the like. In General Formula (G1) and General Formulae (G2-1) to (G2-6) above, the substituted or unsubstituted heteroaromatic hydrocarbon ring having 6 to 30 carbon atoms in the ring that is represented by Ar is specifically a benzene ring, a naphthalene ring, a fluorene ring, a dimethylfluorene ring, a diphenylfluorene ring, a spirofluorene ring, an anthracene ring, a phenanthrene ring, a triphenylene ring, a pyrene ring, a tetracene ring, a chrysene ring, a benzo[a]anthracene ring, or the like. Ar is especially preferably the ring represented by any one of Structural Formulae (Ar-1) to (Ar-27) below.

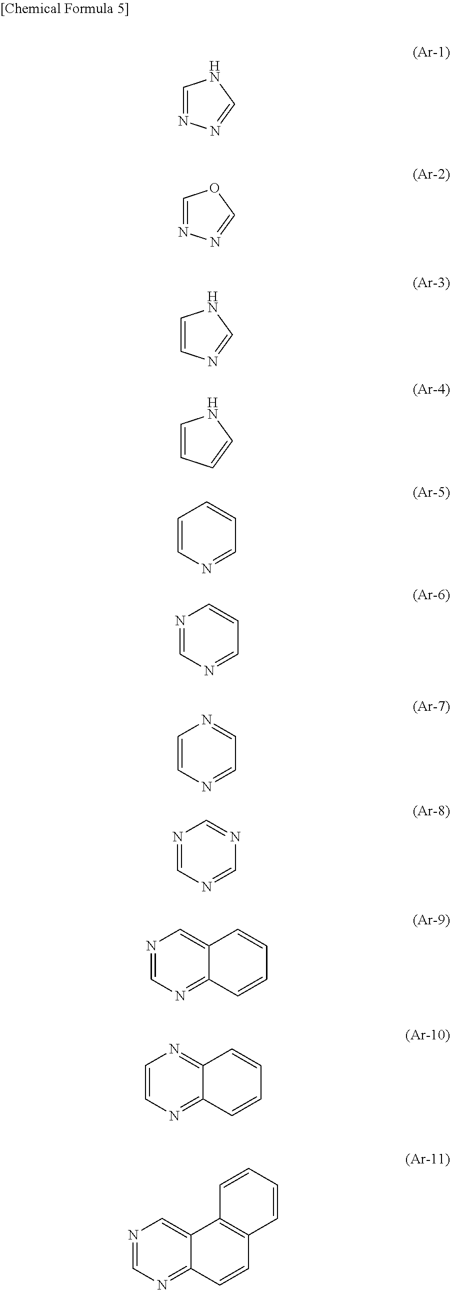

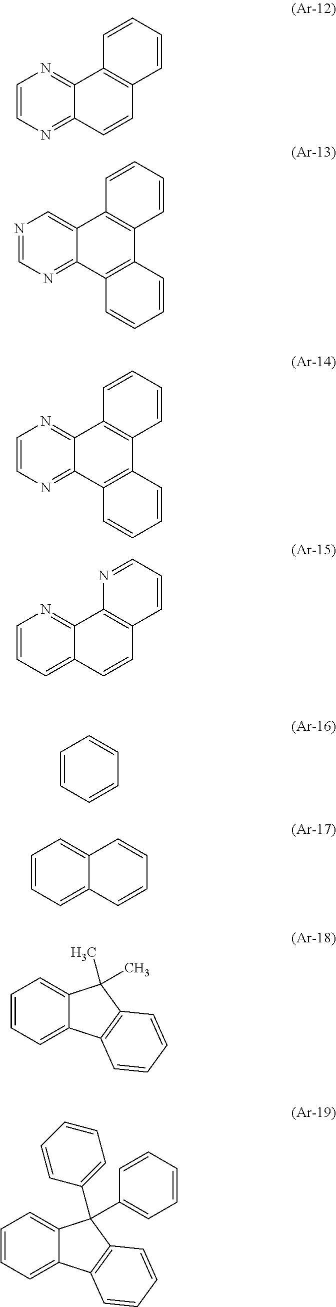

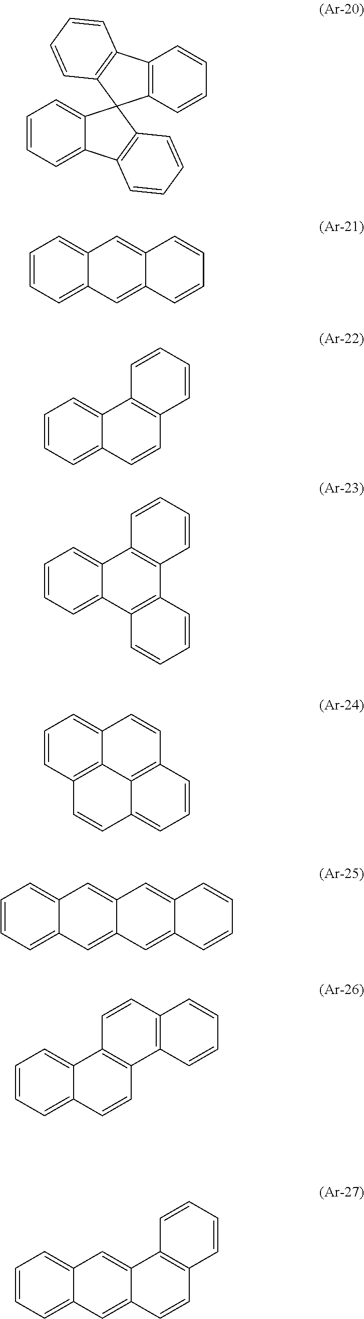

Note that Ar preferably has a nitrogen atom in its ring and is preferably bonded to the skeleton within parentheses in General Formula (G1) above by a bond of the nitrogen atom or a carbon atom adjacent to the nitrogen atom.

As specific examples of the organic metal compounds represented by General Formula (G1) and General Formulae (G2-1) to (G2-6) above, organic compounds represented by Structural Formulae (101) to (117) below, such as 1,1′-(9,9′-spirobi[9H-fluorene]-2,7-diyl)bis(1,3,4,6,7,8-hexahydro-2H-pyrimido[1,2-a]pyrimidine) (abbreviation: 2,7hpp2SF) (Structural Formula 108) and 1-(9,9′-spirobi[9H-fluoren]-2-yl)-1,3,4,6,7,8-hexahydro-2H-pyrimido[1,2-a]pyrimidine (abbreviation: 2hppSF) (Structural Formula 109) can be given.

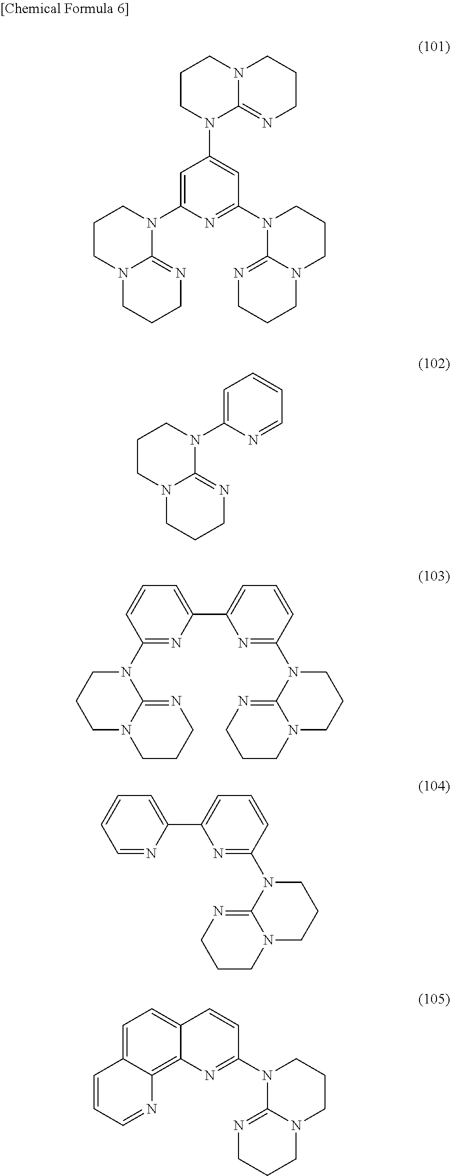

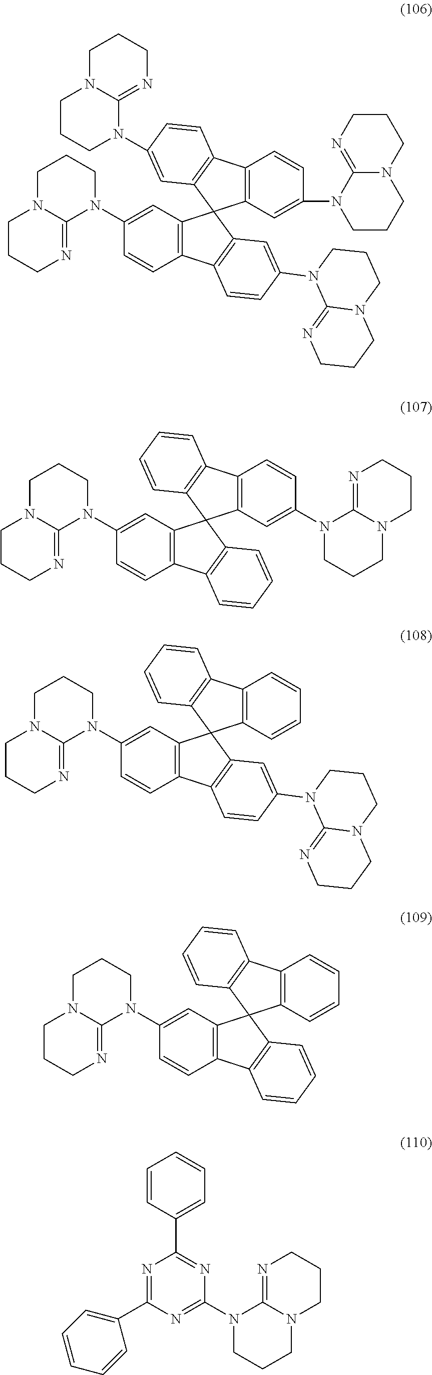 [SMILES: c1cc2c(cc1N1CCCN3CCCN=C31)C1(c3cc(N4CCCN5CCCN=C54)ccc3-2)c2cc(N3CCCN4CCCN=C43)ccc2-c2ccc(N3CCCN4CCCN=C43)cc21 ; c1ccc2c(c1)-c1ccc(N3CCCN4CCCN=C43)cc1C21c2ccccc2-c2ccc(N3CCCN4CCCN=C43)cc21 ; c1ccc2c(c1)-c1ccccc1C21c2cc(N3CCCN4CCCN=C43)ccc2-c2ccc(N3CCCN4CCCN=C43)cc21 ; c1ccc2c(c1)-c1ccccc1C21c2ccccc2-c2ccc(N3CCCN4CCCN=C43)cc21 ; c1ccc(-c2nc(-c3ccccc3)nc(N3CCCN4CCCN=C43)n2)cc1]

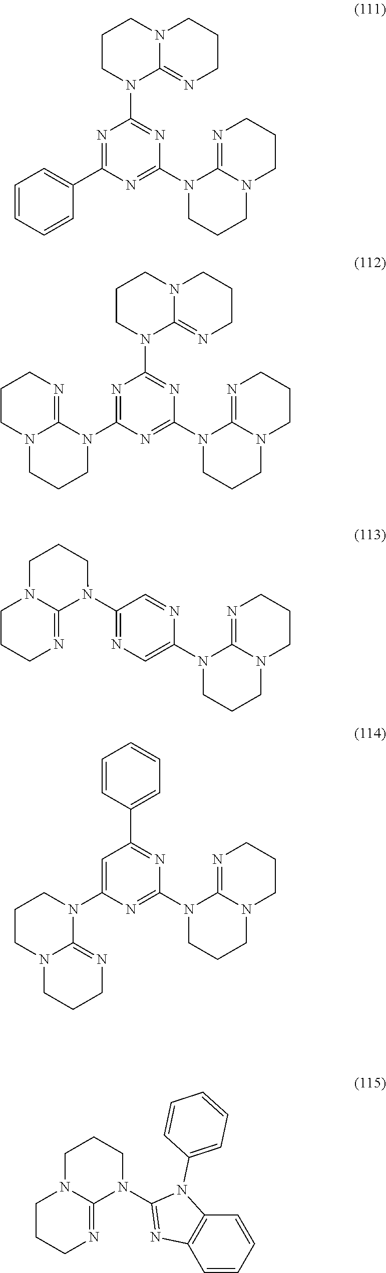

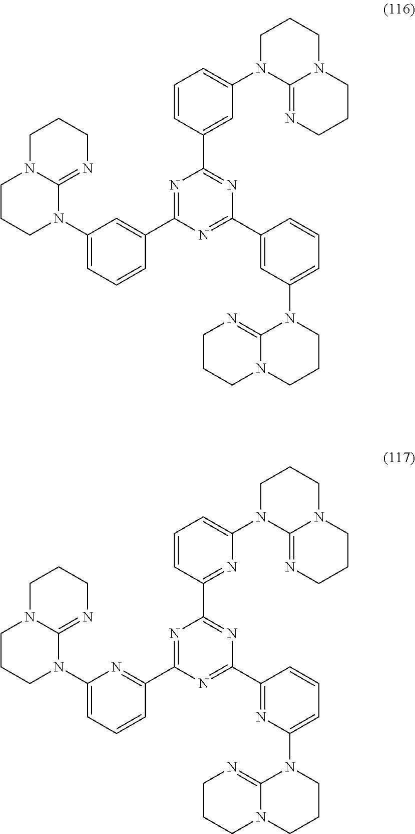 [SMILES: c1cc(-c2nc(-c3cccc(N4CCCN5CCCN=C54)c3)nc(-c3cccc(N4CCCN5CCCN=C54)c3)n2)cc(N2CCCN3CCCN=C32)c1 ; c1cc(-c2nc(-c3cccc(N4CCCN5CCCN=C54)n3)nc(-c3cccc(N4CCCN5CCCN=C54)n3)n2)nc(N2CCCN3CCCN=C32)c1]

It is preferable that the substance having strong basicity with pKₐ greater than or equal to 8 not have a skeleton having an electron-transport property so that injected electrons and blocked holes can be inhibited from recombining on the substance having strongly basicity with pKₐ greater than or equal to 8. As the substance having strong basicity with pKₐ greater than or equal to 8, an organic compound such as 1-(9,9′-spirobi[9H-fluoren]-2-yl)-1,3,4,6,7,8-hexahydro-2H-pyrimido[1,2-a]pyrimidine (abbreviation: 2hppSF), 2,9-bis(1,3,4,6,7,8-hexahydro-2H-pyrimido[1,2-a]pyrimidin-1-yl)-1,10-phenanthroline (abbreviation: 2,9hpp2Phen), 4,7-di-1-pyrrolidinyl-1,10-phenanthroline (abbreviation: Pyrrd-Phen), or 8,8′-pyridine-2,6-diyl-bis(5,6,7,8-tetrahydroimidazo[1,2-a]pyrimidine) (abbreviation: 2,6tip2Py) can be specifically used, for example.

In the case where the light-emitting device is manufactured by a process involving exposure to the air, a washing step using an aqueous solution, or the like, the first organic compound preferably has low solubility. For example, the solubility of the first organic compound is affected by the number of hydrophilic groups such as 2H-pyrimido[1,2-a]pyrimidine groups (hpp groups) and the number of hydrophobic groups such as tert-butyl groups in the first organic compound. It is thus preferable that the number of hydrophilic groups in the first organic compound be smaller and be specifically 1. It is preferable that in the first organic compound, the number of hydrophobic groups be larger than that of hydrophilic groups and be specifically 2 or more.

Specifically, the solubility of the first organic compound in water is preferably lower than 0.77 mg/ml, further preferably lower than or equal to 0.065 mg/ml, still further preferably lower than or equal to 0.0023 mg/ml, yet still further preferably lower than or equal to 1×10⁻⁵ mg/ml.

Even when the first organic compound has high solubility is used, a favorable light-emitting device can be obtained by adjusting the concentration of the first organic compound in the electron-injection buffer region 119. Specifically, the concentration of the first organic compound in the electron-injection buffer region 119 is preferably lower than the value of y=−8.735×ln (x)−2.3154, where y is the concentration (weight %) of the first organic compound in the electron-injection buffer region 119 and x is the solubility (mg/ml) of the first organic compound in water.

### <Second Organic Compound>

Meanwhile, the second organic compound has an electron-transport property. In a substance with a high electron-transport property, electron mobility is higher than hole mobility. Specifically, the electron mobility in the case where the square root of the electric field strength [V/cm] is 600 is preferably higher than or equal to 1×10⁻⁷ cm²/Vs, further preferably higher than or equal to 1×10⁻⁶ cm²/Vs.

As the organic compound having a high electron-transport property, a heteroaromatic compound can be used, for example. The heteroaromatic compound refers to a cyclic compound containing at least two different kinds of elements in a ring. Examples of cyclic structures include a three-membered ring, a four-membered ring, a five-membered ring, a six-membered ring, and the like, among which a five-membered ring and a six-membered ring are particularly preferable; the elements contained in the heteroaromatic compound are preferably one or more of nitrogen, oxygen, and sulfur, as well as carbon. In particular, a heteroaromatic compound containing nitrogen (a nitrogen-containing heteroaromatic compound) is preferable, and any of materials having a high electron-transport property (electron-transport materials), such as a nitrogen-containing heteroaromatic compound and an organic compound including a π-electron deficient heteroaromatic compound and the nitrogen-containing heteroaromatic compound, is preferably used.

It is preferable that the second organic compound not have a skeleton having a hole-transport property. Examples of the second organic compound include an organic compound without an amine skeleton and an organic compound without a carbazole skeleton.

The LUMO level of the second organic compound is preferably higher than or equal to −3.25 eV and lower than or equal to −2.50 eV. The HOMO level of the second organic compound is preferably higher than or equal to −6.5 eV and lower than or equal to −5.7 eV.

The acid dissociation constant pKₐ of the second organic compound is preferably greater than or equal to 3 and lower than or equal to 8, further preferably greater than or equal to 4 and less than or equal to 6. For example, the second organic compound may have basicity with the acid dissociation constant pKₐ greater than or equal to 4 and less than or equal to 8.

The second organic compound preferably has a skeleton having an electron-transport property. As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferable. Examples of the organic compound having a π-electron deficient heteroaromatic ring skeleton preferably includes an organic compound having a heteroaromatic ring having a polyazole skeleton, an organic compound having a heteroaromatic ring having a pyridine skeleton, an organic compound having a heteroaromatic ring having a diazine skeleton, and an organic compound having a heteroaromatic ring having a triazine skeleton.

Among the above materials, the organic compound having a heteroaromatic ring having a diazine skeleton (such as a pyrimidine skeleton, a pyrazine skeleton, or a pyridazine skeleton), the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage. In particular, a benzofuropyrimidine skeleton, a benzothienopyrimidine skeleton, a benzofuropyrazine skeleton, and a benzothienopyrazine skeleton are preferable because of their high acceptor property and reliability.

As the organic compound having a π-electron deficient heteroaromatic ring skeleton, it is possible to use any of materials given as examples of an electron-transport organic compound for the later-described first electron-transport layer. Specifically, the organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage. Specifically, 2,2′-(1,3-phenylene)bis(9-phenyl-1,10-phenanthroline) (abbreviation: mPPhen2P), 2-[3-(2-triphenylenyl)phenyl]-1,10-phenanthroline (abbreviation: mpPPhen), 2-[4-(9-phenanthrenyl)-1-naphthalenyl]-1,10-phenanthroline (abbreviation: PnNPhen), or any other organic compound having a phenanthroline skeleton is preferably used; it is further preferable to use mPPhen2P or any other organic compound having a phenanthroline dimer structure because such an organic compound enables excellently stable film quality. Furthermore, a material having a pyridine skeleton or a phenanthroline skeleton, which has a large pKₐ and thus has a high hole-blocking property, is particularly preferable as an electron-transport material used for the second organic compound of a light-emitting device of one embodiment of the present invention. A molecule having a larger number of pyridine skeletons or phenanthroline skeletons has a higher hole-blocking property and is thus particularly preferable for the electron-transport material that is used for the second organic compound in the light-emitting device of one embodiment of the present invention.

A mixed layer can be formed by co-evaporation of the organic compound described above in <First organic compound> and the organic compound described above in <Second organic compound>. Using the mixed layer as the electron-injection buffer region 119 of the layer 116 increases the reliability of the light-emitting device.

### <Mechanism of Light-Emitting Device>

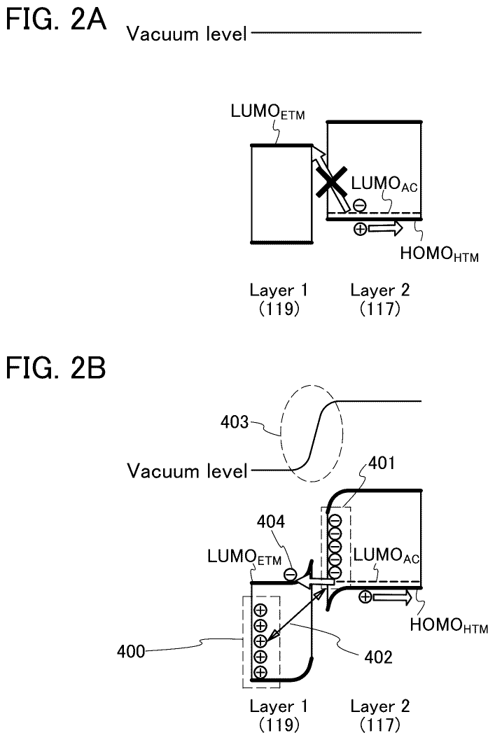

Here, a mechanism of a light-emitting device of one embodiment of the present invention is described in detail with reference to FIG. 2A.

In a typical light-emitting device, a Li compound used in an N-type layer acts as a donor, and generates carriers by charge separation between an electron-transport material and the Li compound. By contrast, the electron-injection buffer region 119 (layer 1) in one embodiment of the present invention is a layer no charge separation occurs and neither carriers nor electric charge is generated.

Meanwhile, in the charge-generation region 117 (layer 2), carriers (holes and electrons) are generated by voltage application even when the electron-injection buffer region 119 (layer 1) generates no electric charge. However, the difference between the LUMO level (LUMO_{ETM}) of an electron-transport material and the LUMO level (LUMO_{AC}) of an acceptor material is usually large, and thus the potential gap between the LUMO level of an acceptor material in the charge-generation region 117 and the LUMO level of the electron-transport material in the electron-injection buffer region 119 is also large, so that injection of the elections generated in the charge-generation region 117 to the electron-injection buffer region 119 is difficult (FIG. 2A).

Thus, in the case where electrons are generated in the charge-generation region 117 and does not generated in the electron-injection buffer region 119, the electrons are hardly injected to an electron-transport layer 114 of the light-emitting unit 501 and it is difficult to obtain light emission from the light-emitting layer 113 of the light-emitting unit 501.

However, the result that the light-emitting device of one embodiment of the present invention functions as a light-emitting device is obtained, although the electron-injection buffer region 119 does not function as a charge-generation layer. This can be explained referring to the driving mechanism of the light-emitting device, which involves electric dipole generation due to electric charge accumulation and a resultant shift of the vacuum level.

First, no carriers are generated from the electron-injection buffer region 119 of the light-emitting device of one embodiment of the present invention by voltage application, as described above. Meanwhile, holes injected from the anode 101 to the light-emitting unit 501 are accumulated at the interface of the electron-injection buffer region 119 on the electron-transport layer 114 side (holes 400 in FIG. 2B) because the electron-transport layer blocks holes or has a low hole-transport property. At this time, the electron-injection buffer region 119 blocks holes or has considerably low hole mobility, preventing passage of the holes and allowing the light-emitting unit 501 to emit light efficiently.

The voltage application and the hole accumulation induce holes and electrons in the charge-generation region 117; however, the electrons induced in the charge-generation region 117 are not injected to the electron-injection buffer region 119 but are accumulated on the electron-injection buffer region 119 side of the charge-generation region 117 (electrons 401 in FIG. 2B) since the difference between the LUMO level of the acceptor material included in the charge-generation region 117 and that of the second organic compound having an electron-transport property included in the electron-injection buffer region 119 is large as described above. The accumulated electrons form an electric double layer together with the holes accumulated on the electron-transport layer 114 side of the electron-injection buffer region 119, whereby electric dipole is generated (electric dipole 402 in FIG. 2B).

Accordingly, the vacuum level shift (vacuum level 403 in FIG. 2B) occurs, and thus the LUMO level of the acceptor material in the charge-generation region 117 and the LUMO level of the second organic compound having an electron-transport property in the electron-injection buffer region 119 become closer to each other, so that the electrons (electron 404 in FIG. 2B) generated in the charge-generation region 117 are injected to the electron-injection buffer region 119. The electrons that have been injected to the electron-injection buffer region 119 are injected to the light-emitting unit 501, reach the light-emitting layer 113 and are recombined with holes, enabling light emission in the first light-emitting unit 501. In this manner, the light-emitting device of one embodiment of the present invention can function as a light-emitting device.

A light-emitting device including the layer 116 which contains an unstable element such as an alkali metal or an alkaline earth metal or a compound of such an element acting as a donor, e.g., a Li oxide, deteriorates when exposed to the air. By contrast, a light-emitting device that includes the layer generating no electric charge (the electron-injection buffer region 119) is less likely to deteriorate when being exposed to the air. Therefore, even when the light-emitting device is processed with a step using a lithography method where exposure to the air is involved in the processing process, the deterioration of the light-emitting device due to exposure to the air is less likely to occur, whereby the light-emitting device of one embodiment of the present invention can be a light-emitting device with favorable characteristics.

Furthermore, the charge-generation region 117 is positioned on the cathode side of the electron-injection buffer region 119 and the electron-relay region 118. The charge-generation region 117 including an acceptor material is stable with respect to the air, and even when a light-emitting device is manufactured by forming the cathode 102 over the charge-generation region 117 exposed to the air, the light-emitting device is less likely to deteriorate due to exposure to the air. From this, it can also be said that the light-emitting device including the layer 116 is a light-emitting device stable with respect to the air.

The light-emitting device of one embodiment of the present invention having the above-described structure can have high current efficiency, high reliability, and a suppressed increase in driving voltage.

Note that one embodiment of the present invention is particularly suitable for a light-emitting device manufactured through a lithography step and also contributes to cost reduction of a light-emitting device manufactured without going through a lithography step since one embodiment of the present invention enables the light-emitting device to be stable to the atmosphere and accordingly have increased yield and eliminates the need for strict control of an atmosphere during a manufacturing process.

### <Structure of Light-Emitting Device>

Structures of the light-emitting device 130, which includes the above described organic compound, other than the above-described structures are specifically described below.

The light-emitting unit 501 may include functional layers in addition to the light-emitting layer. Although FIG. 1A illustrates the structure in which a hole-injection layer 111 (hereinafter referred to as a fourth layer in some cases), a hole-transport layer 112, and the electron-transport layer 114 are provided in the light-emitting unit 501 in addition to the light-emitting layer 113, the structure of the organic compound layer 103 in the present invention is not limited thereto, and any of the layers may be omitted or other layers may be added. Typical examples of the other layers include a carrier-blocking layer and an exciton-blocking layer.

Since the intermediate layer 116 includes the electron-injection buffer region 119, the electron-injection buffer region 119 serves as an electron-injection layer for a light-emitting unit on the anode side; thus, an electron-injection layer may be provided as necessary in the light-emitting unit 501 in FIG. 1A.

### [Layer 116]

Structures of the layer 116 of the light-emitting device 130 is described below.

The electron-injection buffer region 119 is a layer containing the first organic compound having a basic skeleton and the second organic compound having an electron-transport property as described above. In this layer, one or more of a metal, a metal compound, and a metal complex may be mixed.

The first organic compound having a basic skeleton in the electron-injection buffer region 119 preferably has no electron-donating property. The first organic compound having basicity preferably has no electron-donating property with respect to the second organic compound having an electron-transport property. When having an electron-donating property, the first organic compound having basicity more easily reacts with an atmospheric component such as water or oxygen and thus becomes unstable. The hole-transport property of the electron-injection buffer region 119 can be considerably lowered by containing the first organic compound having basicity and the second organic compound having an electron-transport property, and thus the layer 116 can function even when the first organic compound having basicity has no electron-donating property. Thus, the layer 116 and a light-emitting device that are stable with respect to an atmospheric component such as water or oxygen can be formed. It is preferable that a small signal or no signal be observed by an electron spin resonance (ESR) method in the electron-injection buffer region 119. For example, the spin density attributed to a signal observed at a g-factor of approximately 2.00 is preferably lower than or equal to 1×10¹⁷ spins/cm³, further preferably lower than 1×10¹⁶ spins/cm³. Specifically, the spin density of the mixed layer containing the first organic compound and the second organic compound in the electron-injection buffer region 119 measured by the electron spin resonance method is preferably lower than or equal to 1×10¹⁷ spins/cm³, further preferably lower than 1×10¹⁶ spins/cm³.

The charge-generation region 117 which is a charge generation layer is preferably in contact with the cathode 102 and preferably formed using a first material having an acceptor property and a composite material including an organic compound having a hole-transport property. Specifically, a mixed layer can be formed by co-evaporation of the first material having an acceptor property and an organic compound having a hole-transport property. That is, the mixed layer can be provided in the charge-generation region 117. The charge-generation region 117 may have a stacked-layer structure of a layer containing the first material having an acceptor property and a layer containing an organic compound having a hole-transport property. For example, a layer containing an organic compound having a hole-transport property may be positioned between the cathode 102 and the layer containing the first material having an acceptor property.

The first material having an acceptor property in the charge-generation region 117 preferably has an electron-accepting property. The first material having an acceptor property preferably has an electron-accepting property with respect to the organic compound having a hole-transport property. When the first material having an acceptor property has an electron-accepting property, charge separation occurs in the charge-generation region 117 and the charge-generation region 117 can function as a charge-generation layer. A signal is preferably observed by electron spin resonance in the charge-generation region 117. For example, the density of spins attributed to a signal observed at a g-factor of approximately 2.00 is preferably higher than or equal to 1×10¹⁷ spins/cm³, further preferably higher than or equal to 1×10¹⁸ spins/cm³, still further preferably higher than or equal to 1×10¹⁹ spins/cm³.

As the organic compound having a hole-transport property that is used in the composite material, any of a variety of organic compounds such as aromatic amine compounds, heteroaromatic compounds, aromatic hydrocarbons, and high molecular compounds (e.g., oligomers, dendrimers, or polymers) can be used. Note that the organic compound having a hole-transport property that is used in the composite material preferably has a hole mobility of 1×10⁻⁶ cm²/Vs or higher. The organic compound having a hole-transport property that is used in the composite material is preferably a compound having a condensed aromatic hydrocarbon ring or a π-electron rich heteroaromatic ring. As the condensed aromatic hydrocarbon ring, an anthracene ring, a naphthalene ring, or the like is preferable, for example. As the π-electron rich heteroaromatic ring, a condensed aromatic ring having at least one of a pyrrole skeleton, a furan skeleton, and a thiophene skeleton in the ring is preferable; specifically, a carbazole ring, a dibenzothiophene ring, or a ring in which an aromatic ring or a heteroaromatic ring is further condensed to the carbazole ring or the dibenzothiophene ring is preferable.

Such an organic compound having a hole-transport property further preferably has any of a carbazole skeleton, a dibenzofuran skeleton, a dibenzothiophene skeleton, and an anthracene skeleton. In particular, an aromatic amine having a substituent that includes a dibenzofuran ring or a dibenzothiophene ring, an aromatic monoamine that includes a naphthalene ring, or an aromatic monoamine in which a 9-fluorenyl group is bonded to nitrogen of amine through an arylene group may be used. Note that the organic compound having a hole-transport property preferably has an N,N-bis(4-biphenyl)amino group because a light-emitting device having a long lifetime can be manufactured.

Specific examples of the above-described organic compounds having a hole-transport property include N-(4-biphenyl)-6,N-diphenylbenzo[b]naphtho[1,2-d]furan-8-amine (abbreviation: BnfABP), NN-bis(4-biphenyl)-6-phenylbenzo[b]naphtho[1,2-d]furan-8-amine (abbreviation: BBABnf), 4,4′-bis(6-phenylbenzo[b]naphtho[1,2-d]furan-8-yl)-4″-phenyltriphenylamine (abbreviation: BnfBB1BP), N,N-bis(4-biphenyl)benzo[b]naphtho[1,2-d]furan-6-amine (abbreviation: BBABnf(6)), N,N-bis(4-biphenyl)benzo[b]naphtho[1,2-d]furan-8-amine (abbreviation: BBABnf(8)), N,N-bis(4-biphenyl)benzo[b]naphtho[2,3-d]furan-4-amine (abbreviation: BBABnf(II)(4)), NN-bis[4-(dibenzofuran-4-yl)phenyl]-4-amino-p-terphenyl (abbreviation: DBfBB1TP), N-[4-(dibenzothiophen-4-yl)phenyl]-N-phenyl-4-biphenylamine (abbreviation: ThBA1BP), 4-(2-naphthyl)-4′,4″-diphenyltriphenylamine (abbreviation: BBAβNB), 4-[4-(2-naphthyl)phenyl]-4′,4″-diphenyltriphenylamine (abbreviation: BBAβNBi), 4,4′-diphenyl-4″-(6;1′-binaphthyl-2-yl)triphenylamine (abbreviation: BBAαNβNB), 4,4′-diphenyl-4″-(7;1′-binaphthyl-2-yl)triphenylamine (abbreviation: BBAαNβNB-03), 4,4′-diphenyl-4″-(7-phenyl)naphthyl-2-yltriphenylamine (abbreviation: BBAPβNB-03), 4,4′-diphenyl-4″-(6;2′-binaphthyl-2-yl)triphenylamine (abbreviation: BBA(βN2)B), 4,4′-diphenyl-4″-(7;2′-binaphthyl-2-yl)triphenylamine (abbreviation: BBA(βN2)B-03), 4,4′-diphenyl-4″-(4;2′-binaphthyl-1-yl)triphenylamine (abbreviation: BBAβNαNB), 4,4′-diphenyl-4″-(5;2′-binaphthyl-1-yl)triphenylamine (abbreviation: BBAbNαNB-02), 4-(4-biphenylyl)-4′-(2-naphthyl)-4″-phenyltriphenylamine (abbreviation: TPBiAβNB), 4-(3-biphenylyl)-4′-[4-(2-naphthyl)phenyl]-4″-phenyltriphenylamine (abbreviation: mTPBiAβNBi), 4-(4-biphenylyl)-4′-[4-(2-naphthyl)phenyl]-4″-phenyltriphenylamine (abbreviation: TPBiAβNBi), 4-phenyl-4′-(1-naphthyl)triphenylamine (abbreviation: αNBA1BP), 4,4′-bis(1-naphthyl)triphenylamine (abbreviation: αNBB1BP), 4,4′-diphenyl-4″-[4′-(carbazol-9-yl)biphenyl-4-yl]triphenylamine (abbreviation: YGTBi1BP), 4′-[4-(3-phenyl-9H-carbazol-9-yl)phenyl]tris(biphenyl-4-yl)amine (abbreviation: YGTBi1BP-02), 4-[4′-(carbazol-9-yl)biphenyl-4-yl]-4′-(2-naphthyl)-4″-phenyltriphenylamine (abbreviation: YGTBiβNB), N-[4-(9-phenyl-9H-carbazol-3-yl)phenyl]-N-[4-(1-naphthyl)phenyl]-9,9′-spirobi[9H-fluoren]-2-amine (abbreviation: PCBNBSF), NN-bis[(biphenyl)-4-yl]-9,9′-spirobi[9H-fluoren]-2-amine (abbreviation: BBASF), N,N-bis[(biphenyl)-4-yl]-9,9′-spirobi[9H-fluoren]-4-amine (abbreviation: BBASF(4)), N-(biphenyl-2-yl)-N-(9,9-dimethyl-9H-fluoren-2-yl)-9,9′-spirobi[9H-fluoren]-4-amine (abbreviation: oFBiSF), N-(biphenyl-4-yl)-N-(9,9-dimethyl-9H-fluoren-2-yl)dibenzofuran-4-amine (abbreviation: FrBiF), N-[4-(1-naphthyl)phenyl]-N-[3-(6-phenyldibenzofuran-4-yl)phenyl]-1-naphthylamine (abbreviation: mPDBfBNBN), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-[4-(9-phenylfluoren-9-yl)phenyl]triphenylamine (abbreviation: BPAFLBi), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), N-phenyl-N-[4-(9-phenyl-9H-carbazol-3-yl)phenyl]-9,9′-spirobi[9H-fluoren]-2-amine (abbreviation: PCBASF), N-(biphenyl-4-yl)-N-[4-(9-phenyl-9H-carbazol-3-yl)phenyl]-9,9-dimethyl-9H-fluoren-2-amine (abbreviation: PCBBiF), N,N-bis(9,9-dimethyl-9H-fluoren-2-yl)-9,9′-spirobi[9H-fluoren]-4-amine, N,N-bis(9,9-dimethyl-9H-fluoren-2-yl)-9,9′-spirobi[9H-fluoren]-3-amine, N,N-bis(9,9-dimethyl-9H[fluoren]-2-yl)-9,9′-spirobi[9H-fluoren]-2-amine, and N,N-bis(9,9-dimethyl-9H-fluoren-2-yl)-9,9′-spirobi[9H-fluoren]-1-amine.

As the material having a hole-transport property, the following aromatic amine compounds can also be used: N,N-di(p-tolyl)-N,N-diphenyl-p-phenylenediamine (abbreviation: DTDPPA), 4,4′-bis[N-(4-diphenylaminophenyl)-N-phenylamino]biphenyl (abbreviation: DPAB), 4,4′-bis(N-{4-[N-(3-methylphenyl)-N′-phenylamino]phenyl}-N-phenylamino)biphenyl (abbreviation: DNTPD), and 1,3,5-tris[N-(4-diphenylaminophenyl)-N-phenylamino]benzene (abbreviation: DPA3B), and the like.

Examples of the first material having an acceptor property that is included in the charge-generation region 117 include an organic compound having an electron-withdrawing group (e.g., a halogen group, a cyano group, or the like), such as 7,7,8,8-tetracyano-2,3,5,6-tetrafluoroquinodimethane (abbreviation: F4-TCNQ), chloranil, 2,3,6,7,10,11-hexacyano-1,4,5,8,9,12-hexaazatriphenylene (abbreviation: HAT-CN), 1,3,4,5,7,8-hexafluorotetracyano-naphthoquinodimethane (abbreviation: F6-TCNNQ), or 2-(7-dicyanomethylen-1,3,4,5,6,8,9,10-octafluoro-7H-pyren-2-ylidene)malononitrile. A compound in which electron-withdrawing groups are bonded to a condensed aromatic ring having a plurality of heteroatoms, such as HAT-CN, is particularly preferable because it is thermally stable. A [3] radialene derivative having an electron-withdrawing group (in particular, a cyano group, a halogen group such as a fluoro group, or the like) has a very high electron-accepting property and thus is preferable. Specific examples include α,α′,α″-1,2,3-cyclopropanetriylidenetris[4-cyano-2,3,5,6-tetrafluorobenzeneacetonitrile], α,α′,α″-1,2,3-cyclopropanetriylidenetris[2,6-dichloro-3,5-difluoro-4-(trifluoromethyl)benzeneacetonitrile], and α,α′,α″-1,2,3-cyclopropanetriylidenetris[2,3,4,5,6-pentafluorobenzeneacetonitrile]. As the substance having an acceptor property, transition metal oxide such as molybdenum oxide, vanadium oxide, ruthenium oxide, tungsten oxide, or manganese oxide can also be used, other than the above-described organic compounds.

The electron-relay region 118 includes a material having an electron-transport property and has a function of preventing an interaction between the electron-injection buffer region 119 and the charge-generation region 117 and smoothly transferring electrons. The LUMO level of the material having an electron-transport property contained in the electron-relay region 118 is preferably between the LUMO level of the acceptor substance in the charge-generation region 117 and the LUMO level of the organic compound contained in the electron-injection buffer region 119. As a specific value of the energy level, the LUMO level of the material having an electron-transport property in the electron-relay region 118 is preferably higher than or equal to −5.0 eV, further preferably higher than or equal to −5.0 eV and lower than or equal to −3.0 eV, still further preferably higher than or equal to −4.30 eV and lower than or equal to −3.00 eV, yet still further preferably higher than or equal to −4.30 eV and lower than or equal to −3.30 eV, in which case electrons generated in the charge-generation region 117 can be easily injected to the electron-injection buffer region 119 and accordingly an increase in driving voltage can be inhibited. Note that as the material having an electron-transport property used in the electron-relay region 118, a phthalocyanine-based material or a metal complex having a metal-oxygen bond and an aromatic ligand is preferably used.

Specifically, it is possible to use a perylenetetracarboxylic acid derivative such as diquinoxalino[2,3-a:2′,3′-c]phenazine (abbreviation: HATNA), 2,3,8,9,14,15-hexafluorodiquinoxalino[2,3-a:2′,3′-c]phenazine (abbreviation: HATNA-F6), 3,4,9,10-perylenetetracarboxylic diimide (abbreviation: PTCDI), or 3,4,9,10-perylenetetracarboxyl-bis-benzimidazole (abbreviation: PTCBI), (C₆₀-Iₕ)[5,6]fullerene (abbreviation: C₆₀), (C₇₀-D₅ₕ)[5,6]fullerene (abbreviation: C₇₀), or phthalocyanine (abbreviation: H₂Pc). Alternatively, it is possible to use a metal phthalocyanine containing copper, zinc, cobalt, iron, chromium, nickel, or the like or a derivative thereof, such as copper phthalocyanine (abbreviation: CuPc), zinc phthalocyanine (abbreviation: ZnPc), cobalt phthalocyanine (abbreviation: CoPc), iron phthalocyanine (abbreviation: FePc), tin phthalocyanine (abbreviation: SnPc), tin oxide phthalocyanine (abbreviation: SnOPc), titanium oxide phthalocyanine (abbreviation: TiOPc), or vanadium oxide phthalocyanine (abbreviation: VOPc). It is particularly preferable to use a phthalocyanine-based metal complex such as copper phthalocyanine or zinc phthalocyanine or 2,3,8,9,14,15-hexafluorodiquinoxalino[2,3-a:2′,3′-c]phenazine. Among these materials, CuPc and ZnPc are preferable because they are inexpensive and have favorable characteristics. Using ZnPc, which has a low diffusion coefficient with respect to silicon, reduces the probability that metal diffusion to a semiconductor adversely affects the semiconductor characteristics; accordingly, ZnPc is particularly suitable for a display apparatus manufactured using a silicon semiconductor.

The thickness of the electron-relay region 118 is preferably greater than or equal to 1 nm and less than or equal to 10 nm, further preferably greater than or equal to 2 nm and less than or equal to 5 nm.

A light-emitting device including the intermediate layer 116 does not suffer a significant increase of driving voltage and a significant decrease of emission efficiency even when the organic compound layer 103 is processed by a lithography method and thus has favorable characteristics.

Note that the structure of the light-emitting device of one embodiment of the present invention is not limited to that of the light-emitting device 130 in FIG. 1A. For example, the light-emitting device of one embodiment of the present invention may have a structure in which the light-emitting device 130 in FIG. 1A does not include the electron-relay region 118. For example, as in a light-emitting device 130A illustrated in FIG. 1B, the charge-generation region 117 may be positioned over the electron-injection buffer region 119.

### [Electrode]

The structures of the anode 101 and the cathode 102 in the light-emitting device 130 are described below.

The anode 101 may have a stacked-layer structure where the layer in contact with the organic compound layer 103 functions as the anode. The anode is preferably formed using any of metals, alloys, and conductive compounds with a high work function (specifically, higher than or equal to 4.0 eV), mixtures thereof, and the like. Specific examples include indium oxide-tin oxide (ITO: Indium Tin Oxide), indium oxide-tin oxide containing silicon or silicon oxide, indium oxide-zinc oxide, and indium oxide containing tungsten oxide and zinc oxide (IWZO). Such conductive metal oxide films are usually formed by a sputtering method, but may be formed by application of a sol-gel method or the like. In an example of the formation method, indium oxide-zinc oxide is deposited by a sputtering method using a target in which zinc oxide is added to indium oxide at greater than or equal to 1 wt % and less than or equal to 20 wt %. Furthermore, indium oxide including tungsten oxide and zinc oxide (IWZO) can be formed by a sputtering method using a target in which tungsten oxide and zinc oxide are added to indium oxide at 0.5 to 5 wt % and greater than or equal to 0.1 wt % and less than or equal to 1 wt %, respectively. Other examples of the material used for the anode include gold (Au), platinum (Pt), nickel (Ni), tungsten (W), chromium (Cr), molybdenum (Mo), iron (Fe), cobalt (Co), copper (Cu), palladium (Pd), and nitride of a metal material (e.g., titanium nitride). Graphene can also be used for the anode. Note that when the composite material contained in the charge-generation region 117 in the above-described layer 116 is used for a layer (typically, a hole-injection layer) that is in contact with the anode, an electrode material can be selected regardless of its work function.

The cathode 102 may have a stacked-layer structure where the layer in contact with the organic compound layer 103 functions as the cathode. As a substance of the cathode, any of metals, alloys, and electrically conductive compounds with a low work function (specifically, lower than or equal to 3.8 eV), mixtures thereof, and the like can be used. Specific examples of such a cathode material include elements belonging to Group 1 or Group 2 of the periodic table, such as alkali metal (e.g., lithium (Li) or cesium (Cs)), alkaline earth metal (e.g., magnesium (Mg), calcium (Ca), and strontium (Sr)), and alloys containing any of these elements (e.g., MgAg and AlLi). Another specific examples of the cathode material include rare earth metals (e.g., europium (Eu) and ytterbium (Yb)) and an alloy containing any of these metals. However, when the electron-injection layer is provided between the cathode 102 and the electron-transport layer, any of a variety of conductive materials such as aluminum (Al), silver (Ag), indium oxide-tin oxide (ITO), and indium oxide-tin oxide containing silicon or silicon oxide can be used for the cathode regardless of the work function.

In the case where the cathode 102 is formed using a material that transmits the light LGT, the light-emitting device can emit light from the cathode 102 side.

Films of these conductive materials can be formed by a dry process such as a vacuum evaporation method or a sputtering method, an ink-jet method, a spin coating method, or the like. Alternatively, a wet process using a sol-gel method or a wet process using a paste of a metal material may be employed.

### [Light-Emitting Unit]

The structure of the light-emitting unit 501 in the light-emitting device 130 is described below.

The organic compound layer 103 has a stacked-layer structure. FIG. 1A illustrates a stacked-layer structure including the layer 116 and the light-emitting unit 501 including the light-emitting layer 113. The light-emitting unit 501 also has a stacked-layer structure. The light-emitting unit 501 can include a variety of functional layers such as a hole-injection layer, a hole-transport layer, an electron-transport layer, an electron-injection layer, a carrier-blocking layer (e.g., a hole-blocking layer or an electron-blocking layer), and an exciton-blocking layer as appropriate, without being limited to the structure illustrated in FIG. 1A.

The hole-injection layer 111 is provided in contact with the anode and has a function of facilitating injection of holes into the organic compound layer 103 (the light-emitting unit 501). The hole-injection layer 111 can be formed using a phthalocyanine-based compound or complex compound (e.g., phthalocyanine (abbreviation: H₂Pc), copper phthalocyanine (abbreviation: CuPc), or the like), an aromatic amine compound (e.g., 4,4′-bis[N-(4-diphenylaminophenyl)-N-phenylamino]biphenyl (abbreviation: DPAB), 4,4′-bis(N-{4-[N-(3-methylphenyl)-N-phenylamino]phenyl}-N-phenylamino)biphenyl (abbreviation: DNTPD), or the like), a high molecular such as poly(3,4-ethylenedioxythiophene)/(polystyrenesulfonic acid) (abbreviation: PEDOT/PSS), or the like.

The hole-injection layer 111 which is a fourth layer may be formed using a substance having an electron-acceptor property. As the substance having an acceptor property, any of substances described as examples of the acceptor substance that is used in the composite material contained in the charge-generation region 117 in the above-described layer 116 can similarly be used.

The composite material included in the charge-generation region 117 in the above-described layer 116 may be similarly used to form the hole-injection layer 111 which is the fourth layer. For example, the hole-injection layer 111 is preferably formed using a composite material including a second material having an acceptor property and an organic compound having a hole-transport property. In particular, a mixed layer can be formed by co-evaporation of the second material having an acceptor property and the organic compound having a hole-transport property. That is, the mixed layer can be provided as the hole-injection layer 111. The hole-injection layer 111 may include a stacked-layer structure of a layer containing the second material having an acceptor property and a layer containing the organic compound having a hole-transport property. For example, a layer containing the second material having an acceptor property may be positioned between the anode 101 and the layer containing an organic compound having a hole-transport property. Note that the second material can be any of materials that can be used as the above-described first material.

Further preferably, in the hole-injection layer 111, the organic compound having a hole-transport property that is used in the composite material has a relatively low HOMO level higher than or equal to −5.7 eV and lower than or equal to −5.4 eV. When the organic compound having a hole-transport property that is used in the composite material has a relatively low HOMO level, holes can be easily injected into the hole-transport layer to easily provide a light-emitting device having a long lifetime. In addition, when the organic compound having a hole-transport property that is used in the composite material has a relatively low HOMO level, induction of holes can be inhibited properly so that a light-emitting device having a longer lifetime can be obtained.

The formation of the hole-injection layer 111 can improve the hole-injection property, whereby a light-emitting device having a low driving voltage can be obtained.

Among substances having an acceptor property, an organic compound having an acceptor property is easy to use because it is easily formed by vapor deposition.

Furthermore, the composite material included in the charge-generation region 117 can also be used for the hole-injection layer 111; thus, it can be said that the hole-injection layer 111 is also stable with respect to the air. Thus, the light-emitting device of one embodiment of the present invention in which the anode is in contact with the hole-injection layer 111 containing the composite material included in the charge-generation region 117 and the cathode is in contact with the charge-generation region 117 can be regarded as a light-emitting device which is less likely to deteriorate due to the exposure to the air (a light-emitting device stable with respect to the air).

The hole-transport layer 112 contains an organic compound having a hole-transport property. The organic compound having a hole-transport property preferably has a hole mobility higher than or equal to 1×10⁻⁶ cm²/Vs.

Examples of the material having a hole-transport property include compounds having an aromatic amine skeleton, such as 4,4′-bis[N-(1-naphthyl)-N-phenylamino]biphenyl (abbreviation: NPB), NN-diphenyl-N,N-bis(3-methylphenyl)-4,4′-diaminobiphenyl (abbreviation: TPD), N,N-bis(9,9′-spirobi[9H-fluoren]-2-yl)-N,N′-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), and N-phenyl-N-[4-(9-phenyl-9H-carbazol-3-yl)phenyl]-9,9′-spirobi[9H-fluoren]-2-amine (abbreviation: PCBASF); compounds having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), 3,3′-bis(9-phenyl-9H-carbazole) (abbreviation: PCCP), 9,9′-bis(biphenyl-4-yl)-3,3′-bi-9H-carbazole (abbreviation: BisBPCz), 9,9′-bis(biphenyl-3-yl)-3,3′-bi-9H-carbazole (abbreviation: BismBPCz), 9-(biphenyl-3-yl)-9′-(biphenyl-4-yl)-9H,9′H-3,3′-bicarbazole (abbreviation: mBPCCBP), 9-(2-naphthyl)-9′-phenyl-9H,9′H-3,3′-bicarbazole (abbreviation: PNCCP), 9-(3-biphenyl)-9′-(2-naphthyl)-3,3′-bi-9H-carbazole (abbreviation: PNCCmBP), 9-(4-biphenyl)-9′-(2-naphthyl)-3,3′-bi-9H-carbazole (abbreviation: PNCCBP), 9,9′-di-2-naphthyl-3,3′-9H,9′H-bicarbazole (abbreviation: BisPNCz), 9-(2-naphthyl)-9′-[1,1′:4′,1″-terphenyl]-3-yl-3,3′-9H,9′H-bicarbazole, 9-(2-naphthyl)-9′-[1,1′:3′,1″-terphenyl]-3-yl-3,3′-9H,9′H-bicarbazole, 9-(2-naphthyl)-9′-[1,1′:3′,1″-terphenyl]-5′-yl-3,3′-9H,9′H-bicarbazole, 9-(2-naphthyl)-9′-[1,1′:4′,1″-terphenyl]-4-yl-3,3′-9H,9′H-bicarbazole, 9-(2-naphthyl)-9′-[1,1′:3′,1″-terphenyl]-4-yl-3,3′-9H,9′H-bicarbazole, 9-(2-naphthyl)-9′-(triphenylen-2-yl)-3,3′-9H,9′H-bicarbazole, 9-phenyl-9′-(triphenylen-2-yl)-3,3′-9H,9′H-bicarbazole (abbreviation: PCCzTp), 9,9′-bis(triphenylen-2-yl)-3,3′-9H,9′H-bicarbazole, 9-(4-biphenyl)-9′-(triphenylen-2-yl)-3,3′-9H,9′H-bicarbazole, and 9-(triphenylen-2-yl)-9′-[1,1′:3′,1″-terphenyl]-4-yl-3,3′-9H,9′H-bicarbazole; compounds having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), and 4-[4-(9-phenyl-9H-fluoren-9-yl)phenyl]-6-phenyldibenzothiophene (abbreviation: DBTFLP-IV); and compounds having a furan skeleton, such as 4,4′,4″-(benzene-1,3,5-triyl)tri(dibenzofuran) (abbreviation: DBF3P-II) and 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. Note that any of the substances given as examples of the hole-transport material used for the composite material for the hole-injection layer 111 can also be suitably used as the material included in the hole-transport layer 112.

The light-emitting layer 113 preferably contains a light-emitting substance and a host material. The light-emitting layer may additionally contain other materials. Alternatively, the light-emitting layer may be a stack of two layers with different compositions.

The light-emitting substance may be a fluorescent substance, a phosphorescent substance, a substance exhibiting thermally activated delayed fluorescence (TADF), or other light-emitting substances.

Examples of the material that can be used as a fluorescent substance in the light-emitting layer are as follows. Other fluorescent substances can also be used.

The examples include 5,6-bis[4-(10-phenyl-9-anthryl)phenyl]-2,2′-bipyridine (abbreviation: PAP2BPy), 5,6-bis[4′-(10-phenyl-9-anthryl)biphenyl-4-yl]-2,2′-bipyridine (abbreviation: PAPP2BPy), N,N-diphenyl-N,N-bis[4-(9-phenyl-9H-fluoren-9-yl)phenyl]pyrene-1,6-diamine (abbreviation: 1,6FLPAPrn), N,N-bis(3-methylphenyl)-N,N-bis[3-(9-phenyl-9H-fluoren-9-yl)phenyl]pyrene-1,6-diamine (abbreviation: 1,6mMemFLPAPrn), N,N-bis[4-(9H-carbazol-9-yl)phenyl]-N,N-diphenylstilbene-4,4′-diamine (abbreviation: YGA2S), 4-(9H-carbazol-9-yl)-4′-(10-phenyl-9-anthryl)triphenylamine (abbreviation: YGAPA), 4-(9H-carbazol-9-yl)-4′-(9,10-diphenyl-2-anthryl)triphenylamine (abbreviation: 2YGAPPA), N,9-diphenyl-N-[4-(10-phenyl-9-anthryl)phenyl]-9H-carbazol-3-amine (abbreviation: PCAPA), perylene, 2,5,8,11-tetra-tert-butylperylene (abbreviation: TBP), 4-(10-phenyl-9-anthryl)-4′-(9-phenyl-9H-carbazol-3-yl)triphenylamine (abbreviation: PCBAPA), N,N′-(2-tert-butylanthracene-9,10-diyldi-4,1-phenylene)bis[N,N,N-triphenyl-1,4-phenylenediamine](abbreviation: DPABPA), N,9-diphenyl-N-[4-(9,10-diphenyl-2-anthryl)phenyl]-9H-carbazol-3-amine (abbreviation: 2PCAPPA), N-[4-(9,10-diphenyl-2-anthryl)phenyl]-N,N,N-triphenyl-1,4-phenylenediamine (abbreviation: 2DPAPPA), N,N,N,N,N′,N′,N″,N″-octaphenyldibenzo[g,p]chrysene-2,7,10,15-tetraamine (abbreviation: DBC1), coumarin 30, N-(9,10-diphenyl-2-anthryl)-N,9-diphenyl-9H-carbazol-3-amine (abbreviation: 2PCAPA), N-[9,10-bis(biphenyl-2-yl)-2-anthryl]-N,9-diphenyl-9H-carbazol-3-amine (abbreviation: 2PCABPhA), N-(9,10-diphenyl-2-anthryl)-N,N,N′-triphenyl-1,4-phenylenediamine (abbreviation: 2DPAPA), N-[9,10-bis(biphenyl-2-yl)-2-anthryl]-N,N,N-triphenyl-1,4-phenylenediamine (abbreviation: 2DPABPhA), 9,10-bis(biphenyl-2-yl)-N-[4-(9H-carbazol-9-yl)phenyl]-N-phenylanthracen-2-amine (abbreviation: 2YGABPhA), N,N,9-triphenylanthracen-9-amine (abbreviation: DPhAPhA), coumarin 545T, NN-diphenylquinacridone (abbreviation: DPQd), rubrene, 5,12-bis(biphenyl-4-yl)-6,11-diphenyltetracene (abbreviation: BPT), 2-(2-{2-[4-(dimethylamino)phenyl]ethenyl}-6-methyl-4H-pyran-4-ylidene)propanedinitrile (abbreviation: DCM1), 2-{2-methyl-6-[2-(2,3,6,7-tetrahydro-1H,5H-benzo[ij]quinolizin-9-yl)ethenyl]-4H-pyran-4-ylidene}propanedinitrile (abbreviation: DCM2), N,N,N,N-tetrakis(4-methylphenyl)tetracene-5,11-diamine (abbreviation: p-mPhTD), 7,14-diphenyl-N,N,N,N-tetrakis(4-methylphenyl)acenaphtho[1,2-a]fluoranthene-3,10-diamine (abbreviation: p-mPhAFD), 2-{2-isopropyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTI), 2-{2-tert-butyl-6-[2-(1,1,7,7-tetramethyl-2,3,6,7-tetrahydro-1H,5H-benzo[ij]quinolizin-9-yl)ethenyl]-4H-pyran-4-ylidene}propanedinitrile (abbreviation: DCJTB), 2-(2,6-bis{2-[4-(dimethylamino)phenyl]ethenyl}-4H-pyran-4-ylidene)propanedinitrile (abbreviation: BisDCM), 2-{2,6-bis[2-(8-methoxy-1,1,7,7-tetramethyl-2,3,6,7-tetrahydro-1H,5H-benzo[ij]quinolizin-9-yl)ethenyl]-4H-pyran-4-ylidene}propanedinitrile (abbreviation: BisDCJTM), N,N-diphenyl-N,N-(1,6-pyrene-diyl)bis[(6-phenylbenzo[b]naphtho[1,2-d]furan)-8-amine](abbreviation: 1,6BnfAPrn-03), 3,10-bis[N-(9-phenyl-9H-carbazol-2-yl)-N-phenylamino]naphtho[2,3-b;6,7-b′]bisbenzofuran (abbreviation: 3,10PCA2Nbf(IV)-02), and 3,10-bis[N-(dibenzofuran-3-yl)-N-phenylamino]naphtho[2,3-b;6,7-b′]bisbenzofuran (abbreviation: 3,10FrA2Nbf(IV)-02). Condensed aromatic diamine compounds typified by pyrenediamine compounds such as 1,6FLPAPrn, 1,6mMemFLPAPrn, and 1,6BnfAPrn-03 are particularly preferable because of their high hole-trapping properties, high emission efficiency, or high reliability.

Examples of the material that can be used when a phosphorescent substance is used as the light-emitting substance in the light-emitting layer are as follows.

The examples include an organometallic iridium complex having a 4H-triazole skeleton, such as tris{2-[5-(2-methylphenyl)-4-(2,6-dimethylphenyl)-4H-1,2,4-triazol-3-yl-κN2]phenyl-κC}iridium(III) (abbreviation: [Ir(mpptz-dmp)₃]), tris(5-methyl-3,4-diphenyl-4H-1,2,4-triazolato)iridium(III) (abbreviation: [Ir(Mptz)₃]), or tris[4-(3-biphenyl)-5-isopropyl-3-phenyl-4H-1,2,4-triazolato]iridium(III) (abbreviation: [Ir(iPrptz-3b)₃]); an organometallic iridium complex having a 1H-triazole skeleton, such as tris[3-methyl-1-(2-methylphenyl)-5-phenyl-1H-1,2,4-triazolato]iridium(III) (abbreviation: [Ir(Mptz1-mp)₃]) or tris(1-methyl-5-phenyl-3-propyl-1H-1,2,4-triazolato)iridium(III) (abbreviation: [Ir(Prptz1-Me)₃]); an organometallic iridium complex having an imidazole skeleton, such as fac-tris[1-(2,6-diisopropylphenyl)-2-phenyl-1H-imidazole]iridium(III) (abbreviation: [Ir(iPrpim)₃]) or tris[3-(2,6-dimethylphenyl)-7-methylimidazo[1,2-f]phenanthridinato]iridium(III) (abbreviation: [Ir(dmpimpt-Me)₃]); and an organometallic iridium complex in which a phenylpyridine derivative having an electron-withdrawing group is a ligand, such as bis[2-(4′,6′-difluorophenyl)pyridinato-N,C^{2′}]iridium(III) tetrakis(1-pyrazolyl)borate (abbreviation: FIr6), bis[2-(4′,6′-difluorophenyl)pyridinato-N,C^{2′}]iridium(III) picolinate (abbreviation: FIrpic), bis{2-[3′,5′-bis(trifluoromethyl)phenyl]pyridinato-N,C^{2′}}iridium(III) picolinate (abbreviation: [Ir(CF₃ppy)₂(pic)]), or bis[2-(4′,6′-difluorophenyl)pyridinato-N,C^{2′}]iridium(III) acetylacetonate (abbreviation: FIracac). These compounds exhibit blue phosphorescent light and have an emission peak in the wavelength range of 450 nm to 520 nm.

Other examples include an organometallic iridium complex having a pyrimidine skeleton, such as tris(4-methyl-6-phenylpyrimidinato)iridium(III) (abbreviation: [Ir(mppm)₃]), tris(4-t-butyl-6-phenylpyrimidinato)iridium(III) (abbreviation: [Ir(tBuppm)₃]), (acetylacetonato)bis(6-methyl-4-phenylpyrimidinato)iridium(III) (abbreviation: [Ir(mppm)₂(acac)]), (acetylacetonato)bis(6-tert-butyl-4-phenylpyrimidinato)iridium(III) (abbreviation: [Ir(tBuppm)₂(acac)]), (acetylacetonato)bis[6-(2-norbornyl)-4-phenylpyrimidinato]iridium(III) (abbreviation: [Ir(nbppm)₂(acac)]), (acetylacetonato)bis[5-methyl-6-(2-methylphenyl)-4-phenylpyrimidinato]iridium(III) (abbreviation: [Ir(mpmppm)₂(acac)]), or (acetylacetonato)bis(4,6-diphenylpyrimidinato)iridium(III) (abbreviation: [Ir(dppm)₂(acac)]); an organometallic iridium complex having a pyrazine skeleton, such as (acetylacetonato)bis(3,5-dimethyl-2-phenylpyrazinato)iridium(III) (abbreviation: [Ir(mppr-Me)₂(acac)]) or (acetylacetonato)bis(5-isopropyl-3-methyl-2-phenylpyrazinato)iridium(III) (abbreviation: [Ir(mppr-iPr)₂(acac)]); an organometallic iridium complex having a pyridine skeleton, such as tris(2-phenylpyridinato-N,C^{2′})iridium(III) (abbreviation: [Ir(ppy)₃]), bis(2-phenylpyridinato-N,C^{2′})iridium(III) acetylacetonate (abbreviation: [Ir(ppy)₂(acac)]), bis(benzo[h]quinolinato)iridium(III) acetylacetonate (abbreviation: [Ir(bzq)₂(acac)]), tris(benzo[h]quinolinato)iridium(III) (abbreviation: [Ir(bzq)₃]), tris(2-phenylquinolinato-N,C^{2′})iridium(III) (abbreviation: [Ir(pq)₃]), bis(2-phenylquinolinato-N,C^{2′})iridium(III) acetylacetonate (abbreviation: [Ir(pq)₂(acac)]), [2-d₃-methyl-8-(2-pyridinyl-κN)benzofuro[2,3-b]pyridine-κC]bis[2-(5-d₃-methyl-2-pyridinyl-κN2)phenyl-kC]iridium(III) (abbreviation: Ir(5mppy-d₃)₂(mbfpypy-d₃)), {2-(methyl-d₃)-8-[4-(1-methylethyl-1-d)-2-pyridinyl-κN]benzofuro[2,3-b]pyridin-7-yl-κC}bis{5-(methyl-d₃)-2-[5-(methyl-d₃)-2-pyridinyl-κN]phenyl-κC}iridium(III) (abbreviation: Ir(5mtpy-d₆)₂(mbfpypy-iPr-d₄)), [2-d₃-methyl-(2-pyridinyl-κN)benzofuro[2,3-b]pyridine-κCbis[2-(2-pyridinyl-κN)phenyl-κC]iridium(III) (abbreviation: Ir(ppy)₂(mbfpypy-d₃)), or [2-(4-methyl-5-phenyl-2-pyridinyl-κN)phenyl-κC]bis[2-(2-pyridinyl-κN)phenyl-κC]iridium(III) (abbreviation: Ir(ppy)₂(mdppy)); and a rare earth metal complex such as tris(acetylacetonato)(monophenanthroline)terbium(III) (abbreviation: [Tb(acac)₃(Phen)]). These are mainly compounds that exhibit green phosphorescent light and have an emission peak in the wavelength range of 500 nm to 600 nm. Note that organometallic iridium complexes having a pyrimidine skeleton have distinctively high reliability or emission efficiency and thus are particularly preferable.

Other examples include an organometallic iridium complex having a pyrimidine skeleton, such as (diisobutyrylmethanato)bis[4,6-bis(3-methylphenyl)pyrimidinato]iridium(III) (abbreviation: [Ir(5mdppm)₂(dibm)]), bis[4,6-bis(3-methylphenyl)pyrimidinato](dipivaloylmethanato)iridium(III) (abbreviation: [Ir(5mdppm)₂(dpm)]), or bis[4,6-di(naphthalen-1-yl)pyrimidinato](dipivaloylmethanato)iridium(III) (abbreviation: [Ir(d1npm)₂(dpm)]); an organometallic iridium complex having a pyrazine skeleton, such as (acetylacetonato)bis(2,3,5-triphenylpyrazinato)iridium(III) (abbreviation: [Ir(tppr)₂(acac)]), bis(2,3,5-triphenylpyrazinato)(dipivaloylmethanato)iridium(III) (abbreviation: [Ir(tppr)₂(dpm)]), or (acetylacetonato)bis[2,3-bis(4-fluorophenyl)quinoxalinato]iridium(III) (abbreviation: [Ir(Fdpq)₂(acac)]); an organometallic iridium complex having a pyridine skeleton, such as tris(1-phenylisoquinolinato-N,C^{2′})iridium(III) (abbreviation: [Ir(piq)₃]) or bis(1-phenylisoquinolinato-N,C^{2′})iridium(III) acetylacetonate (abbreviation: [Ir(piq)₂(acac)]); a platinum complex such as 2,3,7,8,12,13,17,18-octaethyl-21H,23H-porphyrinplatinum(II) (abbreviation: PtOEP); and a rare earth metal complex such as tris(1,3-diphenyl-1,3-propanedionato)(monophenanthroline)europium(III) (abbreviation: [Eu(DBM)₃(Phen)]) or tris[1-(2-thenoyl)-3,3,3-trifluoroacetonato](monophenanthroline)europium(III) (abbreviation: [Eu(TTA)₃(Phen)]). These compounds exhibit red phosphorescent light and have an emission peak in the wavelength range of 600 nm to 700 nm. Organometallic iridium complexes having a pyrazine skeleton can provide red light emission with favorable chromaticity.

Besides the above phosphorescent compounds, known phosphorescent compounds may be selected and used.

Examples of the TADF material include a fullerene, a derivative thereof, an acridine, a derivative thereof, and an eosin derivative. Furthermore, a metal-containing porphyrin, such as a porphyrin containing magnesium (Mg), zinc (Zn), cadmium (Cd), tin (Sn), platinum (Pt), indium (In), or palladium (Pd), can be given as an example. Examples of the metal-containing porphyrin include a protoporphyrin-tin fluoride complex (SnF₂(Proto IX)), a mesoporphyrin-tin fluoride complex (SnF₂(Meso IX)), a hematoporphyrin-tin fluoride complex (SnF₂(Hemato IX)), a coproporphyrin tetramethyl ester-tin fluoride complex (SnF₂(Copro III-4Me)), an octaethylporphyrin-tin fluoride complex (SnF₂(OEP)), an etioporphyrin-tin fluoride complex (SnF₂(Etio I)), and an octaethylporphyrin-platinum chloride complex (PtCl₂OEP), which are represented by the following structural formulae.

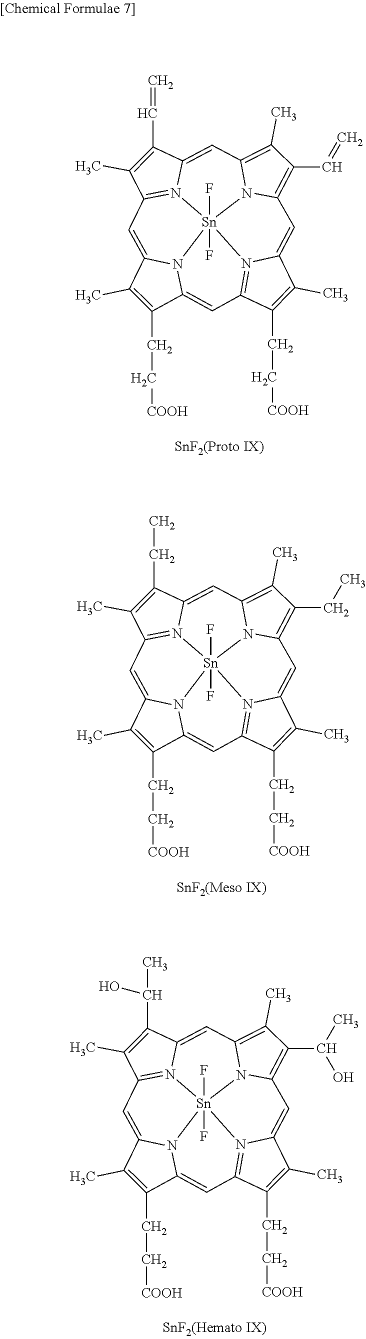

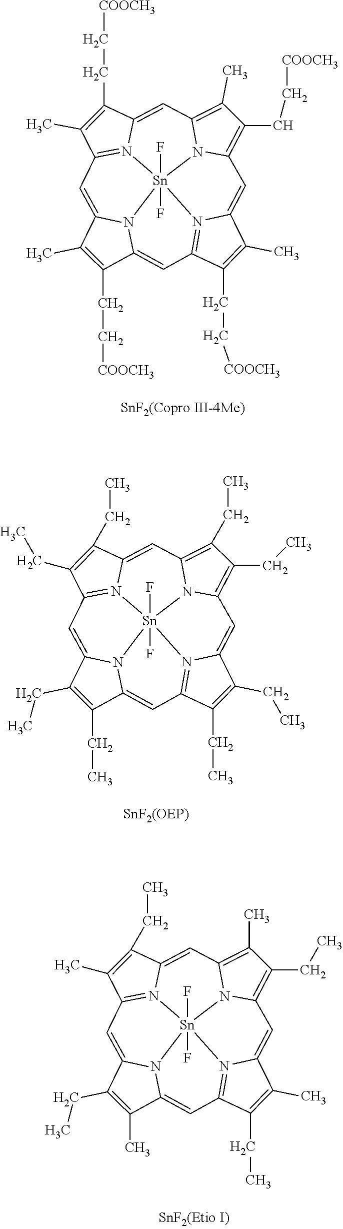

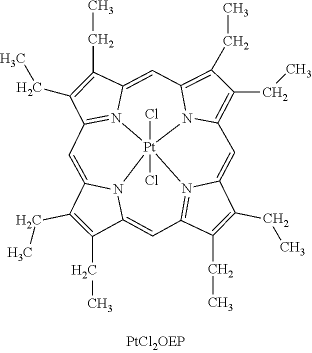

Alternatively, a heterocyclic compound having one or both of a π-electron rich heteroaromatic ring and a π-electron deficient heteroaromatic ring that is represented by the following structural formulae, such as 2-(biphenyl-4-yl)-4,6-bis(12-phenylindolo[2,3-a]carbazol-11-yl)-1,3,5-triazine (abbreviation: PIC-TRZ), 9-(4,6-diphenyl-1,3,5-triazin-2-yl)-9′-phenyl-9H,9′H-3,3′-bicarbazole (abbreviation: PCCzTzn), 2-{4-[3-(N-phenyl-9H-carbazol-3-yl)-9H-carbazol-9-yl]phenyl}-4,6-diphenyl-1,3,5-triazine (abbreviation: PCCzPTzn), 2-[4-(10H-phenoxazin-10-yl)phenyl]-4,6-diphenyl-1,3,5-triazine (abbreviation: PXZ-TRZ), 3-[4-(5-phenyl-5,10-dihydrophenazin-10-yl)phenyl]-4,5-diphenyl-1,2,4-triazole (abbreviation: PPZ-3TPT), 3-(9,9-dimethyl-9H-acridin-10-yl)-9H-xanthen-9-one (abbreviation: ACRXTN), bis[4-(9,9-dimethyl-9,10-dihydroacridine)phenyl]sulfone (abbreviation: DMAC-DPS), or 10-phenyl-10H,10′H-spiro[acridin-9,9′-anthracen]-10′-one (abbreviation: ACRSA) can be used. Such a heterocyclic compound is preferable because of having excellent electron-transport and hole-transport properties owing to a π-electron rich heteroaromatic ring and a π-electron deficient heteroaromatic ring. Among skeletons having a π-electron deficient heteroaromatic ring, a pyridine skeleton, a diazine skeleton (a pyrimidine skeleton, a pyrazine skeleton, or a pyridazine skeleton), and a triazine skeleton are particularly preferable because of their high stability and reliability. In particular, a benzofuropyrimidine skeleton, a benzothienopyrimidine skeleton, a benzofuropyrazine skeleton, and a benzothienopyrazine skeleton are preferable because of their high acceptor properties and high reliability. Among skeletons having the π-electron rich heteroaromatic ring, an acridine skeleton, a phenoxazine skeleton, a phenothiazine skeleton, a furan skeleton, a thiophene skeleton, and a pyrrole skeleton have high stability and reliability; thus, at least one of these skeletons is preferably included. A dibenzofuran skeleton and a dibenzothiophene skeleton are preferable as a furan skeleton and a thiophene skeleton, respectively. As a pyrrole skeleton, an indole skeleton, a carbazole skeleton, an indolocarbazole skeleton, a bicarbazole skeleton, and a 3-(9-phenyl-9H-carbazol-3-yl)-9H-carbazole skeleton are particularly preferable. Note that a substance in which the π-electron rich heteroaromatic ring is directly bonded to the π-electron deficient heteroaromatic ring is particularly preferable because the electron-donating property of the π-electron rich heteroaromatic ring and the electron-accepting property of the π-electron deficient heteroaromatic ring are both improved, the energy difference between the S1 level and the T1 level becomes small, and thus thermally activated delayed fluorescence can be obtained with high efficiency. Note that an aromatic ring to which an electron-withdrawing group such as a cyano group is bonded may be used instead of the π-electron deficient heteroaromatic ring. As a π-electron rich skeleton, an aromatic amine skeleton, a phenazine skeleton, or the like can be used. As a π-electron deficient skeleton, a xanthene skeleton, a thioxanthene dioxide skeleton, an oxadiazole skeleton, a triazole skeleton, an imidazole skeleton, an anthraquinone skeleton, a skeleton including boron such as phenylborane or boranthrene, an aromatic ring having a cyano group or a nitrile group such as benzonitrile or cyanobenzene, a heteroaromatic ring, a carbonyl skeleton such as benzophenone, a phosphine oxide skeleton, a sulfone skeleton, or the like can be used. As described above, a π-electron deficient skeleton and a π-electron rich skeleton can be used instead of at least one of the π-electron deficient heteroaromatic ring and the π-electron rich heteroaromatic ring.

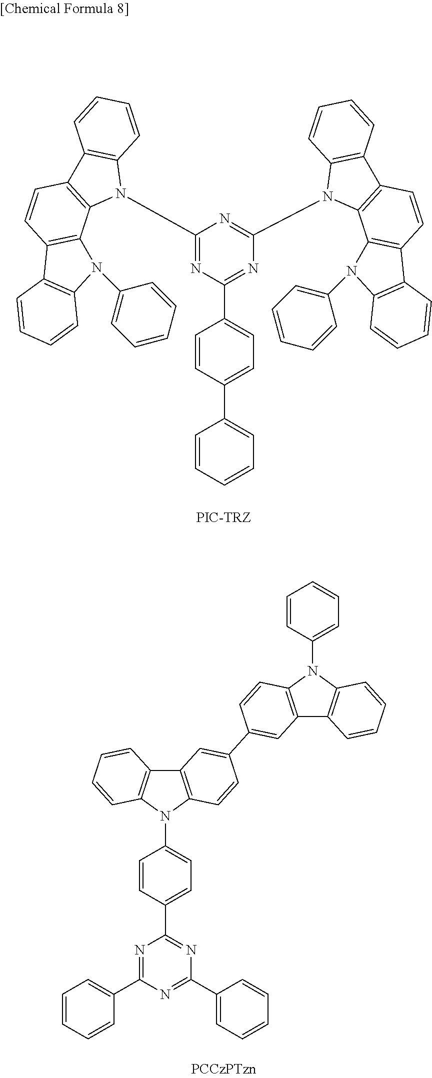 [SMILES: c1ccc(-c2ccc(-c3nc(-n4c5ccccc5c5ccc6c7ccccc7n(-c7ccccc7)c6c54)nc(-n4c5ccccc5c5ccc6c7ccccc7n(-c7ccccc7)c6c54)n3)cc2)cc1 ; c1ccc(-c2nc(-c3ccccc3)nc(-c3ccc(-n4c5ccccc5c5cc(-c6ccc7c(c6)c6ccccc6n7-c6ccccc6)ccc54)cc3)n2)cc1]

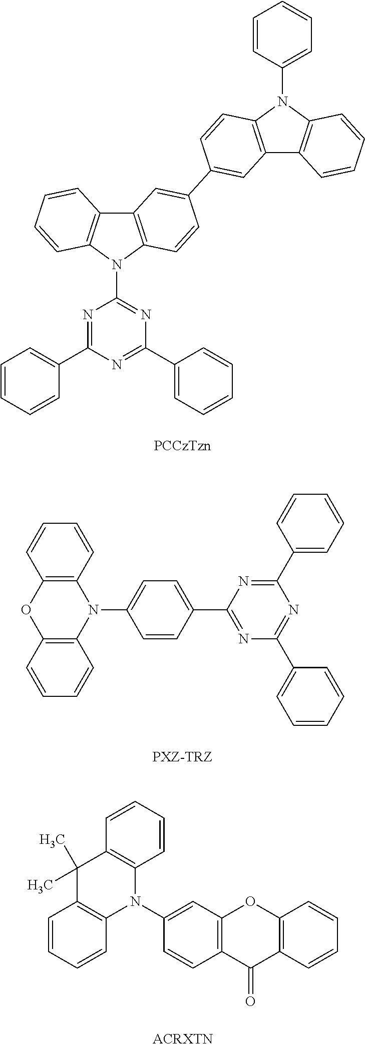 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2nc(-c3ccccc3)nc(-c3ccc(N4c5ccccc5Oc5ccccc54)cc3)n2)cc1 ; CC1(C)c2ccccc2N(c2ccc3c(=O)c4ccccc4oc3c2)c2ccccc21]

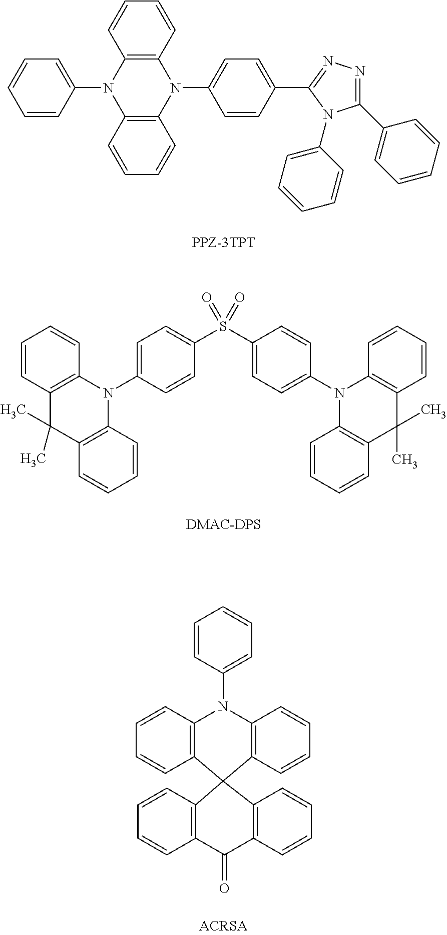 [SMILES: c1ccc(-c2nnc(-c3ccc(N4c5ccccc5N(c5ccccc5)c5ccccc54)cc3)n2-c2ccccc2)cc1 ; CC1(C)c2ccccc2N(c2ccc(S(=O)(=O)c3ccc(N4c5ccccc5C(C)(C)c5ccccc54)cc3)cc2)c2ccccc21 ; O=C1c2ccccc2C2(c3ccccc31)c1ccccc1N(c1ccccc1)c1ccccc12]

As the TADF material, a TADF material whose singlet excited state and triplet excited state are in a thermal equilibrium state may be used. Since such a TADF material enables a short emission lifetime (excitation lifetime), a decrease in efficiency of a light-emitting device in a high-luminance region can be inhibited. Specifically, a material having the following molecular structure can be used.

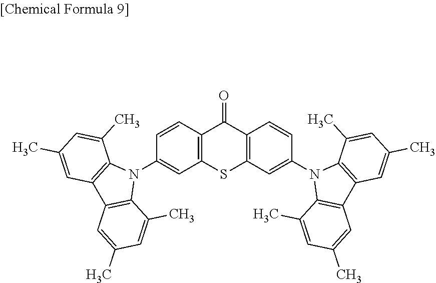

Note that a TADF material is a material having a small difference between the S1 level and the T1 level and a function of converting triplet excitation energy into singlet excitation energy by reverse intersystem crossing. Thus, it is possible to upconvert triplet excitation energy into singlet excitation energy (i.e., reverse intersystem crossing) using a small amount of thermal energy and efficiently generate a singlet excited state. In addition, the triplet excitation energy can be converted into luminescence.

An exciplex whose excited state is formed of two kinds of substances has an extremely small difference between the S1 level and the T1 level and has a function of a TADF material capable of converting triplet excitation energy into singlet excitation energy.

A phosphorescent spectrum observed at a low temperature (e.g., from 10 K to 77 K) is used for an index of the T1 level. When the level of energy with a wavelength of the line obtained by extrapolating a tangent to the fluorescent spectrum at a tail on the short wavelength side is the S1 level and the level of energy with a wavelength of the line obtained by extrapolating a tangent to the phosphorescent spectrum at a tail on the short wavelength side is the T1 level, the difference between the S1 level and the T1 level of the TADF material is preferably smaller than or equal to 0.3 eV, further preferably smaller than or equal to 0.2 eV.

When a TADF material is used as the light-emitting substance, the S1 level of the host material is preferably higher than the S1 level of the TADF material. In addition, the T1 level of the host material is preferably higher than the T1 level of the TADF material.

As the host material in the light-emitting layer, various carrier-transport materials such as the above-described TADF materials, and one or both of materials having an electron-transport property and materials having a hole-transport property can be used.

The material having a hole-transport property is preferably an organic compound having an amine skeleton, a π-electron rich heteroaromatic ring skeleton, or the like. Examples of the material include a compound having an aromatic amine skeleton, such as 4,4′-bis[N-(1-naphthyl)-N-phenylamino]biphenyl (abbreviation: NPB), N,N-diphenyl-N,N′-bis(3-methylphenyl)-4,4′-diaminobiphenyl (abbreviation: TPD), N,N-bis(9,9′-spirobi[9H-fluoren]-2-yl)-N,N-diphenyl-4,4′-diaminobiphenyl (abbreviation: BSPB), 4-phenyl-4′-(9-phenylfluoren-9-yl)triphenylamine (abbreviation: BPAFLP), 4-phenyl-3′-(9-phenylfluoren-9-yl)triphenylamine (abbreviation: mBPAFLP), 4-phenyl-4′-(9-phenyl-9H-carbazol-3-yl)triphenylamine (abbreviation: PCBA1BP), 4,4′-diphenyl-4″-(9-phenyl-9H-carbazol-3-yl)triphenylamine (abbreviation: PCBBi1BP), 4-(1-naphthyl)-4′-(9-phenyl-9H-carbazol-3-yl)triphenylamine (abbreviation: PCBANB), 4,4′-di(1-naphthyl)-4″-(9-phenyl-9H-carbazol-3-yl)triphenylamine (abbreviation: PCBNBB), 9,9-dimethyl-N-phenyl-N-[4-(9-phenyl-9H-carbazol-3-yl)phenyl]fluoren-2-amine (abbreviation: PCBAF), or N-phenyl-N-[4-(9-phenyl-9H-carbazol-3-yl)phenyl]-9,9′-spirobi[9H-fluoren]-2-amine (abbreviation: PCBASF); a compound having a carbazole skeleton, such as 1,3-bis(N-carbazolyl)benzene (abbreviation: mCP), 4,4′-di(N-carbazolyl)biphenyl (abbreviation: CBP), 3,6-bis(3,5-diphenylphenyl)-9-phenylcarbazole (abbreviation: CzTP), or 3,3′-bis(9-phenyl-9H-carbazole) (abbreviation: PCCP); a compound having a thiophene skeleton, such as 4,4′,4″-(benzene-1,3,5-triyl)tri(dibenzothiophene) (abbreviation: DBT3P-II), 2,8-diphenyl-4-[4-(9-phenyl-9H-fluoren-9-yl)phenyl]dibenzothiophene (abbreviation: DBTFLP-III), or 4-[4-(9-phenyl-9H-fluoren-9-yl)phenyl]-6-phenyldibenzothiophene (abbreviation: DBTFLP-IV); and a compound having a furan skeleton, such as 4,4′,4″-(benzene-1,3,5-triyl)tri(dibenzofuran) (abbreviation: DBF3P-II) or 4-{3-[3-(9-phenyl-9H-fluoren-9-yl)phenyl]phenyl}dibenzofuran (abbreviation: mmDBFFLBi-II). Among the above materials, the compound having an aromatic amine skeleton and the compound having a carbazole skeleton are preferable because these compounds are highly reliable and have high hole-transport properties to contribute to a reduction in driving voltage. In addition, the organic compounds given as examples of the material having a hole-transport property that can be used for the hole-transport layer can also be used.

As the material having an electron-transport property, for example, a metal complex such as bis(10-hydroxybenzo[h]quinolinato)beryllium(II) (abbreviation: BeBq₂), bis(2-methyl-8-quinolinolato)(4-phenylphenolato)aluminum(III) (abbreviation: BAlq), bis(8-quinolinolato)zinc(II) (abbreviation: Znq), bis[2-(2-benzoxazolyl)phenolato]zinc(II) (abbreviation: ZnPBO), or bis[2-(2-benzothiazolyl)phenolato]zinc(II) (abbreviation: ZnBTZ); or an organic compound having a π-electron deficient heteroaromatic ring is preferable. Examples of the organic compound having a π-electron deficient heteroaromatic ring include an organic compound having an azole skeleton, such as 2-(4-biphenylyl)-5-(4-tert-butylphenyl)-1,3,4-oxadiazole (abbreviation: PBD), 3-(4-biphenylyl)-4-phenyl-5-(4-tert-butylphenyl)-1,2,4-triazole (abbreviation: TAZ), 1,3-bis[5-(p-tert-butylphenyl)-1,3,4-oxadiazol-2-yl]benzene (abbreviation: OXD-7), 9-[4-(5-phenyl-1,3,4-oxadiazol-2-yl)phenyl]-9H-carbazole (abbreviation: CO11), 2,2′,2″-(1,3,5-benzenetriyl)tris(1-phenyl-1H-benzimidazole) (abbreviation: TPBI), 2-[3-(dibenzothiophen-4-yl)phenyl]-1-phenyl-1H-benzimidazole (abbreviation: mDBTBIm-II), or 4,4′-bis(5-methylbenzoxazol-2-yl)stilbene (abbreviation: BzOs); an organic compound having a heteroaromatic ring having a pyridine skeleton, such as 3,5-bis[3-(9H-carbazol-9-yl)phenyl]pyridine (abbreviation: 35DCzPPy), 1,3,5-tri[3-(3-pyridyl)phenyl]benzene (abbreviation: TmPyPB), bathophenanthroline (abbreviation: BPhen), bathocuproine (abbreviation: BCP), 2,9-di(naphthalen-2-yl)-4,7-diphenyl-1,10-phenanthroline (abbreviation: NBphen), 2,2′-(1,3-phenylene)bis(9-phenyl-1,10-phenanthroline) (abbreviation: mPPhen2P), or 2,2′-biphenyl-4,4′-diylbis(1,10-phenanthroline); an organic compound having a diazine skeleton, such as 2-[3-(dibenzothiophen-4-yl)phenyl]dibenzo[f,h]quinoxaline (abbreviation: 2mDBTPDBq-II), 2-[3-(3′-dibenzothiophen-4-yl)biphenyl]dibenzo[f,h]quinoxaline (abbreviation: 2mDBTBPDBq-II), 2-[3′-(9H-carbazol-9-yl)biphenyl-3-yl]dibenzo[f,h]quinoxaline (abbreviation: 2mCzBPDBq), 2-[4′-(9-phenyl-9H-carbazol-3-yl)-3,1′-biphenyl-1-yl]dibenzo[f,h]quinoxaline (abbreviation: 2mpPCBPDBq), 2-[4-(3,6-diphenyl-9H-carbazol-9-yl)phenyl]dibenzo[f,h]quinoxaline (abbreviation: 2CzPDBq-III), 7-[3-(dibenzothiophen-4-yl)phenyl]dibenzo[f,h]quinoxaline (abbreviation: 7mDBTPDBq-II), 6-[3-(dibenzothiophen-4-yl)phenyl]dibenzo[f,h]quinoxaline (abbreviation: 6mDBTPDBq-II), 9-[3′-(dibenzothiophen-4-yl)biphenyl-3-yl]naphtho[1′,2′:4,5]furo[2,3-b]pyrazine (abbreviation: 9mDBtBPNfpr), 9-[(3′-dibenzothiophen-4-yl)biphenyl-4-yl]naphtho[1′,2′:4,5]furo[2,3-b]pyrazine (abbreviation: 9pmDBtBPNfpr), 4,6-bis[3-(phenanthren-9-yl)phenyl]pyrimidine (abbreviation: 4,6mPnP2Pm), 4,6-bis[3-(4-dibenzothienyl)phenyl]pyrimidine (abbreviation: 4,6mDBTP2Pm-II), 4,6-bis[3-(9H-carbazol-9-yl)phenyl]pyrimidine (abbreviation: 4,6mCzP2Pm), 9,9′-[pyrimidine-4,6-diylbis(biphenyl-3,3′-diyl)]bis(9H-carbazole) (abbreviation: 4,6mCzBP2Pm), 8-(biphenyl-4-yl)-4-[3-(dibenzothiophen-4-yl)phenyl]-[1]benzofuro[3,2-d]pyrimidine (abbreviation: 8BP-4mDBtPBfpm), 3,8-bis[3-(dibenzothiophen-4-yl)phenyl]benzofuro[2,3-b]pyrazine (abbreviation: 3,8mDBtP2Bfpr), 4,8-bis[3-(dibenzothiophen-4-yl)phenyl]-[1]benzofuro[3,2-d]pyrimidine (abbreviation: 4,8mDBtP2Bfpm), 8-[3′-(dibenzothiophen-4-yl) (biphenyl-3-yl)]naphtho[1′,2′:4,5]furo[3,2-d]pyrimidine (abbreviation: 8mDBtBPNfpm), 8-[(2,2′-binaphthalen)-6-yl]-4-[3-(dibenzothiophen-4-yl)phenyl]-[1]benzofuro[3,2-d]pyrimidine (abbreviation: 8(βN2)-4mDBtPBfpm), 2,2′-(pyridine-2,6-diyl)bis(4-phenylbenzo[h]quinazoline) (abbreviation: 2,6(P-Bqn)2Py), 2,2′-(pyridine-2,6-diyl)bis{4-[4-(2-naphthyl)phenyl]-6-phenylpyrimidine}(abbreviation: 2,6(NP-PPm)2Py), 6-(biphenyl-3-yl)-4-[3,5-bis(9H-carbazol-9-yl)phenyl]-2-phenylpyrimidine (abbreviation: 6mBP-4Cz2PPm), 2,6-bis(4-naphthalen-1-ylphenyl)-4-[4-(3-pyridyl)phenyl]pyrimidine (abbreviation: 2,4NP-6PyPPm), 4-[3,5-bis(9H-carbazol-9-yl)phenyl]-2-phenyl-6-(biphenyl-4-yl)pyrimidine (abbreviation: 6BP-4Cz2PPm), or 7-[4-(9-phenyl-9H-carbazol-2-yl)quinazolin-2-yl]-7H-dibenzo[c,g]carbazole (abbreviation: PC-cgDBCzQz); and an organic compound having a heteroaromatic ring having a triazine skeleton, such as 2-(biphenyl-4-yl)-4-phenyl-6-(9,9′-spirobi[9H-fluoren]-2-yl)-1,3,5-triazine (abbreviation: BP-SFTzn), 2-{3-[3-(benzo[b]naphtho[1,2-d]furan-8-yl)phenyl]phenyl}-4,6-diphenyl-1,3,5-triazine (abbreviation: mBnfBPTzn), 2-{3-[3-(benzo[b]naphtho[1,2-d]furan-6-yl)phenyl]phenyl}-4,6-diphenyl-1,3,5-triazine (abbreviation: mBnfBPTzn-02), 2-{4-[3-(N-phenyl-9H-carbazol-3-yl)-9H-carbazol-9-yl]phenyl}-4,6-diphenyl-1,3,5-triazine (abbreviation: PCCzPTzn), 9-[3-(4,6-diphenyl-1,3,5-triazin-2-yl)phenyl]-9′-phenyl-2,3′-bi-9H-carbazole (abbreviation: mPCCzPTzn-02), 2-[3′-(9,9-dimethyl-9H-fluoren-2-yl)-biphenyl-3-yl]-4,6-diphenyl-1,3,5-triazine (abbreviation: mFBPTzn), 5-[3-(4,6-diphenyl-1,3,5-triazin-2-yl)phenyl]-7,7-dimethyl-5H,7H-indeno[2,1-b]carbazole (abbreviation: mINc(II)PTzn), 2-{3-[3-(dibenzothiophen-4-yl)phenyl]phenyl}-4,6-diphenyl-1,3,5-triazine (abbreviation: mDBtBPTzn), 2,4,6-tris[3′-(pyridin-3-yl)biphenyl-3-yl]-1,3,5-triazine (abbreviation: TmPPPyTz), 2-[3-(2,6-dimethyl-3-pyridinyl)-5-(9-phenanthrenyl)phenyl]-4,6-diphenyl-1,3,5-triazine (abbreviation: mPn-mDMePyPTzn), 11-(4-biphenyl-4-yl-6-phenyl-1,3,5-triazin-2-yl)-11,12-dihydro-12-phenyl-indolo(2,3-a)carbazole (abbreviation: BP-Icz(II)Tzn), 2-[3′-(triphenylen-2-yl)-biphenyl-3-yl]-4,6-diphenyl-1,3,5-triazine (abbreviation: mTpBPTzn), 3-[9-(4,6-diphenyl-1,3,5-triazin-2-yl)-2-dibenzofuranyl]-9-phenyl-9H-carbazole (abbreviation: PCDBfTzn), or 2-biphenyl-3-yl-4-phenyl-6-[8-(1,1′:4′,1″-terphenyl)-4-yl-1-dibenzofuranyl]-1,3,5-triazine (abbreviation: mBP-TPDBfTzn). Among the above materials, the organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage.

As the TADF material that can be used as the host material, the above materials mentioned as the TADF material can also be used. When the TADF material is used as the host material, triplet excitation energy generated in the TADF material is converted into singlet excitation energy by reverse intersystem crossing and transferred to the light-emitting substance, whereby the emission efficiency of the light-emitting device can be increased. Here, the TADF material functions as an energy donor, and the light-emitting substance functions as an energy acceptor.

This is very effective in the case where the light-emitting substance is a fluorescent substance. In that case, the S1 level of the TADF material is preferably higher than the S1 level of the fluorescent substance in order that high emission efficiency be achieved. Furthermore, the T1 level of the TADF material is preferably higher than the S1 level of the fluorescent substance. Thus, the T1 level of the TADF material is preferably higher than the T1 level of the fluorescent substance.

It is also preferable to use a TADF material that emits light whose wavelength overlaps with the wavelength on a lowest-energy-side absorption band of the fluorescent substance. This enables smooth transfer of excitation energy from the TADF material to the fluorescent substance and accordingly enables efficient light emission, which is preferable.

In addition, in order to efficiently generate singlet excitation energy from the triplet excitation energy by reverse intersystem crossing, carrier recombination preferably occurs in the TADF material. It is also preferable that the triplet excitation energy generated in the TADF material not be transferred to the triplet excitation energy of the fluorescent substance. For that reason, the fluorescent substance preferably has a protecting group around a luminophore (a skeleton which causes light emission) of the fluorescent substance. As the protecting group, a substituent having no π bond and a saturated hydrocarbon are preferably used. Specific examples include an alkyl group having 3 to 10 carbon atoms, a substituted or unsubstituted cycloalkyl group having 3 to 12 carbon atoms, and a trialkylsilyl group having 3 to 10 carbon atoms. It is further preferable that the fluorescent substance have a plurality of protecting groups. The substituents having no π bond are poor in carrier-transport performance; thus, the TADF material and the luminophore of the fluorescent substance can be made away from each other with little influence on carrier-transportation or carrier recombination. Here, the luminophore refers to an atomic group (skeleton) that causes light emission in a fluorescent substance. The luminophore is preferably a skeleton having a π bond, further preferably includes an aromatic ring, and still further preferably includes a condensed aromatic ring or a condensed heteroaromatic ring. Examples of such a luminophore include a phenanthrene skeleton, a stilbene skeleton, an acridone skeleton, a phenoxazine skeleton, and a phenothiazine skeleton. Specifically, a fluorescent substance having any of a naphthalene skeleton, an anthracene skeleton, a fluorene skeleton, a chrysene skeleton, a triphenylene skeleton, a tetracene skeleton, a pyrene skeleton, a perylene skeleton, a coumarin skeleton, a quinacridone skeleton, and a naphthobisbenzofuran skeleton is preferable because of its high fluorescence quantum yield.

In the case where a fluorescent substance is used as the light-emitting substance, a material having an anthracene skeleton is suitably used as the host material. The use of a substance having an anthracene skeleton as the host material for the fluorescent substance makes it possible to obtain a light-emitting layer with high emission efficiency and high durability. As the substance having an anthracene skeleton that is used as the host material, a substance having a diphenylanthracene skeleton, in particular, a substance having a 9,10-diphenylanthracene skeleton, is chemically stable and thus is preferably used. The host material preferably has a carbazole skeleton because the hole-injection and hole-transport properties are improved; further preferably, the host material has a benzocarbazole skeleton in which a benzene ring is further condensed to carbazole skeleton because the HOMO level thereof is higher than the host material having a carbazole skeleton by approximately 0.1 eV and thus holes enter the host material easily. In particular, the host material preferably has a dibenzocarbazole skeleton because the HOMO level thereof is higher than the host material having a carbazole skeleton by approximately 0.1 eV so that holes enter the host material easily, the hole-transport property is improved, and the heat resistance is increased. Accordingly, a substance that has both a 9,10-diphenylanthracene skeleton and a carbazole skeleton (or a benzocarbazole skeleton or a dibenzocarbazole skeleton) is further preferable as the host material. Note that in terms of the hole-injection and hole-transport properties described above, instead of a carbazole skeleton, a benzofluorene skeleton or a dibenzofluorene skeleton may be used. Examples of such a substance include 9-phenyl-3-[4-(10-phenyl-9-anthryl)phenyl]-9H-carbazole (abbreviation: PCzPA), 3-[4-(1-naphthyl)phenyl]-9-phenyl-9H-carbazole (abbreviation: PCPN), 9-[4-(10-phenyl-9-anthracenyl)phenyl]-9H-carbazole (abbreviation: CzPA), 7-[4-(10-phenyl-9-anthryl)phenyl]-7H-dibenzo[c,g]carbazole (abbreviation: cgDBCzPA), 6-[3-(9,10-diphenyl-2-anthryl)phenyl]benzo[b]naphtho[1,2-d]furan (abbreviation: 2mBnfPPA), 9-phenyl-10-[4-(9-phenyl-9H-fluoren-9-yl)biphenyl-4′-yl]anthracene (abbreviation: FLPPA), 9-(1-naphthyl)-10-[4-(2-naphthyl)phenyl]anthracene (abbreviation: αN-βNPAnth), 9-(1-naphthyl)-10-(2-naphthyl)anthracene (abbreviation: α,βADN), 2-(10-phenylanthracen-9-yl)dibenzofuran, 2-(10-phenyl-9-anthracenyl)benzo[b]naphtho[2,3-d]furan (abbreviation: Bnf(II)PhA), 9-(2-naphthyl)-10-[3-(2-naphthyl)phenyl]anthracene (abbreviation: βN-mβNPAnth), and 1-[4-(10-biphenyl-4-yl-9-anthracenyl)phenyl]-2-ethyl-1H-benzimidazole (abbreviation: EtBImPBPhA). In particular, CzPA, cgDBCzPA, 2mBnfPPA, and PCzPA exhibit excellent properties and thus are preferably selected.

The host material may be a mixture of a plurality of kinds of substances; in the case of using a mixed host material, it is preferable to mix a material having an electron-transport property with a material having a hole-transport property. By mixing the material having an electron-transport property with the material having a hole-transport property, the transport property of the light-emitting layer 113 can be easily adjusted and a recombination region can be easily controlled. The weight ratio of the content of the material having a hole-transport property to the content of the material having an electron-transport property may be 1:19 to 19:1.

Note that a phosphorescent substance can be used as part of the mixed material. When a fluorescent substance is used as the light-emitting substance, the phosphorescent substance can be used as an energy donor for supplying excitation energy to the fluorescent substance.

An exciplex may be formed of these mixed materials. These mixed materials are preferably selected so as to form an exciplex that exhibits light emission overlapping with the wavelength of a lowest-energy-side absorption band of the light-emitting substance, in which case energy can be transferred smoothly and light emission can be obtained efficiently. The use of such a structure is preferable because the driving voltage can also be reduced.

At least one of the materials forming an exciplex may be a phosphorescent substance. In this case, triplet excitation energy can be efficiently converted into singlet excitation energy by reverse intersystem crossing.

Combination of a material having an electron-transport property and a material having a hole-transport property whose HOMO level is higher than or equal to that of the material having an electron-transport property is preferable for forming an exciplex efficiently. In addition, the LUMO level of the material having a hole-transport property is preferably higher than or equal to the LUMO level of the material having an electron-transport property. Note that the LUMO level and the HOMO level of the material can be derived from the electrochemical characteristics (the reduction potential and the oxidation potential) of the material that are measured by cyclic voltammetry (CV).

The formation of an exciplex can be confirmed by a phenomenon in which the emission spectrum of a mixed film in which the hole-transport material and the electron-transport material are mixed is shifted to a longer wavelength than the emission spectrum of each of the materials (or has another peak on the longer wavelength side) observed in comparison of the emission spectrum of the hole-transport material, the emission spectrum of the electron-transport material, and the emission spectrum of the mixed film of these materials, for example. Alternatively, the formation of an exciplex can be confirmed by a difference in transient response, such as a phenomenon in which the transient photoluminescence (PL) lifetime of the mixed film has longer lifetime components or has a larger proportion of delayed components than the transient PL lifetime of each of the materials, observed in comparison of the transient PL of the hole-transport material, the transient PL of the electron-transport material, and the transient PL of the mixed film of these materials. The transient PL can be rephrased as transient electroluminescence (EL). That is, the formation of an exciplex can also be confirmed by a difference in transient response observed in comparison of the transient EL of the hole-transport material, the transient EL of the electron-transport material, and the transient EL of the mixed film of these materials.

The electron-transport layer 114 is a layer including a substance having an electron-transport property. The material having an electron-transport property is preferably a substance having an electron mobility higher than or equal to 1×10⁻⁷ cm²/Vs, further preferably higher than or equal to 1×10⁻⁶ cm²/Vs in the case where the square root of the electric field strength [V/cm] is 600. Note that any other substance can also be used as long as the substance has an electron-transport property higher than a hole-transport property. An organic compound having a π-electron deficient heteroaromatic ring is preferable as the above organic compound. The organic compound having a π-electron deficient heteroaromatic ring is preferably one or more of an organic compound having a heteroaromatic ring having a polyazole skeleton, an organic compound having a heteroaromatic ring having a pyridine skeleton, an organic compound having a heteroaromatic ring having a diazine skeleton, and an organic compound having a heteroaromatic ring having a triazine skeleton.

As the organic compound having an electron-transport property that can be used in the above-described electron-transport layer, the above described material having an electron-transport property and the organic compound that can be used as the organic compound having an electron-transport property in the electron injection buffer region in the layer 116 can be similarly used. Among the above materials, the organic compound having a heteroaromatic ring having a diazine skeleton, the organic compound having a heteroaromatic ring having a pyridine skeleton, and the organic compound having a heteroaromatic ring having a triazine skeleton have high reliability and thus are preferable. In particular, the organic compound having a heteroaromatic ring having a diazine (pyrimidine or pyrazine) skeleton and the organic compound having a heteroaromatic ring having a triazine skeleton have a high electron-transport property to contribute to a reduction in driving voltage.

The electron mobility of the electron-transport layer in the case where the square root of the electric field strength [V/cm] is 600 is preferably higher than or equal to 1×10⁻⁷ cm²/Vs and lower than or equal to 5×10⁻⁵ cm²/Vs. The amount of electrons injected into the light-emitting layer can be controlled by the reduction in the electron-transport property of the electron-transport layer 114, whereby the light-emitting layer can be prevented from having excess electrons. It is particularly preferable to employ this structure when the hole-injection layer is formed using a composite material that includes a material having a hole-transport property with a relatively low HOMO level higher than or equal to −5.7 eV and lower than or equal to −5.4 eV, in which case a long lifetime can be achieved. In this case, the material having an electron-transport property preferably has a HOMO level higher than or equal to −6.0 eV.

As an electron-injection layer 115, a layer including an alkali metal or an alkaline earth metal such as lithium fluoride (LiF), cesium fluoride (CsF), calcium fluoride (CaF₂), 8-hydroxyquinolinato-lithium (abbreviation: Liq), ytterbium (Yb), a compound thereof, or a complex thereof may be used, in addition to the above-described organic compound having a basic skeleton. An electride or a layer that is formed using a substance having an electron-transport property and that contains an alkali metal, an alkaline earth metal, or a compound thereof may be used as the electron-injection layer 115. Examples of the electride include a substance in which electrons are added at high concentration to calcium oxide-aluminum oxide.

Note that as the electron-injection layer 115, it is possible to use a layer containing a substance that has an electron-transport property (preferably an organic compound having a bipyridine skeleton) and includes a fluoride of the alkali metal or the alkaline earth metal at a concentration higher than or equal to that at which the electron-injection layer 115 becomes in a microcrystalline state (50 wt % or higher). Since the layer has a low refractive index, a light-emitting device having higher external quantum efficiency can be provided.

Any of a variety of methods can be used for forming the organic compound layer 103, regardless of whether it is a dry process or a wet process. For example, a vacuum evaporation method, a gravure printing method, an offset printing method, a screen printing method, an ink-jet method, a spin coating method, or the like may be used.

Different film formation methods may be used to form the electrodes or the layers described above.

Note that the structure of the light-emitting device included in the light-emitting apparatus of one embodiment of the present invention is not limited by the light-emitting device 130 in FIG. 1A and the light-emitting device 130A in FIG. 1B. As in a light-emitting device 130USD illustrated in FIG. 1C, for example, in the light-emitting device included in the light-emitting apparatus of one embodiment of the present invention, the layer 116 may be provided over the cathode 102, the organic compound layer 103 may be provided over the layer 116, the anode 101 may be provided over the organic compound layer 103, and the light LGT generated in the light-emitting layer 113 included in the organic compound layer 103 may be emitted from the anode 101 side.

In the light-emitting device 130USD in FIG. 1C, the layer 116 includes the electron-injection buffer region 119, the electron-relay region 118, and the charge-generation region 117 like the layer 116 in the light-emitting device 130 in FIG. 1A. Note that in the layer 116 of the light-emitting device 130USD, the charge-generation region 117 is positioned over the cathode 102, the electron-relay region 118 is positioned over the charge-generation region 117, and the electron-injection buffer region 119 is positioned over the electron-relay region 118.

In the light-emitting device 130USD in FIG. 1C, the light-emitting unit 501 includes the hole-injection layer 111, the hole-transport layer 112, the light-emitting layer 113, and the electron-transport layer 114, as in the organic compound layer 103 in the light-emitting device 130 in FIG. 1A. Note that in the organic compound layer 103 of the light-emitting device 130USD, the electron-transport layer 114 is positioned over the electron-injection buffer region 119 of the layer 116, the light-emitting layer 113 is positioned over the electron-transport layer 114, the hole-transport layer 112 is positioned over the light-emitting layer 113, and the hole-injection layer 111 is positioned over the hole-transport layer 112.

In the light-emitting device 130USD, for example, the light LGT generated in the light-emitting layer 113 is emitted to the upper side of the light-emitting device 130USD through the cathode 102. Note that in that case, when a transparent electrode is used as the anode 101, the visible light (e.g., a wavelength greater than or equal to 400 nm and less than 750 nm) transmittance of the transparent electrode is preferably higher than or equal to 40%. In the case where a transflective electrode is used as the anode 101, the reflectance of the transflective electrode is preferably higher than or equal to 10% and lower than or equal to 95%, further preferably higher than or equal to 30% and lower than or equal to 80%. Note that the light-emitting device 130USD may be a dual-emission light-emitting device which emits light to not only the upper side of the light-emitting device 130 through the anode 101 but also the lower side of the light-emitting device through the cathode 102 (not illustrated).

The light-emitting device included in the light-emitting apparatus of one embodiment of the present invention may have a structure in which the electron-relay region 118 is not provided in the light-emitting device 130USD in FIG. 1C, as in a light-emitting device 130USDA in FIG. 1D, for example.

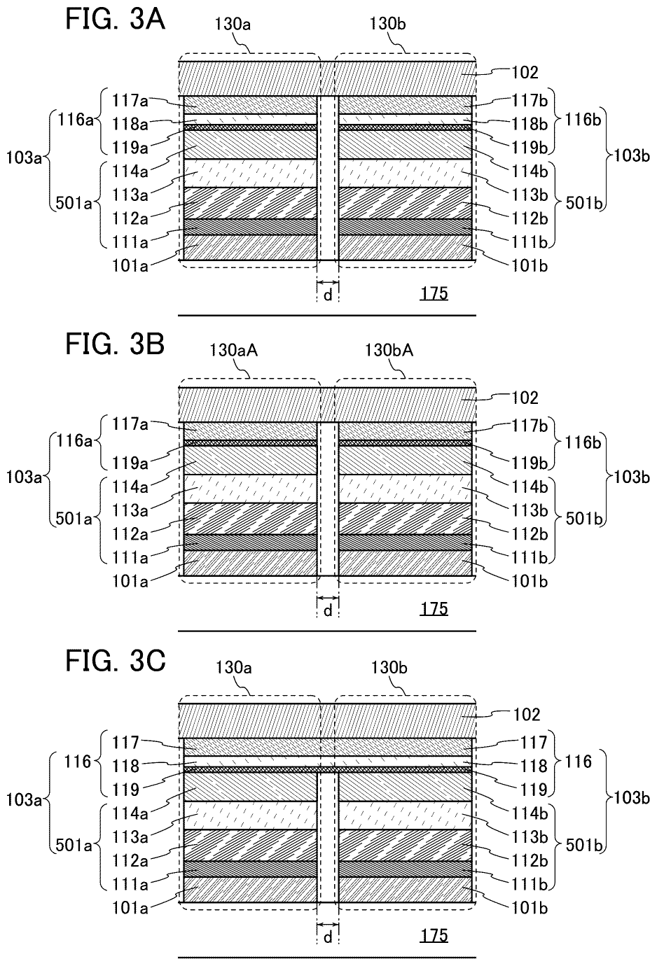

In the light-emitting apparatus of one embodiment of the present invention, adjacent light-emitting devices may share various functional layers such as a hole-injection layer, a hole-transport layer, an electron-transport layer, an electron-injection layer, a carrier-blocking layer (e.g., a hole-blocking layer or an electron-blocking layer), and an exciton-blocking layer, for example. As one example, FIG. 3A illustrates two adjacent light-emitting devices (a light-emitting device 130a and a light-emitting device 130b) included in the light-emitting apparatus of one embodiment of the present invention.

The light-emitting device 130a includes an organic compound layer 103a between an anode 101a and the cathode 102 over an insulating layer 175. The organic compound layer 103a has a structure in which a light-emitting unit 501a and a layer 116a are stacked. Although FIG. 3A illustrates an example in which one light-emitting device includes one light-emitting unit, one light-emitting device may include two or more light-emitting units which are stacked. The light-emitting unit 501a includes a hole-injection layer 111a, a hole-transport layer 112a, a light-emitting layer 113a, and an electron-transport layer 114a. The layer 116a includes a charge-generation region 117a, an electron-relay region 118a, and an electron-injection buffer region 119a.

The light-emitting device 130b includes an organic compound layer 103b between an anode 101b and the cathode 102 over the insulating layer 175. The organic compound layer 103b has a structure in which a light-emitting unit 501b and a layer 116b are stacked. Although FIG. 3A illustrates an example in which one light-emitting device includes one light-emitting unit, one light-emitting device may include two or more light-emitting units which are stacked. The light-emitting unit 501b includes a hole-injection layer 111b, a hole-transport layer 112b, a light-emitting layer 113b, and an electron-transport layer 114b. The layer 116b includes a charge-generation region 117b, an electron-relay region 118b, and an electron-injection buffer region 119b. Note that the electron-relay region 118b is not necessarily provided in the light-emitting device 130b.

Note that the electron-relay region 118a is not necessarily provided in the light-emitting device 130a. Similarly, the electron-relay region 118b is not necessarily provided in the light-emitting device 130b. For example, as in two adjacent light-emitting devices (a light-emitting device 130aA and a light-emitting device 130bA) illustrated in FIG. 3B, the layer 116a does not necessarily include the electron-relay region 118a and the layer 116b does not necessarily include the electron-relay region 118b.

In FIG. 3A, the cathode 102 is preferably one continuous layer shared by the light-emitting device 130a and the light-emitting device 130b. In addition, in FIG. 3A, the layer 116a and the layer 116b may be one layer shared by the light-emitting device 130a and the light-emitting device 130b. Specifically, as illustrated in FIG. 3C, each of the electron-injection buffer region 119, the electron-relay region 118, and the charge-generation region 117 may be one continuous layer shared by the light-emitting device 130a and the light-emitting device 130b. Note that in the layer 116, only the electron-relay region 118 and the charge-generation region 117 may each be one shared layer, or only the charge-generation region 117 may be one shared layer (neither case is illustrated).

In the light-emitting device 130a and the light-emitting device 130b in FIG. 3C, the organic compound layer 103a and the organic compound layer 103b except for the electron-injection layer 116 are processed by a lithography method after the formation of the electron-transport layer 114a and after the formation of the electron-transport layer 114b, respectively; thus, the organic compound layer 103a and the organic compound layer 103b are independent of each other. Furthermore, since edge portions (contours) of the organic compound layer 103a except for the layer 116 are processed by a lithography method, the edge portions are aligned or substantially aligned in the direction perpendicular to the substrate. Since edge portions (contours) of the organic compound layer 103b except for the layer 116 are processed by a lithography method, the edge portions are aligned or substantially aligned in the direction perpendicular to the substrate.

Since the organic compound layers are processed by a lithography method, a distance d between the anode 101a and the anode 101b can be smaller than that of the case where the organic compound layers are formed through mask vapor deposition. The distance d can be more than or equal to 2 μm and less than or equal to 5 μm. An insulating layer can be provided between the anode 101a and the anode 101b, and the insulating layer is in contact with the cathode 102 or the layer 116.

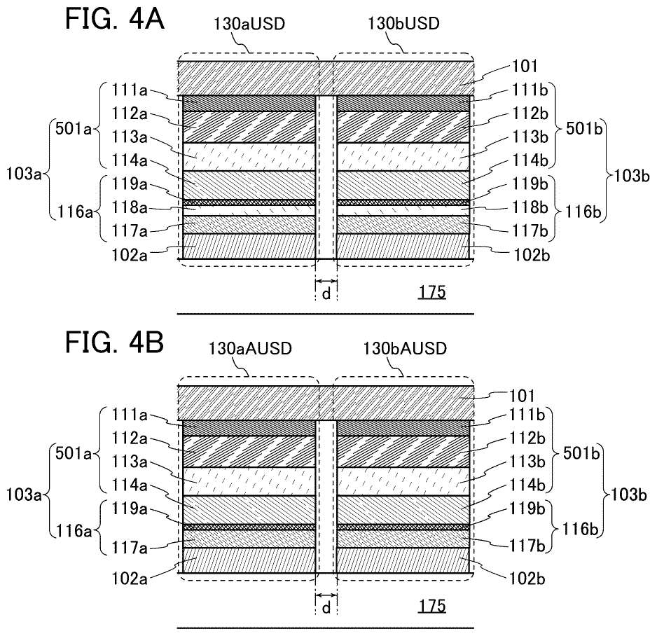

Note that in the light-emitting device 130a and the light-emitting device 130b in FIG. 3A, the anode 101a and the anode 101b may be one continuous layer shared by the light-emitting devices, and the cathode 102 may be formed for each light-emitting device. For example, as in a light-emitting device 130aUSD illustrated in FIG. 4A, a cathode 102a may be provided over the insulating layer 175, the layer 116a (the charge-generation region 117a, the electron-relay region 118a, and the electron-injection buffer region 119a) may be provided over the cathode 102a, the light-emitting unit 501a (the electron-transport layer 114a, the light-emitting layer 113a, the hole-transport layer 112a, and the hole-injection layer 11a) may be provided over the layer 116a, and the anode 101 may be provided over the organic compound layer 103a. Similarly, as in a light-emitting device 130bUSD illustrated in FIG. 4A, a cathode 102b may be provided over the insulating layer 175, the layer 116b (the charge-generation region 117b, the electron-relay region 118b, and the electron-injection buffer region 119b) may be provided over the cathode 102b, the light-emitting unit 501b (the electron-transport layer 114b, the light-emitting layer 113b, the hole-transport layer 112b, and the hole-injection layer 111b) may be provided over the layer 116b, and the anode 101 may be provided over the organic compound layer 103b. That is, the light-emitting device 130aUSD and the light-emitting device 130bUSD illustrated in FIG. 4A have a structure where the stacking order of the functional layers in each of the light-emitting device 130a and the light-emitting device 130b illustrated in FIG. 3A is reversed.

In the light-emitting device 130aA and the light-emitting device 130bA in FIG. 3B, as described above, the anode 101a and the anode 101b may be one continuous layer shared by the light-emitting devices, the cathode 102 may be formed for each light-emitting device, and the stacking order of the functional layers may be reversed. For example, as in a light-emitting device 130aAUSD illustrated in FIG. 4B, the cathode 102a may be provided over the insulating layer 175, the layer 116a (the charge-generation region 117a and the electron-injection buffer region 119a) may be provided over the cathode 102a, the light-emitting unit 501a (the electron-transport layer 114a, the light-emitting layer 113a, the hole-transport layer 112a, and the hole-injection layer 111a) may be provided over the layer 116a, and the anode 101 may be provided over the organic compound layer 103a. Similarly, as in a light-emitting device 130bAUSD illustrated in FIG. 4B, the cathode 102b may be provided over the insulating layer 175, the layer 116b (the charge-generation region 117b and the electron-injection buffer region 119b) may be provided over the cathode 102b, the light-emitting unit 501b (the electron-transport layer 114b, the light-emitting layer 113b, the hole-transport layer 112b, and the hole-injection layer 111b) may be provided over the layer 116b, and the anode 101 may be provided over the organic compound layer 103b.

The structure of this embodiment can be used in combination with any of the other structures as appropriate.

### Embodiment 2

When a plurality of the light-emitting devices 130 (in addition to the light-emitting devices 130, the light-emitting devices 130A, 130USD, 130USDA, 130a, 130b, 130aA, 130bA, 130aUSD, 130bUSD, 130aAUSD, and 130bAUSD are collectively referred to as the light-emitting devices 130) described in the above embodiment are formed over the insulating layer 175, the light-emitting apparatus is formed. In this embodiment, the light-emitting apparatus of one embodiment of the present invention will be described in detail.

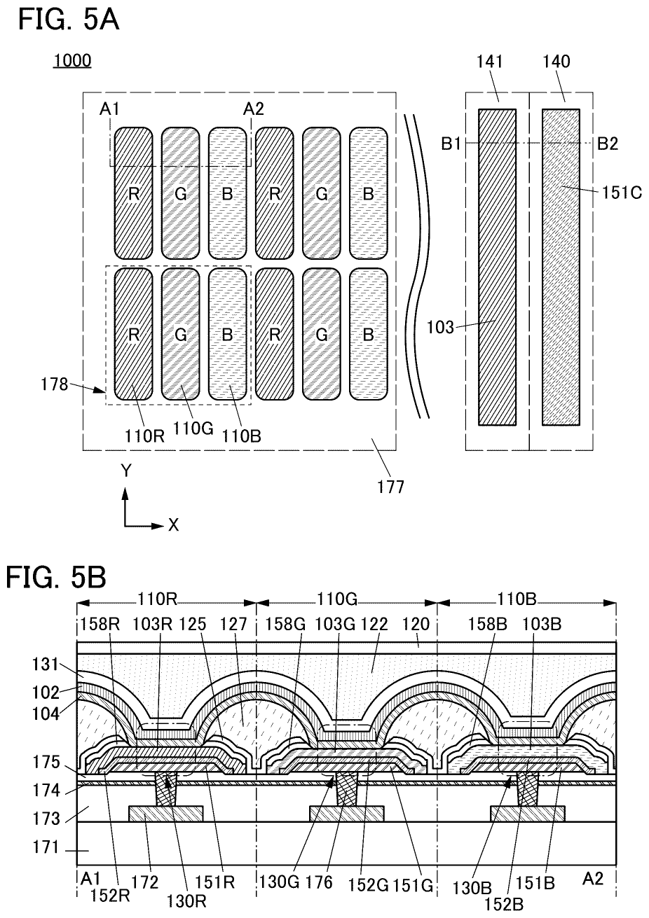

As illustrated in FIG. 5A and FIG. 5B, a light-emitting apparatus 1000 includes a pixel portion 177 in which a plurality of pixels 178 are arranged in matrix. The pixel 178 includes a subpixel 110R, a subpixel 110G, and a subpixel 110B.

In this specification and the like, for example, matters common to the subpixel 110R, the subpixel 110G, and the subpixel 110B are sometimes described using the collective term “subpixel 110”. As for components that are distinguished from each other using letters of the alphabet, matters common to the components are sometimes described using reference numerals excluding the letters of the alphabet.

The subpixel 110R emits red light, the subpixel 110G emits green light, and the subpixel 110B emits blue light. Thus, an image that can be represented in red, green, and blue can be displayed on the pixel portion 177. Note that in this embodiment, three colors of red (R), green (G), and blue (B) are given as examples of colors of light emitted by subpixels; however, the structure of the present invention is not limited to this structure. That is, subpixels of a different combination of colors may be employed. The number of subpixels is not limited to three, and four or more subpixels may be used, for example. Examples of four subpixels include subpixels emitting light of four colors of R, G, B, and white (W), subpixels emitting light of four colors of R, G, B, and yellow (Y), and four subpixels emitting light of R, G, B, and infrared light (IR).

In this specification and the like, the row direction and the column direction are sometimes referred to as the X direction and the Y direction, respectively. The X direction and the Y direction intersect with each other and are perpendicular or substantially perpendicular to each other, for example.

FIG. 5A illustrates an example where subpixels of different colors are arranged in the X direction and subpixels of the same color are arranged in the Y direction. Note that subpixels of different colors may be arranged in the Y direction, and subpixels of the same color may be arranged in the X direction.

A connection portion 140 and a region 141 may be provided outside the pixel portion 177. The region 141 is preferably positioned between the pixel portion 177 and the connection portion 140, for example. The organic compound layer 103 is provided in the region 141. A conductive layer 151C is provided in the connection portion 140.

Although FIG. 5A illustrates an example where the region 141 and the connection portion 140 are positioned on the right side of the pixel portion 177, the positions of the region 141 and the connection portion 140 are not particularly limited. The number of the regions 141 and the number of the connection portions 140 can each be one or more.

FIG. 5B is an example of a cross-sectional view taken along a dashed-dotted line A1-A2 in FIG. 5A. As illustrated in FIG. 5B, the light-emitting apparatus 1000 includes an insulating layer 171, a conductive layer 172 over the insulating layer 171, an insulating layer 173 over the insulating layer 171 and the conductive layer 172, an insulating layer 174 over the insulating layer 173, and the insulating layer 175 over the insulating layer 174. The insulating layer 171 is preferably provided over a substrate (not illustrated). An opening reaching the conductive layer 172 is provided in the insulating layer 175, the insulating layer 174, and the insulating layer 173, and a plug 176 is provided to fill the opening.

In the pixel portion 177, the light-emitting device 130 is provided over the insulating layer 175 and the plug 176. A protective layer 131 is provided to cover the light-emitting device 130. A substrate 120 is bonded to the protective layer 131 with a resin layer 122. An inorganic insulating layer 125 and an insulating layer 127 over the inorganic insulating layer 125 may be provided between adjacent light-emitting devices 130.

Although FIG. 5B illustrates a plurality of cross sections of an inorganic insulating layer 125 and an insulating layer 127, the inorganic insulating layer 125 and the insulating layer 127 are each preferably a continuous layer when the light-emitting apparatus 1000 is seen from above. That is, the insulating layer 127 is preferably a layer having openings above an anode.

In FIG. 5B, a light-emitting device 130R, a light-emitting device 130G, and a light-emitting device 130B are illustrated as the light-emitting device 130. The light-emitting device 130R, the light-emitting device 130G, and the light-emitting device 130B emit light of different colors. For example, the light-emitting device 130R can emit red light, the light-emitting device 130G can emit green light, and the light-emitting device 130B can emit blue light. Alternatively, the light-emitting device 130R, the light-emitting device 130G, or the light-emitting device 130B may emit visible light of another color or infrared light.

Note that the organic compound layer 103 at least includes a light-emitting layer and can include other functional layers (a hole-injection layer, a hole-transport layer, a hole-blocking layer, an electron-blocking layer, an electron-transport layer, an electron-injection layer, and the like). The organic compound layer 103 and a common layer 104 may collectively include functional layers (a hole-injection layer, a hole-transport layer, a hole-blocking layer, a light-emitting layer, an electron-blocking layer, an electron-transport layer, an electron-injection layer, and the like) included in an EL layer that emits light.

The light-emitting apparatus of one embodiment of the present invention can be, for example, a top-emission light-emitting apparatus where light is emitted in the direction opposite to a substrate over which light-emitting devices are formed. Note that the light-emitting apparatus of one embodiment of the present invention may be of a bottom emission type.

The light-emitting device 130 (130R, 130G, or 130B) has a structure as described in Embodiment 1. The light-emitting device 130 includes an anode electrode (pixel electrode) including a conductive layer 151 (151R, 151G, or 151B) and a conductive layer 152 (152R, 152G, or 152B), the organic compound layer 103 (103R, 103G, or 103B) over the anode, the common layer 104 over the organic compound layer 103 (103R, 103G, or 103B), and the cathode (common electrode) 102 over the common layer.

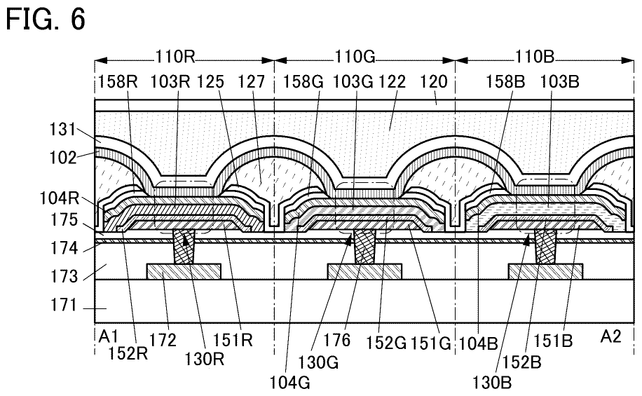

Note that the common layer 104 is not necessarily provided. Specifically, as illustrated in FIG. 6, a functional layer 104R, a functional layer 104G, and a functional layer 104B functioning as an alternative to the common layer 104 are provided in the light-emitting devices 130 (130R, 130G, and 130B), for example. Note that the light-emitting devices 130 (130R, 130G, and 130B) illustrated in FIG. 6 can be formed in the following manner, for example: an organic compound layer and a functional layer are successively formed, and then the organic compound layer and the functional layer are collectively patterned by a lithography method.

As illustrated in FIG. 5B, the common layer 104 can reduce damage to the organic compound layer 103R caused in a later step. In the case where the common layer 104 is provided, the common layer 104 may function as an electron-injection region and a charge-generation region. In the case where the common layer 104 functions as an electron-injection region and a charge-generation region, a stack of the organic compound layer 103R and the common layer 104 corresponds to the organic compound layer 103 in Embodiment 1.

In the light-emitting device, one of the pixel electrode and the common electrode functions as an anode and the other functions as a cathode. Hereinafter, description is made on the assumption that the pixel electrode functions as the anode and the common electrode functions as the cathode unless otherwise specified.

The organic compound layers 103R, the organic compound layers 103G, and the organic compound layers 103B are island-shaped layers and are isolated on a light-emitting device basis or on an emission color basis. Providing the island-shaped organic compound layer 103 in each of the light-emitting devices 130 can inhibit a leakage current between the adjacent light-emitting devices 130 even in a high-resolution light-emitting apparatus. This can prevent crosstalk, so that a light-emitting apparatus with extremely high contrast can be obtained. Specifically, a light-emitting apparatus having high current efficiency at low luminance can be obtained.

The organic compound layer 103 may be provided to cover top and side surfaces of the anode (pixel electrode) of the light-emitting device 130. In that case, the aperture ratio of the light-emitting apparatus 1000 can be easily increased as compared to the structure where an end portion of the organic compound layer 103 is positioned on the inner side of an end portion of the pixel electrode. Covering the side surface of the pixel electrode of the light-emitting device 130 with the organic compound layer 103 can inhibit the pixel electrode from being in contact with the cathode 102; hence, a short circuit of the light-emitting device 130 can be inhibited. Furthermore, the distance between a light-emitting region (i.e., a region overlapping with the pixel electrode) in the organic compound layer 103 and the end portion of the organic compound layer 103 can be increased. Since the end portion of the organic compound layer 103 might be damaged by processing, using a region that is away from the end portion of the organic compound layer 103 as the light-emitting region can increase the reliability of the light-emitting device 130.

In the light-emitting apparatus of one embodiment of the present invention, the anode (pixel electrode) of the light-emitting device may have a stacked-layer structure. For example, in the example illustrated in FIG. 5B, the anode of the light-emitting device 130 is a stack of the conductive layer 151 and the conductive layer 152.

In the case where the light-emitting apparatus 1000 is a top-emission light-emitting apparatus, for example, in the pixel electrode of the light-emitting device 130, the conductive layer 151 preferably has high visible light reflectance and the conductive layer 152 preferably has a visible-light-transmitting property and a high work function. The higher the visible light reflectance of the pixel electrode is, the higher the efficiency of extraction of the light emitted by the organic compound layer 103 is. In the case where the pixel electrode functions as an anode, the higher the work function of the pixel electrode is, the easier it is to inject holes into the organic compound layer 103. Accordingly, when the pixel electrode of the light-emitting device 130 is a stack of the conductive layer 151 with high visible light reflectance and the conductive layer 152 with a high work function, the light-emitting device 130 can have high light extraction efficiency and a low driving voltage.

Specifically, the visible light reflectance of the conductive layer 151 is preferably higher than or equal to 40% and lower than or equal to 100%, further preferably higher than or equal to 70% and lower than or equal to 100%, for example. When used as an electrode having a visible-light-transmitting property, the conductive layer 152 preferably has a visible light transmittance higher than or equal to 40%, for example.

In the case where a film formed after the formation of the pixel electrode having a stacked-layer structure is removed by a wet etching method, for example, the stack might be impregnated with a chemical solution used for the etching. When the impregnated chemical solution reaches the pixel electrode, galvanic corrosion between a plurality of layers constituting the pixel electrode might occur, leading to deterioration of the pixel electrode.

In view of the above, the conductive layer 152 is preferably formed to cover the top and side surfaces of the conductive layer 151. When the conductive layer 151 is covered with the conductive layer 152, the impregnated chemical solution does not reach the conductive layer 151; thus, occurrence of galvanic corrosion in the pixel electrode can be inhibited. This allows the light-emitting apparatus 1000 to be manufactured by a high-yield method and to be accordingly inexpensive. In addition, generation of a defect in the light-emitting apparatus 1000 can be inhibited, which makes the light-emitting apparatus 1000 highly reliable.

A metal material can be used for the conductive layer 151, for example. Specifically, it is possible to use a metal such as aluminum (Al), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals, for example.

For the conductive layer 152, an oxide containing one or more selected from indium, tin, zinc, gallium, titanium, aluminum, and silicon can be used. For example, it is preferable to use a conductive oxide containing one or more of indium oxide, an indium tin oxide, an indium zinc oxide, zinc oxide, zinc oxide containing gallium, titanium oxide, an indium zinc oxide containing gallium, an indium zinc oxide containing aluminum, an indium tin oxide containing silicon, an indium zinc oxide containing silicon, and the like. In particular, indium tin oxide containing silicon can be suitably used for the conductive layer 152 because of having a high work function, for example, a work function higher than or equal to 4.0 eV.

The conductive layer 151 and the conductive layer 152 may each be a stack of a plurality of layers containing different materials. In that case, the conductive layer 151 may include a layer formed using a material that can be used for the conductive layer 152, such as a conductive oxide. Furthermore, the conductive layer 152 may include a layer formed using a material that can be used for the conductive layer 151, such as a metal material. In the case where the conductive layer 151 has a stacked-layer structure of two or more layers, for example, a layer in contact with the conductive layer 152 can contain the same material as a layer of the conductive layer 152 in contact with the conductive layer 151.

The conductive layer 151 preferably has an end portion with a tapered shape. Specifically, the end portion of the conductive layer 151 preferably has a tapered shape with a taper angle of less than 90°. In that case, the conductive layer 152 provided along the side surface of the conductive layer 151 also has an end portion with a tapered shape. When the side surface of the conductive layer 152 has a tapered shape, coverage with the organic compound layer 103 provided along the side surface of the conductive layer 152 can be improved.

In the case where the conductive layer 151 or the conductive layer 152 has a stacked-layer structure, at least one of the stacked layers preferably has a tapered side surface. The stacked layers of the conductive layer(s) may have different tapered shapes.

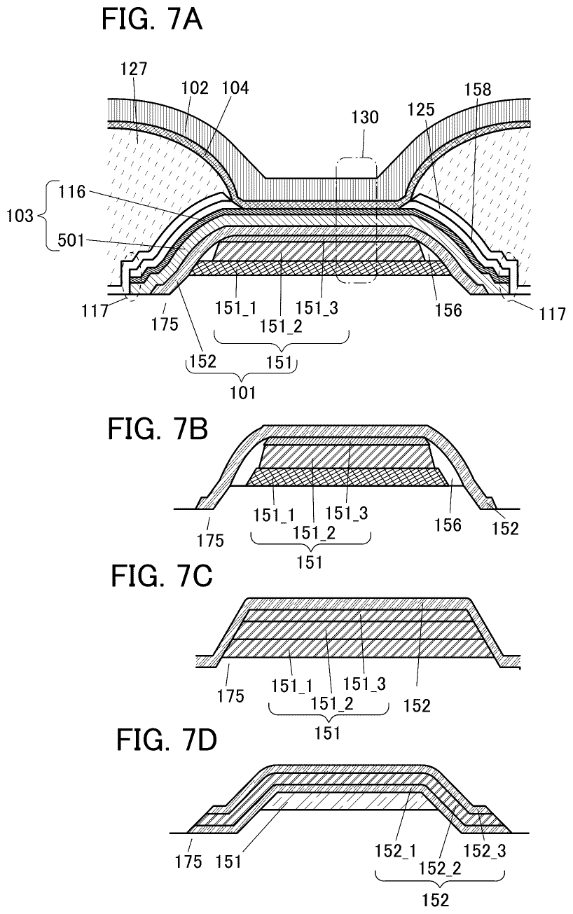

FIG. 7A illustrates the case where the conductive layer 151 has a stacked-layer structure of a plurality of layers containing different materials. As illustrated in FIG. 7A, the conductive layer 151 includes a conductive layer 151_1, a conductive layer 151_2 over the conductive layer 151_1, and a conductive layer 151_3 over the conductive layer 151_2. In other words, the conductive layer 151 illustrated in FIG. 7A has a three-layer stacked structure. In the case where the conductive layer 151 has a stacked-layer structure of a plurality of layers as described above, the visible light reflectance of at least one of the layers included in the conductive layer 151 is higher than that of the conductive layer 152.

In the example illustrated in FIG. 7A, the conductive layer 151_2 is interposed between the conductive layer 151_1 and the conductive layer 151_3. A material that is less likely to change in quality than a material for the conductive layer 1512 is preferably used for the conductive layer 151_1 and the conductive layer 151_3. For example, a material that is less likely to cause migration due to contact with the insulating layer 175 than the material for the conductive layer 151_2 can be used for the conductive layer 1511. The conductive layer 151_3 can be formed using a material that is less likely to be oxidized than the conductive layer 151_2 and whose oxide has a lower electrical resistivity than an oxide of the material for the conductive layer 151_2.

In this manner, the structure where the conductive layer 151_2 is interposed between the conductive layer 151_1 and the conductive layer 1513 can expand the range of choices for the material for the conductive layer 151_2. The conductive layer 1512, for example, can thus have higher visible light reflectance than at least one of the conductive layer 151_1 and the conductive layer 151_3. For example, aluminum can be used for the conductive layer 151_2. The conductive layer 151_2 may be formed using an alloy containing aluminum. For the conductive layer 151_1, titanium, a material which has lower visible light reflectance than aluminum and is less likely to cause migration even at the time of contact with the insulating layer 175 than aluminum, can be used. Furthermore, the conductive layer 1513 can be formed using titanium, which is a material that has a lower visible light reflectance than aluminum but is less likely to be oxidized than aluminum and whose oxide has an electrical resistivity lower than that of aluminum oxide.

The conductive layer 151_3 may be formed using silver or an alloy containing silver. Silver is characterized by its visible light reflectance higher than that of titanium. In addition, silver is characterized by being less likely to be oxidized than aluminum, and silver oxide is characterized by its electrical resistivity lower than that of aluminum oxide. Thus, the conductive layer 151_3 formed using silver or an alloy containing silver can suitably increase the visible light reflectance of the conductive layer 151 and inhibit an increase in the electric resistance of the pixel electrode due to oxidation of the conductive layer 1512. Here, as the alloy containing silver, an alloy of silver, palladium, and copper (also referred to as Ag—Pd—Cu or APC) can be used, for example. When the conductive layer 151_3 is formed using silver or an alloy containing silver and the conductive layer 151_2 is formed using aluminum, the visible light reflectance of the conductive layer 151_3 can be higher than that of the conductive layer 151_2. Here, the conductive layer 151_2 may be formed using silver or an alloy containing silver. The conductive layer 151_1 may be formed using silver or an alloy containing silver.

Meanwhile, a film formed using titanium has better processability in etching than a film formed using silver. Thus, the use of titanium for the conductive layer 151_3 makes it easy to form the conductive layer 151_3. Note that a film formed using aluminum also has better processability in etching than a film formed using silver.

The conductive layer 151 having a stacked-layer structure of a plurality of layers as described above can improve the characteristics of the light-emitting apparatus. For example, the light-emitting apparatus 1000 can have high light extraction efficiency and high reliability.

Here, in the case where the light-emitting device 130 has a microcavity structure, the use of silver or an alloy containing silver, i.e., a material with high visible light reflectance, for the conductive layer 151_3 can favorably increase the light extraction efficiency of the light-emitting apparatus 1000.

Depending on the selected material or the processing method of the conductive layer 151, the side surface of the conductive layer 151_3 might be positioned inward from the side surfaces of the conductive layer 151_1 and the conductive layer 151_2, and a protruding portion might be formed in the conductive layer 151_1 as illustrated in FIG. 7A. This might impair coverage of the conductive layer 151 with the conductive layer 152 to cause step disconnection of the conductive layer 152.

Thus, an insulating layer 156 is preferably provided as illustrated in FIG. 7A. FIG. 7A illustrates an example in which the insulating layer 156 is provided over the conductive layer 151_1 to include a region overlapping with the side surface of the conductive layer 151_2. In this structure, occurrence of step disconnection or thinning of the conductive layer 152 due to the protruding portion can be inhibited, so that poor connection or an increase in driving voltage can be inhibited.

Although FIG. 7A illustrates the structure in which the side surface of the conductive layer 151_2 is entirely covered with the insulating layer 156, part of the side surface of the conductive layer 151_2 is not necessarily covered with the insulating layer 156. Also in a pixel electrode with a later-described structure, part of the side surface of the conductive layer 1512 is not necessarily covered with the insulating layer 156.

Here, the insulating layer 156 preferably has a curved surface as illustrated in FIG. 7A. In this case, step disconnection in the conductive layer 152 covering the insulating layer 156 is less likely to occur than those in the case where the insulating layer 156 has a perpendicular side surface, for example. In addition, step disconnection in the conductive layer 152 covering the insulating layer 156 is less likely to occur also in the case where the side surface of the insulating layer 156 has a tapered shape, specifically, a tapered shape with a taper angle less than 90°, than those in the case where the insulating layer 156 has a perpendicular side surface, for example. As described above, the light-emitting apparatus 1000 can be manufactured by a high-yield method. In addition, generation of a defect can be inhibited, which makes the light-emitting apparatus 1000 highly reliable.

Note that one embodiment of the present invention is not limited thereto. FIG. 7B to FIG. 7D illustrate other examples of the structure of the anode 101.

FIG. 7B illustrates a structure of the anode 101 in FIG. 1A, in which the insulating layer 156 covers the side surfaces of the conductive layer 151_1, the conductive layer 1512, and the conductive layer 151_3 instead of covering only the side surface of the conductive layer 151_2.

FIG. 7C illustrates a structure of the anode 101 in FIG. 1A, in which the insulating layer 156 is not provided.

FIG. 7D illustrates a structure of the anode 101 in FIG. 1, in which the conductive layer 151 does not have a stacked-layer structure and the conductive layer 152 has a stacked-layer structure.

A conductive layer 152_1 has higher adhesion to a conductive layer 152_2 than the insulating layer 175 does, for example. For the conductive layer 152_1, an oxide containing one or more selected from indium, tin, zinc, gallium, titanium, aluminum, and silicon, for example, can be used. For example, it is preferable to use a conductive oxide containing one or more of indium oxide, an indium tin oxide, an indium zinc oxide, zinc oxide, zinc oxide containing gallium, titanium oxide, an indium titanium oxide, zinc titanate, an aluminum zinc oxide, an indium zinc oxide containing gallium, an indium zinc oxide containing aluminum, an indium tin oxide containing silicon, an indium zinc oxide containing silicon, and the like. Accordingly, peeling of the conductive layer 152_2 can be inhibited. The conductive layer 1522 is not in contact with the insulating layer 175.

The conductive layer 152_2 is a layer whose visible light reflectance (e.g., reflectance with respect to light with a predetermined wavelength in a range greater than or equal to 400 nm and less than 750 nm) is higher than that of the conductive layer 151, the conductive layer 1521, and the conductive layer 152_2. The visible light reflectance of the conductive layer 152_2 can be, for example, higher than or equal to 70% and lower than or equal to 100%, and is preferably higher than or equal to 80% and lower than or equal to 100%, further preferably higher than or equal to 90% and lower than or equal to 100%. For the conductive layer 152_2, silver or an alloy containing silver can be used, for example. As the alloy containing silver, an alloy containing silver, palladium, and copper (APC), for example, can be listed. Consequently, the light-emitting apparatus 1000 can be a light-emitting apparatus with high light extraction efficiency. Note that a metal other than silver may be used for the conductive layer 152_2.

When the conductive layer 151 and the conductive layer 152 serve as the anode, a layer having a high work function is preferably used as the conductive layer 1521. A conductive layer 152_3 has a higher work function than the conductive layer 1522, for example. For the conductive layer 1523, a material similar to the material that can be used for the conductive layer 152_1 can be used, for example. For example, the conductive layer 152_1 and the conductive layer 152_3 can be formed using the same kind of material.

When the conductive layer 151 and the conductive layer 152 serve as the cathode, a layer having a low work function is preferably used as the conductive layer 152_1. The conductive layer 152_3 has a lower work function than the conductive layer 1522, for example.

The conductive layer 152_3 is preferably a layer having high visible light transmittance (e.g., transmittance with respect to light with a predetermined wavelength in a range greater than or equal to 400 nm and less than 750 nm). For example, the visible light transmittance of the conductive layer 152_3 is preferably higher than that of the conductive layer 151 and the conductive layer 152_2. The visible light transmittance of the conductive layer 152_3 can be, for example, higher than or equal to 60% and lower than or equal to 100%, and is preferably higher than or equal to 70% and lower than or equal to 100%, further preferably higher than or equal to 80% and lower than or equal to 100%. Accordingly, the amount of light absorbed by the conductive layer 152_3 among light emitted from the organic compound layer 103 can be reduced. As described above, the conductive layer 152_2 under the conductive layer 152_3 can be a layer having high visible light reflectance. Thus, the light-emitting apparatus 1000 can have high light extraction efficiency.

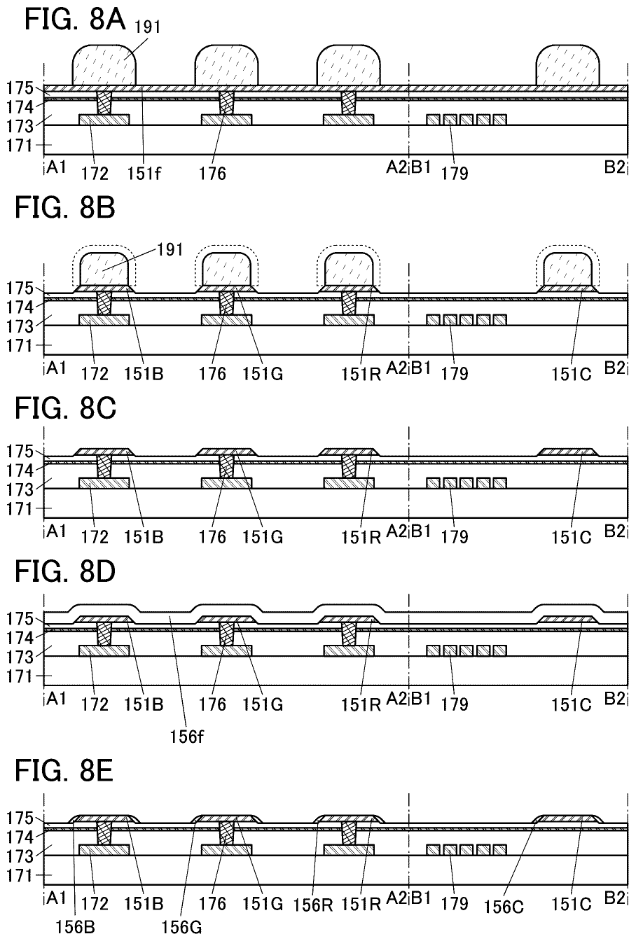

Next, a manufacturing method example of the light-emitting apparatus 1000 having the structure illustrated in FIG. 5 is described with reference to FIG. 8 to FIG. 14.

### [Example of Manufacturing Method]

Thin films included in the light-emitting apparatus (insulating films, semiconductor films, conductive films, and the like) can be formed by, for example, a sputtering method, a chemical vapor deposition (CVD) method, a vacuum evaporation method, a pulsed laser deposition (PLD) method, an ALD method, or the like. Examples of the CVD method include a plasma-enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given.

Thin films included in the light-emitting apparatus (insulating films, semiconductor films, conductive films, and the like) can also be formed by a wet process such as spin coating, dipping, spray coating, ink-jetting, dispensing, screen printing, offset printing, doctor blade coating, slit coating, roll coating, curtain coating, or knife coating.

Specifically, for manufacture of the light-emitting device, a vacuum process such as an evaporation method or the like and a solution process such as a spin coating method, an inkjet method, or the like can be used. Examples of the evaporation method include a physical vapor deposition method (PVD method) and a chemical vapor deposition method (CVD method). Examples of the PVD method include a sputtering method, an ion plating method, an ion beam evaporation method, a molecular beam evaporation method, and a vacuum evaporation method. In particular, the functional layers (e.g., a hole-injection layer, a hole-transport layer, a hole-blocking layer, a light-emitting layer, an electron-blocking layer, an electron-transport layer, an electron-injection layer, and the like) included in the organic compound layer can be formed by an evaporation method (a vacuum evaporation method), a coating method (e.g., a dip coating method, a die coating method, a bar coating method, a spin coating method, a spray coating method, or the like), a printing method (an inkjet method, a screen printing (stencil) method, an offset printing (planography) method, a flexography (e.g., relief printing) method, a gravure printing method, a micro-contact printing method, or the like), or the like.

Thin films included in the light-emitting apparatus can be processed by a lithography method, for example. Alternatively, a nanoimprinting method, a sandblasting method, a lift-off method, or the like may be used to process thin films. Alternatively, island-shaped thin films may be directly formed by a film formation method using a shielding mask such as a metal mask.

A photolithography method, which is an example of a lithography method, typically includes the following two methods. In one of the methods, a resist mask is formed over a thin film that is to be processed, the thin film is processed by etching, for example, and then the resist mask is removed. In the other method, a photosensitive thin film is formed and then processed into a desired shape by light exposure and development.

For etching of thin films, a dry etching method, a wet etching method, a sandblast method, or the like can be used.

First, the insulating layer 171 is formed over a substrate (not illustrated), as illustrated in FIG. 8A. Next, the conductive layer 172 and a conductive layer 179 are formed over the insulating layer 171, and the insulating layer 173 is formed over the insulating layer 171 so as to cover the conductive layer 172 and the conductive layer 179. Then, the insulating layer 174 is formed over the insulating layer 173, and the insulating layer 175 is formed over the insulating layer 174.

As the substrate, a substrate that has heat resistance high enough to withstand at least heat treatment performed later can be used. When an insulating substrate is used, it is possible to use a glass substrate, a quartz substrate, a sapphire substrate, a ceramic substrate, an organic resin substrate, or the like. Alternatively, it is possible to use a semiconductor substrate such as a single crystal semiconductor substrate or a polycrystalline semiconductor substrate of silicon or silicon carbide, a compound semiconductor substrate (e.g., a compound semiconductor substrate containing silicon germanium), or an SOI substrate.

Next, as illustrated in FIG. 8A, openings reaching the conductive layer 172 are formed in the insulating layer 175, the insulating layer 174, and the insulating layer 173. Then, the plugs 176 are formed to fill the openings.

Next, a conductive film 151f to be the conductive layer 151R, the conductive layer 151G, the conductive layer 151B, and the conductive layer 151C later is formed over the plugs 176 and the insulating layer 175, as illustrated in FIG. 8A. For formation of the conductive film 151f, a sputtering method or a vacuum evaporation method can be used, for example. A metal material can be used for the conductive film 151f, for example.

Next, as illustrated in FIG. 8A, a resist mask 191 is formed over the conductive film 151f, for example. The resist mask 191 can be formed by application of a photosensitive material (photoresist), light exposure, and development.

Subsequently, as illustrated in FIG. 8B, the conductive film 151f in a region that is not overlapped by the resist mask 191, for example, is removed by an etching method such as a dry etching method, for example. Note that in the case where the conductive film 151f includes a layer formed using a conductive oxide such as indium tin oxide, for example, the layer may be removed by a wet etching method. In this manner, the conductive layer 151 is formed. Here, in the case where part of the conductive film 151f is removed by a dry etching method, for example, a depressed portion (also referred to as a depression) may be formed in a region of the insulating layer 175 that does not overlap with the conductive layer 151.

Next, as illustrated in FIG. 8C, the resist mask 191 is removed. The resist mask 191 can be removed by ashing using oxygen plasma, for example. Alternatively, an oxygen gas and CF₄, C₄F₈, SF₆, CHF₃, Cl₂, H₂O, or BCl₃ may be used. Alternatively, an oxygen gas and a Group 18 element such as He may be used. Alternatively, the resist mask 191 may be removed by wet etching.

Next, as illustrated in FIG. 8D, an insulating film 156f to be an insulating layer 156R, an insulating layer 156G, an insulating layer 156B, and an insulating layer 156C later is formed over the conductive layer 151R, the conductive layer 151G, the conductive layer 151B, the conductive layer 151C, and the insulating layer 175. The insulating film 156f can be formed by a CVD method, an ALD method, a sputtering method, or a vacuum evaporation method, for example.

For the insulating film 156f, an inorganic material can be used. As the insulating film 156f, an inorganic insulating film such as an oxide insulating film, a nitride insulating film, an oxynitride insulating film, or a nitride oxide insulating film can be used, for example. For example, an oxide insulating film containing silicon, a nitride insulating film containing silicon, an oxynitride insulating film containing silicon, a nitride oxide insulating film containing silicon, or the like can be used as the insulating film 156f For the insulating film 156f, silicon oxynitride can be used, for example.

Subsequently, as illustrated in FIG. 8E, the insulating film 156f is processed to form the insulating layer 156R, the insulating layer 156G, the insulating layer 156B, and the insulating layer 156C. The insulating layer 156 can be formed by performing etching substantially uniformly on the upper surface of the insulating film 156f, for example. Such uniform etching for planarization is also referred to as etch-back processing. Note that the insulating layer 156 may be formed by a photolithography method.

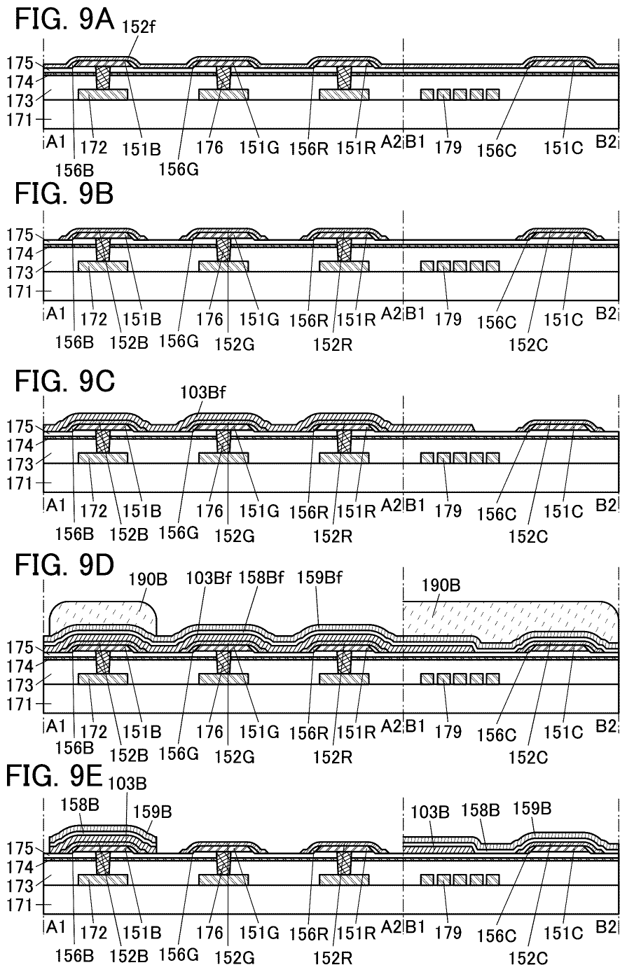

Then, as illustrated in FIG. 9A, a conductive film 152f to be the conductive layer 152R, the conductive layer 152G, and the conductive layer 152B and a conductive layer 152C is formed over the conductive layer 151R, the conductive layer 151G, the conductive layer 151B, the conductive layer 151C, the insulating layer 156R, the insulating layer 156G, the insulating layer 156B, the insulating layer 156C, and the insulating layer 175. Specifically, the conductive film 152f is formed to cover the conductive layer 151R, the conductive layer 151G, the conductive layer 151B, the conductive layer 151C, the insulating layer 156R, the insulating layer 156G, the insulating layer 156B, and the insulating layer 156C, for example.

The conductive film 152f can be formed by a sputtering method or a vacuum evaporation method, for example. The conductive film 152f can be formed by an ALD method. A conductive oxide can be used for the conductive film 152f, for example. The conductive film 152f can be a stack of a film formed using a metal material and a film formed thereover using a conductive oxide. For example, the conductive film 152f can be a stack of a film formed using titanium, silver, or an alloy containing silver and a film formed thereover using a conductive oxide.

Then, as illustrated in FIG. 9B, the conductive film 152f is processed by a photolithography method, for example, so that the conductive layer 152R, the conductive layer 152G, the conductive layer 152B, and the conductive layer 152C are formed. Specifically, the conductive film 152f is partly removed by an etching method after a resist mask is formed, for example. The conductive film 152f can be removed by a wet etching method, for example. The conductive film 152f may be removed by a dry etching method. Through the above steps, the pixel electrode including the conductive layer 151 and the conductive layer 152 is formed.

Next, hydrophobization treatment is preferably performed on the conductive layer 152. The hydrophobization treatment can change the hydrophilic properties of the subject surface to hydrophobic properties or increase the hydrophobic properties of the subject surface. The hydrophobization treatment for the conductive layer 152 can increase the adhesion between the conductive layer 152 and the organic compound layer 103 formed in a later step and inhibit film peeling. Note that the hydrophobization treatment is not necessarily performed.

Next, as illustrated in FIG. 9C, an organic compound film 103Bf to be the organic compound layer 103B is formed over the conductive layer 152B, the conductive layer 152G, and the conductive layer 152R and the insulating layer 175.

Note that in the present invention, the organic compound film 103Bf has a structure where a plurality of organic compound layers each including at least one light-emitting layer are stacked with an intermediate layer therebetween. The structure of the light-emitting device 130 described in Embodiment 1 can be referred to for the specific structure.

As illustrated in FIG. 9C, the organic compound film 103Bf is not formed over the conductive layer 152C. The organic compound film 103Bf can be formed only in an intended region by using a mask for defining a film formation area (in this specification and the like, the mask may be referred to as an area mask or a rough metal mask in order to distinguish it from a fine metal mask), for example. A light-emitting device can be manufactured through a relatively simple process, by employing a film formation step using an area mask and a processing step using a resist mask.

The organic compound film 103Bf can be formed by an evaporation method, specifically a vacuum evaporation method, for example. The organic compound film 103Bf may be formed by a transfer method, a printing method, an ink-jet method, a coating method, or the like.

Then, as illustrated in FIG. 9D, a sacrificial film 158Bf to be a sacrificial layer 158B and a mask film 159Bf to be a mask layer 159B are sequentially formed over the organic compound film 103Bf.

The sacrificial film 158Bf and the mask film 159Bf can be formed by a sputtering method, an ALD method (e.g., a thermal ALD method, a PEALD method, or the like), a CVD method, or a vacuum evaporation method, for example. Alternatively, the sacrificial film 158Bf and the mask film 159Bf may be formed by the above-described wet process.

The sacrificial film 158Bf and the mask film 159Bf are formed at a temperature lower than the heat resistance temperature of the organic compound film 103Bf. The typical substrate temperatures in formation of the sacrificial film 158Bf and the mask film 159Bf are each lower than or equal to 200° C., preferably lower than or equal to 150° C., further preferably lower than or equal to 120° C., still further preferably lower than or equal to 100° C., yet still further preferably lower than or equal to 80° C.

Although this embodiment shows an example where a mask film having a two-layer structure of the sacrificial film 158Bf and the mask film 159Bf is formed, a mask film may have a single-layer structure or a stacked-layer structure of three or more layers.

Providing the sacrificial layer over the organic compound film 103Bf can reduce damage to the organic compound film 103Bf in the manufacturing process of the light-emitting apparatus, resulting in an increase in reliability of the light-emitting device.

As the sacrificial film 158Bf, a film that is highly resistant to the process conditions for the organic compound film 103Bf, specifically, a film having high etching selectivity with respect to the organic compound film 103Bf is used. For the mask film 159Bf, a film having high etching selectivity with respect to the sacrificial film 158Bf is used.

The sacrificial film 158Bf and the mask film 159Bf are preferably films that can be removed by a wet etching method. Using a wet etching method can reduce damage to the organic compound film 103Bf in processing the sacrificial film 158Bf and the mask film 159Bf, as compared to the case of using a dry etching method.

In the case where a wet etching method is employed, it is particularly preferable to use an acidic chemical solution. As an acidic chemical solution, a chemical solution containing one of phosphoric acid, hydrofluoric acid, nitric acid, acetic acid, oxalic acid, sulfuric acid, and the like or a mixed chemical solution (also referred to as a mixed acid) that contains two or more of these acids is preferably used.

As each of the sacrificial film 158Bf and the mask film 159Bf, one or more of a metal film, an alloy film, a metal oxide film, a semiconductor film, an organic insulating film, and an inorganic insulating film, for example, can be used.

When a film containing a material having a property of blocking ultraviolet rays is used as each of the sacrificial film 158Bf and the mask film 159Bf, the organic compound layer can be inhibited from being irradiated with ultraviolet rays in a light exposure step, for example. The organic compound layer is inhibited from being damaged by ultraviolet rays, so that the reliability of the light-emitting device can be improved.

Note that the same effect is obtained when a film containing a material having a property of blocking ultraviolet rays is used for an after-mentioned inorganic insulating film 125f.

For each of the sacrificial film 158Bf and the mask film 159Bf, a metal material such as gold, silver, platinum, magnesium, nickel, tungsten, chromium, molybdenum, iron, cobalt, copper, palladium, titanium, aluminum, yttrium, zirconium, or tantalum or an alloy material containing any of the metal materials are used, for example. It is particularly preferable to use a low-melting-point material such as aluminum or silver.

The sacrificial film 158Bf and the mask film 159Bf can each be formed using a metal oxide such as an In—Ga—Zn oxide, an indium oxide, an In—Zn oxide, an In—Sn oxide, an indium titanium oxide (In—Ti oxide), an indium tin zinc oxide (In—Sn—Zn oxide), an indium titanium zinc oxide (In—Ti—Zn oxide), an indium gallium tin zinc oxide (In—Ga—Sn—Zn oxide), or an indium tin oxide containing silicon.

In addition, in place of gallium described above, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

The sacrificial film 158Bf and the mask film 159Bf are preferably formed using a semiconductor material such as silicon or germanium, for example, for excellent compatibility with a semiconductor manufacturing process. Alternatively, an oxide or a nitride of the semiconductor material can be used. Alternatively, a non-metallic material such as carbon and the like or a compound thereof can be used. A metal such as titanium, tantalum, tungsten, chromium, or aluminum or an alloy containing at least one of these metals can be used. Alternatively, an oxide containing the above-described metal, such as titanium oxide or chromium oxide, or a nitride such as titanium nitride, chromium nitride, or tantalum nitride can be used.

As each of the sacrificial film 158Bf and the mask film 159Bf, any of a variety of inorganic insulating films can be used. In particular, an oxide insulating film is preferable because its adhesion to the organic compound film 103Bf is higher than that of a nitride insulating film. For example, an inorganic insulating material such as aluminum oxide, hafnium oxide, or silicon oxide can be used for the sacrificial film 158Bf and the mask film 159Bf. As the sacrificial film 158Bf and the mask film 159Bf, aluminum oxide films can be formed by an ALD method, for example. An ALD method is preferably used, in which case damage to a base (in particular, the organic compound layer) can be reduced.

An organic material may be used for one or both of the sacrificial film 158Bf and the mask film 159Bf. For example, as the organic material, a material that can be dissolved in a solvent chemically stable with respect to at least the uppermost film of the organic compound film 103Bf may be used. Specifically, a material that is dissolved in water or alcohol can be suitably used. In forming a film of such a material, it is preferable to apply the material dissolved in a solvent such as water or alcohol by a wet film formation method and then perform heat treatment for evaporating the solvent. At this time, the heat treatment is preferably performed in a reduced-pressure atmosphere, in which case the solvent can be removed at a low temperature in a short time and thermal damage to the organic compound film 103Bf can be reduced accordingly.

The sacrificial film 158Bf and the mask film 159Bf may be formed using an organic resin such as polyvinyl alcohol (PVA), polyvinyl butyral, polyvinylpyrrolidone, polyethylene glycol, polyglycerin, pullulan, water-soluble cellulose, an alcohol-soluble polyamide resin, or a fluorine resin like perfluoropolymer.

For example, an organic film (e.g., a PVA film) formed by an evaporation method or any of the above wet processes can be used as the sacrificial film 158Bf, and an inorganic film (e.g., a silicon nitride film) formed by a sputtering method can be used as the mask film 159Bf.

Subsequently, a resist mask 190B is formed over the mask film 159Bf as illustrated in FIG. 9D. The resist mask 190B can be formed by application of a photosensitive material (photoresist), light exposure, and development.

The resist mask 190B may be formed using either a positive resist material or a negative resist material.

The resist mask 190B is provided at a position overlapping with the conductive layer 152B. Note that the resist mask 190B is preferably provided also at a position overlapping with the conductive layer 152C. This can inhibit the conductive layer 152C from being damaged during the manufacturing process of the light-emitting apparatus. Note that the resist mask 190B is not necessarily provided over the conductive layer 152C. The resist mask 190B is preferably provided to cover the area from the end portion of the organic compound film 103Bf to the end portion of the conductive layer 152C (the end portion on the organic compound film 103Bf side), as illustrated in the cross-sectional view along B1-B2 in FIG. 9C.

Next, as illustrated in FIG. 9E, part of the mask film 159Bf is removed using the resist mask 190B, whereby the mask layer 159B is formed. The mask layer 159B remains over the conductive layer 152B and over the conductive layer 152C. After that, the resist mask 190B is removed. Next, part of the sacrificial film 158Bf is removed using the mask layer 159B as a mask (also referred to as a hard mask), so that the sacrificial layer 158B is formed.

Each of the sacrificial film 158Bf and the mask film 159Bf can be processed by a wet etching method or a dry etching method. The sacrificial film 158Bf and the mask film 159Bf are preferably processed by wet etching.

Using a wet etching method can reduce damage to the organic compound film 103Bf in processing the sacrificial film 158Bf and the mask film 159Bf, as compared to the case of using a dry etching method. In the case of using a wet etching method, it is preferable to use a developer, an aqueous solution of tetramethylammonium hydroxide (TMAH), dilute hydrofluoric acid, oxalic acid, phosphoric acid, acetic acid, nitric acid, or a chemical solution containing a mixed solution of any of these acids, for example.

Since the organic compound film 103Bf is not exposed in the processing of the mask film 159Bf, the range of choice for a processing method for the mask film 159Bf is wider than that for the sacrificial film 158Bf. Specifically, even in the case where a gas containing oxygen is used as the etching gas in the processing of the mask film 159Bf, deterioration of the organic compound film 103Bf can be inhibited.

In the case where a wet etching method is employed, it is particularly preferable to use an acidic chemical solution. As an acidic chemical solution, a chemical solution containing one of phosphoric acid, hydrofluoric acid, nitric acid, acetic acid, oxalic acid, sulfuric acid, and the like or a mixed chemical solution (also referred to as a mixed acid) that contains two or more of these acids is preferably used.

In the case of using a dry etching method to process the sacrificial film 158Bf, deterioration of the organic compound film 103Bf can be inhibited by not using a gas containing oxygen as the etching gas. In the case of using a dry etching method, it is preferable to use a gas containing CF₄, C₄F₈, SF₆, CHF₃, Cl₂, H₂O, or BCl₃, for example, as the etching gas. For example, a gas containing a Group 18 element such as He is preferably used as the etching gas.

The resist mask 190B can be removed by a method similar to that for the resist mask 191. At this time, the sacrificial film 158Bf is positioned on the outermost surface, and the organic compound film 103Bf is not exposed; thus, the organic compound film 103Bf can be inhibited from being damaged in the step of removing the resist mask 190B. In addition, the range of choices of the method for removing the resist mask 190B can be widened.

Next, as illustrated in FIG. 9E, the organic compound film 103Bf is processed, so that the organic compound layer 103B is formed. For example, part of the organic compound film 103Bf is removed using the mask layer 159B and the sacrificial layer 158B as a hard mask to form the organic compound layer 103B.

Accordingly, as illustrated in FIG. 9E, the stacked-layer structure of the organic compound layer 103B, the sacrificial layer 158B, and the mask layer 159B remains over the conductive layer 152B. The conductive layer 152G and the conductive layer 152B are exposed.

The organic compound film 103Bf can be processed by dry etching or wet etching. In the case where the processing is performed by dry etching, for example, an etching gas containing oxygen can be used. When the etching gas contains oxygen, the etching rate can be increased. Thus, the etching can be performed under a low-power condition while an adequately high etching rate is maintained. Accordingly, damage to the organic compound film 103Bf can be inhibited. Furthermore, a defect such as attachment of a reaction product generated during the etching can be inhibited.

An etching gas that does not contain oxygen may be used. In the case where the etching gas that does not contain oxygen is used, deterioration of the organic compound film 103Bf can be inhibited, for example.

As described above, in one embodiment of the present invention, the mask layer 159B is formed in the following manner: the resist mask 190B is formed over the mask film 159Bf and part of the mask film 159Bf is removed using the resist mask 190B. After that, part of the organic compound film 103Bf is removed using the mask layer 159B as a hard mask, so that the organic compound layer 103B is formed. In other words, the organic compound layer 103B is formed by processing the organic compound film 103Bf by a photolithography method. Note that part of the organic compound film 103Bf may be removed using the resist mask 190B. Then, the resist mask 190B may be removed.

Here, hydrophobization treatment for the conductive layer 152G may be performed as necessary. At the time of processing the organic compound film 103Bf, a surface of the conductive layer 152G changes to have hydrophilic properties in some cases, for example. The hydrophobization treatment for the conductive layer 152G, for example, can increase the adhesion between the conductive layer 152G and a layer to be formed in a later step (which is the organic compound layer 103G here) and inhibit film peeling.

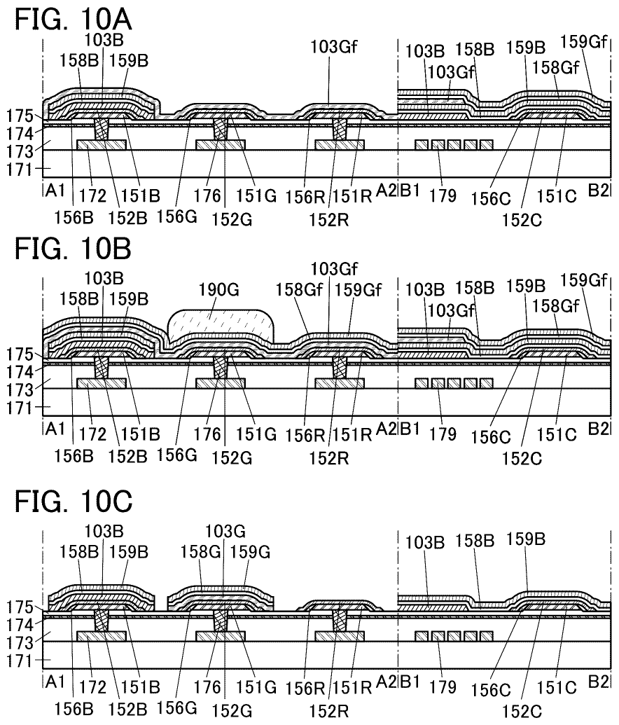

Next, as illustrated in FIG. 10A, an organic compound film 103Gf to be the organic compound layer 103G is formed over the conductive layer 152G, the conductive layer 152R, the mask layer 159B, and the insulating layer 175.

The organic compound film 103Gf can be formed by a method similar to that for forming the organic compound film 103Bf. The organic compound film 103Gf can have a structure similar to that of the organic compound film 103Bf.

Then, as illustrated in FIG. 10B, a sacrificial film 158Gf to be a sacrificial layer 158G and a mask film 159Gf to be a mask layer 159G are sequentially formed over the organic compound film 103Gf and the mask layer 159B. After that, a resist mask 190G is formed. The materials and the formation methods of the sacrificial film 158Gf and the mask film 159Gf are similar to conditions applicable to the sacrificial film 158Bf and the mask film 159Bf. The materials and the formation method of the resist mask 190G are similar to conditions applicable to the resist mask 190B.

The resist mask 190G is provided at a position overlapping with the conductive layer 152G.

Subsequently, as illustrated in FIG. 10C, part of the mask film 159Gf is removed using the resist mask 190G, whereby the mask layer 159G is formed. The mask layer 159G remains over the conductive layer 152G. After that, the resist mask 190G is removed. Next, part of the sacrificial film 158Gf is removed using the mask layer 159G as a mask, so that the sacrificial layer 158G is formed. Next, the organic compound film 103Gf is processed, so that the organic compound layer 103G is formed. For example, part of the organic compound film 103Gf is removed using the mask layer 159G and the sacrificial layer 158G as a hard mask, whereby the organic compound film 103G is formed.

Accordingly, as illustrated in FIG. 10C, the stacked-layer structure of the organic compound layer 103G, the sacrificial layer 158G, and the mask layer 159G remains over the conductive layer 152G. The mask layer 159B and the conductive layer 152R are exposed.

Hydrophobization treatment for the conductive layer 152R may be performed, for example.

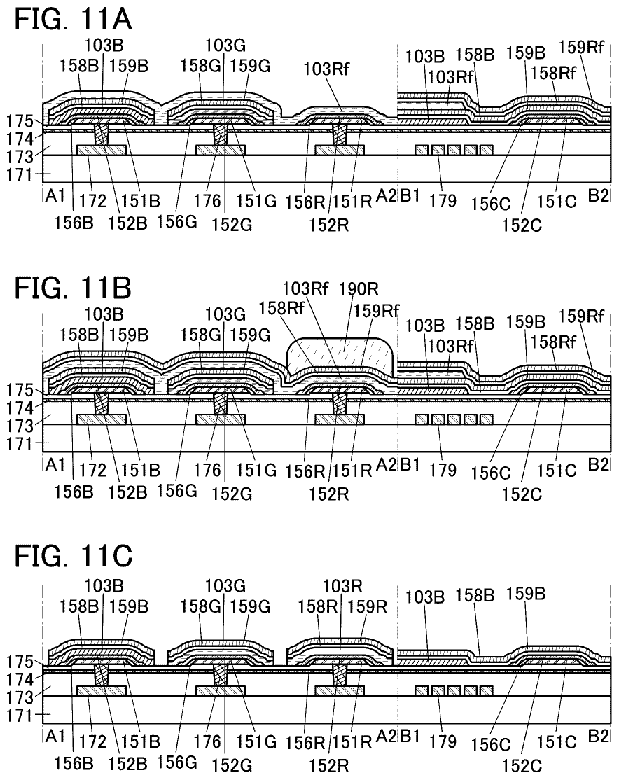

Next, as illustrated in FIG. 11A, an organic compound film 103Rf to be the organic compound layer 103R is formed over the conductive layer 152R, the mask layer 159G, the mask layer 159B, and the insulating layer 175.

The organic compound film 103Gf can be formed by a method similar to that for forming the organic compound film 103Rf. The organic compound film 103Gf can have a structure similar to that of the organic compound film 103Rf.

Subsequently, as illustrated in FIG. 11B and FIG. 11C, a sacrificial layer 158, a mask layer 159R, and the organic compound layer 103R are formed from a sacrificial film 158Rf, a mask film 159Rf, and the organic compound film 103Rf, respectively. For the formation methods of a resist mask 190R, an sacrificial layer 158R, the mask layer 159R, and the organic compound layer 103R, the description for the organic compound layer 103G can be referred to.

Note that side surfaces of the organic compound layer 103B, the organic compound layer 103G, and the organic compound layer 103R are preferably perpendicular or substantially perpendicular to their formation surfaces. For example, the angle between the formation surfaces and these side surfaces is preferably greater than or equal to 60° and less than or equal to 90°.

The distance between two adjacent layers among the organic compound layer 103B, the organic compound layer 103G, and the organic compound layer 103R, which are formed by a photolithography method as described above, can be reduced to less than or equal to 8 μm, less than or equal to 5 μm, less than or equal to 3 μm, less than or equal to 2 μm, or less than or equal to 1 μm. Here, the distance can be specified, for example, by a distance between opposite end portions of two adjacent layers among the organic compound layer 103B, the organic compound layer 103G, and the organic compound layer 103R. Reducing the distance between the island-shaped organic compound layers can provide a light-emitting apparatus having a high resolution and a high aperture ratio. In addition, the distance between the anodes of adjacent light-emitting devices can also be shortened to, for example, less than or equal to 10 μm, less than or equal to 8 μm, less than or equal to 5 μm, less than or equal to 3 μm, or less than or equal to 2 μm. Note that the distance between the anodes of adjacent light-emitting devices is preferably greater than or equal to 2 μm and less than or equal to 5 μm.

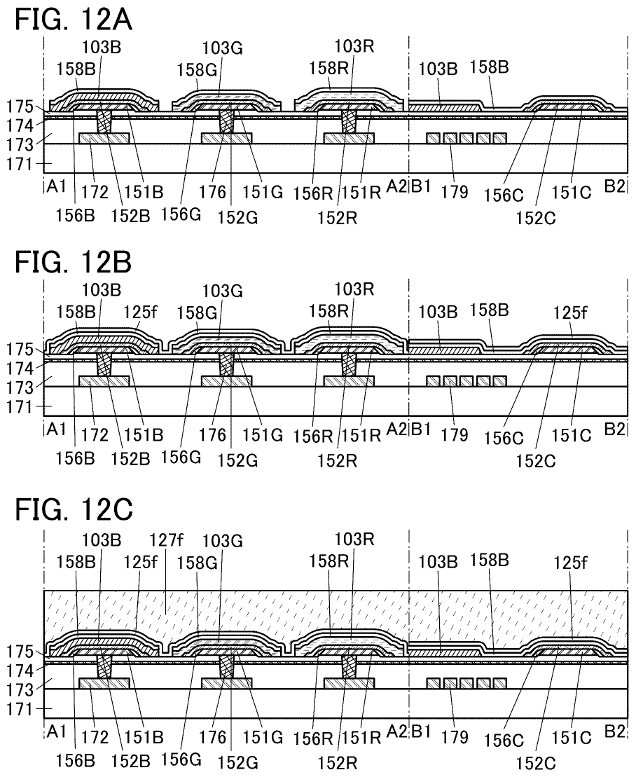

Subsequently, the mask layer 159B, the mask layer 159G, and the mask layer 159R are removed as illustrated in FIG. 12A.

This embodiment shows an example where the mask layer 159B, the mask layer 159G, and the mask layer 159R are removed; however, it is possible that the mask layer 159B, the mask layer 159G, and the mask layer 159R are not removed. For example, in the case where the mask layer 159B, the mask layer 159G, and the mask layer 159R contain the above-described material having a property of blocking ultraviolet rays, the procedure preferably proceeds to the next step without removing the mask layer 159B, the mask layer 159G, and the mask layer 159R, in which case the organic compound layer can be protected from light irradiation (including lighting).

The step of removing the mask layers can be performed by a method similar to that for the step of processing the mask layers. Specifically, by using a wet etching method, damage applied to the organic compound layer 103B, the organic compound layer 103G, and the organic compound layer 103R at the time of removing the mask layers can be reduced as compared to the case of using a dry etching method.

The mask layers may be removed by being dissolved in a solvent such as water or an alcohol. Examples of an alcohol include ethyl alcohol, methyl alcohol, isopropyl alcohol (IPA), and glycerin.

After the mask layers are removed, drying treatment may be performed in order to remove water included in the organic compound layer 103B, the organic compound layer 103G, and the organic compound layer 103R and water adsorbed on the surfaces of the organic compound layer 103B, the organic compound layer 103G, and the organic compound layer 103R. For example, heat treatment in an inert gas atmosphere or a reduced-pressure atmosphere can be performed. The heat treatment can be performed at a substrate temperature of higher than or equal to 50° C. and lower than or equal to 200° C., preferably higher than or equal to 60° C. and lower than or equal to 150° C., further preferably higher than or equal to 70° C. and lower than or equal to 120° C. The heat treatment is preferably performed in a reduced-pressure atmosphere, in which case drying at a lower temperature is possible.

Next, as illustrated in FIG. 12B, the inorganic insulating film 125f to be the inorganic insulating layer 125 is formed to cover the organic compound layer 103B, the organic compound layer 103G, and the organic compound layer 103R and the sacrificial layer 158B, the sacrificial layer 158G, and the sacrificial layer 158R.

As described later, an insulating film to be the insulating layer 127 is to be formed in contact with the top surface of the inorganic insulating film 125f. Thus, the top surface of the inorganic insulating film 125f preferably has a high affinity for the material used for the insulating film to be the insulating layer 127 (e.g., a photosensitive resin composition containing an acrylic resin). To improve the affinity, surface treatment may be performed on the top surface of the inorganic insulating film 125f. Specifically, the surface of the inorganic insulating film 125f is preferably made hydrophobic (or its hydrophobic property is preferably improved). For example, it is preferable to perform the treatment using a silylation agent such as hexamethyldisilazane (HMDS). By making the top surface of the inorganic insulating film 125f hydrophobic in such a manner, an insulating film 127f can be formed with favorable adhesion.

Then, as illustrated in FIG. 12C, an insulating film 127f to be the insulating layer 127 later is formed over the inorganic insulating film 125f.

The inorganic insulating film 125f and the insulating film 127f are preferably formed by a formation method that causes less damage to the organic compound layer 103B, the organic compound layer 103G, and the organic compound layer 103R. The inorganic insulating film 125f, which is formed in contact with the side surfaces of the organic compound layer 103B, the organic compound layer 103G, and the organic compound layer 103R, is particularly preferably formed by a formation method that causes less damage to the organic compound layer 103B, the organic compound layer 103G, and the organic compound layer 103R than the method of forming the insulating film 127f.

Each of the inorganic insulating film 125f and the insulating film 127f is formed at a temperature lower than the heat resistance temperature of the organic compound layer 103B, the organic compound layer 103G, and the organic compound layer 103R. When the inorganic insulating film 125f is formed at a high substrate temperature, the formed inorganic insulating film 125f, even with a small thickness, can have a low impurity concentration and a high barrier property against at least one of water and oxygen.

The substrate temperature at the time of forming the inorganic insulating film 125f and the insulating film 127f is preferably higher than or equal to 60° C., higher than or equal to 80° C., higher than or equal to 100° C., or higher than or equal to 120° C. and lower than or equal to 200° C., lower than or equal to 180° C., lower than or equal to 160° C., lower than or equal to 150° C., or lower than or equal to 140° C.

As the inorganic insulating film 125f, an insulating film having a thickness of greater than or equal to 3 nm, greater than or equal to 5 nm, or greater than or equal to 10 nm and less than or equal to 200 nm, less than or equal to 150 nm, less than or equal to 100 nm, or less than or equal to 50 nm is preferably formed in the above-described range of the substrate temperature.

The inorganic insulating film 125f is preferably formed by an ALD method, for example. An ALD method is preferably used, in which case deposition damage is reduced and a film with good coverage can be formed. As the inorganic insulating film 125f, an aluminum oxide film is preferably formed by an ALD method, for example.

Alternatively, the inorganic insulating film 125f may be formed by a sputtering method, a CVD method, or a PECVD method, each of which has a higher deposition rate than an ALD method. In that case, a highly reliable light-emitting apparatus can be manufactured with high productivity.

The insulating film 127f is preferably formed by the aforementioned wet process. The insulating film 127f is preferably formed by spin coating using a photosensitive material, for example, and specifically preferably formed using a photosensitive resin composition containing an acrylic resin.

The insulating film 127f is preferably formed using a resin composition containing a polymer, an acid-generating agent, and a solvent, for example. The polymer is formed using one or more kinds of monomers and has a structure where one or more kinds of structural units (also referred to as building blocks) are repeated regularly or irregularly. As the acid-generating agent, one or both of a compound that generates an acid by light irradiation and a compound that generates an acid by heating can be used. The resin composition may also include one or more of a photosensitizing agent, a sensitizer, a catalyst, an adhesive aid, a surface-active agent, and an antioxidant.

Heat treatment (also referred to as prebaking) is preferably performed after the insulating film 127f is formed. The heat treatment is performed at a temperature lower than the heat resistance temperature of the organic compound layer 103B, the organic compound layer 103G, and the organic compound layer 103R. The substrate temperature in the heat treatment is preferably higher than or equal to 50° C. and lower than or equal to 200° C., further preferably higher than or equal to 60° C. and lower than or equal to 150° C., still further preferably higher than or equal to 70° C. and lower than or equal to 120° C. Accordingly, the solvent contained in the insulating film 127f can be removed.

Then, part of the insulating film 127f is exposed to visible light or ultraviolet rays. Here, when a positive photosensitive resin composition containing an acrylic resin is used for the insulating film 127f, a region where the insulating layer 127 is not formed in a later step is irradiated with visible light or ultraviolet rays. The insulating layer 127 is formed in regions that are interposed between any two of the conductive layer 152B, the conductive layer 152G, and the conductive layer 152R and around the conductive layer 152C. Thus, the top surfaces of the conductive layer 152B, the conductive layer 152G, the conductive layer 152R, and the conductive layer 152C are irradiated with visible light or ultraviolet rays. Note that when a negative photosensitive material is used for the insulating film 127f, the region where the insulating layer 127 is to be formed is irradiated with visible light or ultraviolet rays.

The width of the insulating layer 127 formed later can be controlled in accordance with the exposed region of the insulating film 127f. In this embodiment, processing is performed such that the insulating layer 127 includes a portion overlapping with the top surface of the conductive layer 151.

Here, when a barrier insulating layer against oxygen (such as an aluminum oxide film) is provided as one or both of the sacrificial layer 158 (the sacrificial layer 158B, the sacrificial layer 158G, and the sacrificial layer 158R) and the inorganic insulating film 125f, diffusion of oxygen into the organic compound layer 103B, the organic compound layer 103G, and the organic compound layer 103R can be inhibited. When the organic compound layer is irradiated with light (visible light rays or ultraviolet rays), an organic compound contained in the organic compound layer is brought into an excited state and a reaction between the organic compound and oxygen in the atmosphere is promoted in some cases. Specifically, when the organic compound layer is irradiated with light (visible light rays or ultraviolet rays) in an atmosphere containing oxygen, oxygen might be bonded to the organic compound contained in the organic compound layer. By providing the sacrificial layer 158 and the inorganic insulating film 125f over the island-shaped organic compound layer, bonding of oxygen in the atmosphere to the organic compound contained in the organic compound layer can be reduced.

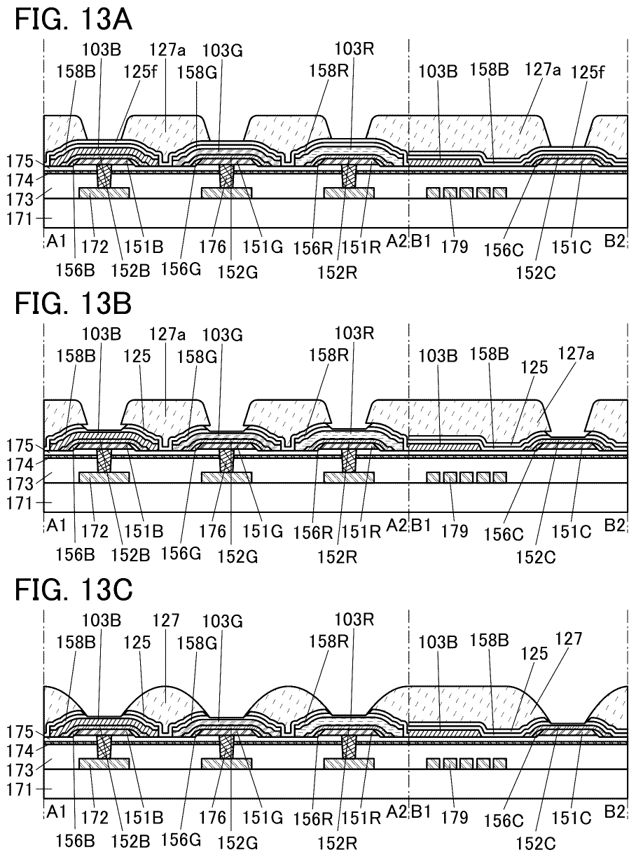

Next, as illustrated in FIG. 13A, the region of the insulating film 127f exposed to light is removed by development, so that an insulating layer 127a is formed. The insulating layer 127a is formed in regions that are interposed between any two of the conductive layer 152B, the conductive layer 152G, and the conductive layer 152R and a region surrounding the conductive layer 152C. Here, when an acrylic resin is used for the insulating film 127f, a developer may be an alkaline solution and can be TMAH, for example.

Next, as illustrated in FIG. 13B, etching treatment is performed using the insulating layer 127a as a mask to remove part of the inorganic insulating film 125f, so that the sacrificial layer 158R, the sacrificial layer 158G, and the sacrificial layer 158B are partly thinned. Thus, the inorganic insulating layer 125 is formed under the insulating layer 127a. Hereinafter, the etching treatment for processing the inorganic insulating film 125f using the insulating layer 127a as a mask may be referred to as first etching treatment.

In other words, the sacrificial layer 158B, the sacrificial layer 158G, and the sacrificial layer 158R are not removed completely by the first etching treatment, and the etching treatment is stopped when the thicknesses of the sacrificial layer 158B, the sacrificial layer 158G, and the sacrificial layer 158R are reduced. The sacrificial layer 158B, the sacrificial layer 158G, and the sacrificial layer 158R remain over the organic compound layer 103B, the organic compound layer 103G, and the organic compound layer 103R correspondingly, whereby the organic compound layer 103B, the organic compound layer 103G, and the organic compound layer 103R can be prevented from being damaged by treatment in a later step.

The first etching treatment can be performed by dry etching or wet etching. Note that the inorganic insulating film 125f is preferably formed using a material similar to that for the sacrificial layer 158B, the sacrificial layer 158G, and the sacrificial layer 158R, in which case the processing of the inorganic insulating film 125f and thinning of the exposed part of the sacrificial layer 158 can be concurrently performed by the first etching treatment.

By etching using the insulating layer 127a with a tapered side surface as a mask, the side surface of the inorganic insulating layer 125 and upper edge portions of the side surfaces of the sacrificial layer 158B, the sacrificial layer 158G, and the sacrificial layer 158R can be made to have a tapered shape relatively easily.

In the case where the first etching treatment is performed by dry etching, for example, a chlorine-based gas can be used. As the chlorine-based gas, one of Cl₂, BCl₃, SiCl₄, CCl₄, and the like or a mixture of two or more of them can be used. Moreover, one of an oxygen gas, a hydrogen gas, a helium gas, an argon gas, and the like or a mixture of two or more of them can be added as appropriate to the chlorine-based gas. By the dry etching, the thin regions of the sacrificial layer 158B, the sacrificial layer 158G, and the sacrificial layer 158R can be formed with favorable in-plane uniformity.

The first etching treatment can be performed by wet etching, for example. The use of a wet etching method can reduce damage to the organic compound layer 103B, the organic compound layer 103G, and the organic compound layer 103R, as compared to the case of using a dry etching method.

The wet etching is preferably performed using an acidic chemical solution. As an acidic chemical solution, a chemical solution containing one of phosphoric acid, hydrofluoric acid, nitric acid, acetic acid, oxalic acid, sulfuric acid, and the like or a mixed chemical solution (also referred to as a mixed acid) that contains two or more of these acids is preferably used.

The wet etching can be performed using an alkaline solution. For example, TMAH, which is an alkaline solution, can be used for the wet etching of an aluminum oxide film. In that case, puddle wet etching can be performed.

After that, heat treatment (also referred to as post-baking) is performed. Next, the heat treatment is performed so that the insulating layer 127a can be changed into the insulating layer 127 having a taper-shaped side surface (FIG. 13C). The heat treatment is performed at a temperature lower than the heat resistance temperature of the organic compound layers. The heat treatment can be performed at a substrate temperature higher than or equal to 50° C. and lower than or equal to 200° C., preferably higher than or equal to 60° C. and lower than or equal to 150° C., further preferably higher than or equal to 70° C. and lower than or equal to 130° C. The heating atmosphere may be either an air atmosphere or an inert gas atmosphere. Alternatively, the heating atmosphere may be either an atmospheric pressure atmosphere or a reduced-pressure atmosphere. The heat treatment in this step is preferably performed at a higher substrate temperature than the heat treatment (pre-baking) after formation of the insulating film 127f.

The heat treatment can improve adhesion between the insulating layer 127 and the inorganic insulating layer 125 and increase corrosion resistance of the insulating layer 127. Furthermore, owing to the change in shape of the insulating layer 127a, an end portion of the inorganic insulating layer 125 can be covered with the insulating layer 127.

When the sacrificial layer 158B, the sacrificial layer 158G, and the sacrificial layer 158R are not completely removed by the first etching treatment and the sacrificial layer 158B, the sacrificial layer 158G, and the sacrificial layer 158R that are thinned are left, the organic compound layer 103B, the organic compound layer 103G, and the organic compound layer 103R can be prevented from deteriorating by being damaged in the heat treatment. This increases the reliability of the light-emitting device.

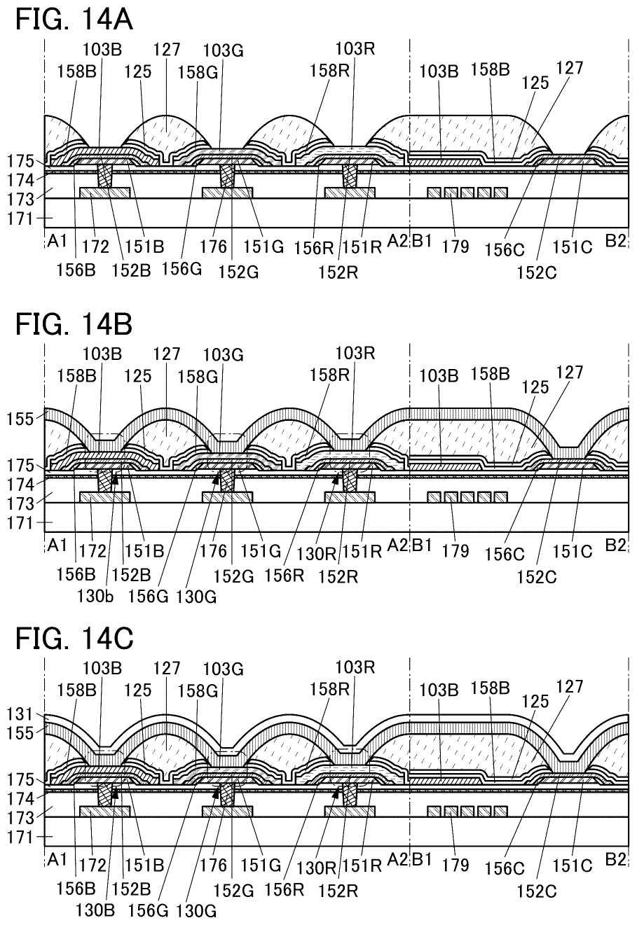

Next, as illustrated in FIG. 14A, etching treatment is performed using the insulating layer 127 as a mask to remove parts of the sacrificial layer 158B, the sacrificial layer 158G, and the sacrificial layer 158R. At this time, part of the inorganic insulating layer 125 is also removed in some cases. By the etching treatment, openings are formed in the sacrificial layer 158B, the sacrificial layer 158G, and the sacrificial layer 158R, and the top surfaces of the organic compound layer 103B, the organic compound layer 103G, and the organic compound layer 103R and the conductive layer 152C are exposed in the openings. Hereinafter, the etching treatment for exposing the organic compound layer 103B, the organic compound layer 103G, and the organic compound layer 103R using the insulating layer 127 as a mask may be referred to as second etching treatment.

The second etching treatment is performed by wet etching. The use of a wet etching method can reduce damage to the organic compound layer 103B, the organic compound layer 103G, and the organic compound layer 103R, as compared to the case of using a dry etching method. The wet etching can be performed using an acidic chemical solution or an alkaline solution as in the case of the first etching treatment.

Heat treatment may be performed after the organic compound layer 103B, the organic compound layer 103G, and the organic compound layer 103R are partly exposed. By the heat treatment, water included in the organic compound layer and water adsorbed on the surface of the organic compound layer, for example, can be removed. The shape of the insulating layer 127 may be changed by the heat treatment. Specifically, the insulating layer 127 may be widened to cover at least one of the end portion of the inorganic insulating layer 125, the end portions of the sacrificial layer 158B, the sacrificial layer 158G, and the sacrificial layer 158R, and the top surfaces of the organic compound layer 103B, the organic compound layer 103G, and the organic compound layer 103R.

FIG. 14A illustrates an example in which part of the end portion of the sacrificial layer 158G (specifically, the tapered portion formed by the first etching treatment) is covered with the insulating layer 127 and the tapered portion formed by the second etching treatment is exposed (see FIG. 7A).

The insulating layer 127 may cover the entire end portion of the sacrificial layer 158G. For example, the end portion of the insulating layer 127 may droop to cover the end portion of the sacrificial layer 158G. As another example, the end portion of the insulating layer 127 may be in contact with the top surface of at least one of the organic compound layer 103B, the organic compound layer 103G, and the organic compound layer 103R.

Next, as illustrated in FIG. 14B, a common electrode 155 is formed over the organic compound layer 103B, the organic compound layer 103G, and the organic compound layer 103R, the conductive layer 152C, and the insulating layer 127. The common electrode 155 can be formed by a method such as a sputtering method or a vacuum evaporation method. Alternatively, the common electrode 155 may be formed in such a manner that a film formed by an evaporation method and a film formed by a sputtering method are stacked.

Next, the protective layer 131 is formed over the common electrode 155 as illustrated in FIG. 14C. The protective layer 131 can be formed by a vacuum evaporation method, a sputtering method, a CVD method, an ALD method, or the like.

Then, the substrate 120 is bonded to the protective layer 131 using the resin layer 122, whereby the light-emitting apparatus can be manufactured. In the method for manufacturing the light-emitting apparatus of one embodiment of the present invention, the insulating layer 156 is provided to include a region overlapping with the side surface of the conductive layer 151 and the conductive layer 152 is formed to cover the conductive layer 151 and the insulating layer 156 as described above. This can increase the yield of the light-emitting apparatus and inhibit generation of defects.

As described above, in the method of manufacturing the light-emitting apparatus of one embodiment of the present invention, the organic compound layer 103B, the organic compound layer 103G, and the organic compound layer 103R that have island shapes are formed not by using a fine metal mask but by processing a film formed over the entire surface; thus, the island-shaped layers can be formed to have a uniform thickness. Consequently, a high-resolution light-emitting apparatus or a light-emitting apparatus with a high aperture ratio can be obtained. Furthermore, even when the resolution or the aperture ratio is high and the distance between subpixels is extremely short, the organic compound layer 103B, the organic compound layer 103G, and the organic compound layer 103R can be inhibited from being in contact with one another between adjacent subpixels. As a result, generation of a leakage current between the subpixels can be inhibited. This can prevent crosstalk, so that a light-emitting apparatus with extremely high contrast can be obtained. Moreover, even a light-emitting apparatus that includes light-emitting devices formed by a photolithography method can have favorable characteristics.

The structure of this embodiment can be used in combination with any of the other structures as appropriate.

### Embodiment 3

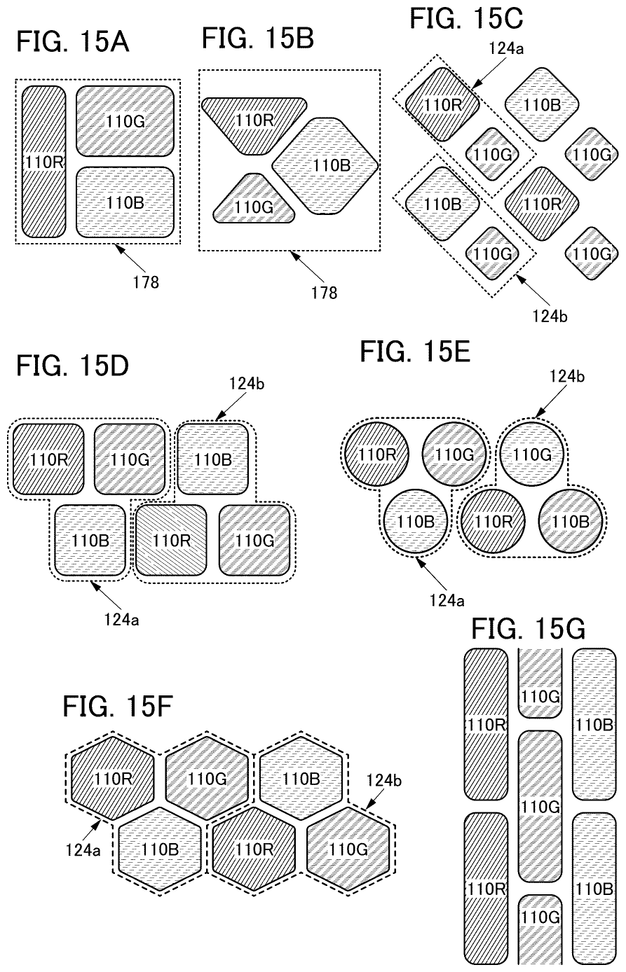

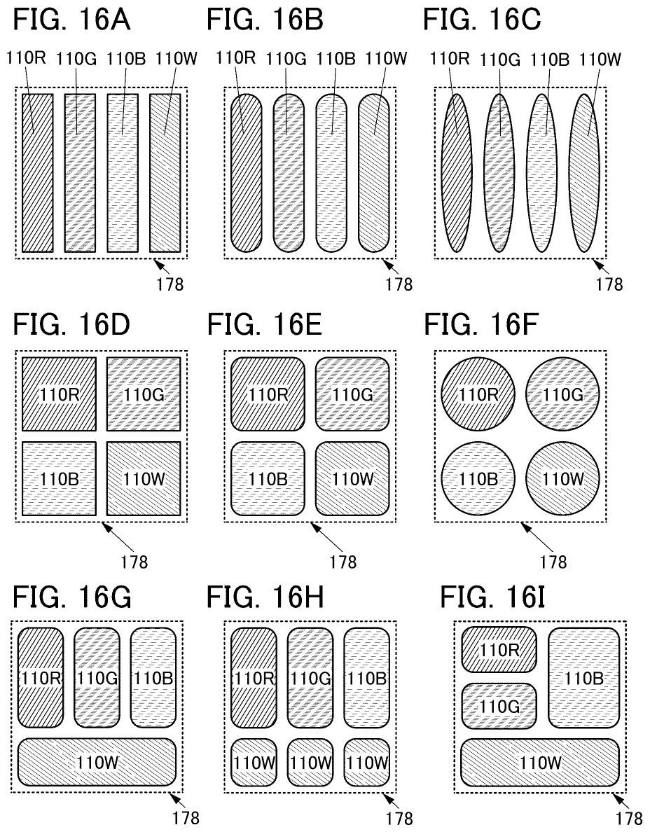

In this embodiment, the light-emitting apparatus of one embodiment of the present invention will be described with reference to FIG. 15A to FIG. 15G and FIG. 16A to FIG. 16I.

### [Pixel Layout]

In this embodiment, pixel layouts different from that in FIG. 5A will be mainly described. There is no particular limitation on the arrangement of subpixels, and a variety of methods can be employed. Examples of the arrangement of subpixels include stripe arrangement, S-stripe arrangement, matrix arrangement, delta arrangement, Bayer arrangement, and PenTile arrangement.

In this embodiment, the top surface shapes of the subpixels illustrated in the diagrams correspond to top surface shapes of light-emitting regions.

Examples of a top surface shape of the subpixel include polygons such as a triangle, a tetragon (including a rectangle and a square), and a pentagon; polygons with rounded corners; an ellipse; and a circle.

The circuit constituting the subpixel is not necessarily placed within the dimensions of the subpixel illustrated in the diagrams and may be placed outside the subpixel.

The pixel 178 illustrated in FIG. 15A employs S-stripe arrangement. The pixel 178 illustrated in FIG. 15A is composed of three subpixels: the subpixel 110R, the subpixel 110G, and the subpixel 110B.

The pixel 178 illustrated in FIG. 15B includes the subpixel 110R whose top surface has a rough trapezoidal shape with rounded corners, the subpixel 110G whose top surface has a rough triangle shape with rounded corners, and the subpixel 110B whose top surface has a rough tetragonal or rough hexagonal shape with rounded corners. The subpixel 110R has a larger light-emitting area than the subpixel 110G. In this manner, the shapes and sizes of the subpixels can be determined independently. For example, the size of a subpixel including a light-emitting device with higher reliability can be smaller.

A pixel 124a and a pixel 124b illustrated in FIG. 15C employ PenTile arrangement. FIG. 15C illustrates an example where the pixels 124a including the subpixel 110R and the subpixel 110G and the pixels 124b including the subpixel 110G and the subpixel 110B are alternately arranged.

The pixel 124a and the pixel 124b illustrated in FIG. 15D to FIG. 15F employ delta arrangement. The pixel 124a includes two subpixels (the subpixel 110R and the subpixel 110G) in the upper row (first row) and one subpixel (the subpixel 110B) in the lower row (second row). The pixel 124b includes one subpixel (the subpixel 110B) in the upper row (first row) and two subpixels (the subpixel 110R and the subpixel 110G) in the lower row (second row).

FIG. 15D illustrates an example in which the top surface of each subpixel has a rough tetragonal shape with rounded corners, FIG. 15E illustrates an example in which the top surface of each subpixel has a circular shape, and FIG. 15F illustrates an example in which the top surface of each subpixel has a rough hexagonal shape with rounded corners.

In FIG. 15F, the subpixels are placed inside the respective hexagonal regions that are arranged densely. Focusing on one of the subpixels, the subpixel is placed so as to be surrounded by six subpixels. The subpixels are arranged such that subpixels exhibiting light of the same color are not adjacent to each other. For example, focusing on the subpixel 110R, the subpixel 110R is surrounded by three subpixels 110G and three subpixels 110B that are alternately arranged.

FIG. 15G illustrates an example in which subpixels of different colors are arranged in a zigzag manner. Specifically, the positions of the top sides of two subpixels arranged in the column direction (e.g., the subpixel 110R and the subpixel 110G or the subpixel 110G and the subpixel 110B) are not aligned in the top view.

For example, in each pixel illustrated in FIG. 15A to FIG. 15G, it is preferable that the subpixel 110R be a subpixel R emitting red light, the subpixel 110G be a subpixel G emitting green light, and the subpixel 110B be a subpixel B emitting blue light. Note that the structure of the subpixels is not limited to this, and the colors and arrangement order of the subpixels can be determined as appropriate. For example, the subpixel 110G may be the subpixel R emitting red light and the subpixel 110R may be the subpixel G emitting green light.

In a photolithography method, as a pattern to be formed by processing becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, the top surface of a subpixel may have a polygonal shape with rounded corners, an elliptical shape, a circular shape, or the like.

Furthermore, in the method for manufacturing the light-emitting apparatus of one embodiment of the present invention, the organic compound layer is processed into an island shape with the use of a resist mask. A resist film formed over the organic compound layer needs to be cured at a temperature lower than the heat resistance temperature of the organic compound layer. Therefore, the resist film is insufficiently cured in some cases depending on the heat resistance temperature of the material of the organic compound layer and the curing temperature of the resist material. An insufficiently cured resist film may have a shape different from a desired shape by processing. As a result, the top surface of the organic compound layer may have a polygonal shape with rounded corners, an elliptical shape, a circular shape, or the like. For example, when a resist mask with a square top surface is intended to be formed, a resist mask with a circular top surface may be formed, and the top surface of the organic compound layer may be circular.

To obtain a desired top surface shape of the organic compound layer, a technique of correcting a mask pattern in advance so that a transferred pattern agrees with a design pattern (an optical proximity correction (OPC) technique) may be used. Specifically, with the OPC technique, a pattern for correction is added to a corner portion of a figure on a mask pattern, for example.

As illustrated in FIG. 16A to FIG. 16I, the pixel can include four types of subpixels.

The pixels 178 illustrated in FIG. 16A to FIG. 16C each employ stripe arrangement.

FIG. 16A illustrates an example in which each subpixel has a rectangular top surface shape, FIG. 16B illustrates an example in which each subpixel has a top surface shape formed by combining two half circles and a rectangle, and FIG. 16C illustrates an example in which each subpixel has an elliptical top surface shape.

The pixels 178 illustrated in FIG. 16D to FIG. 16F each employ matrix arrangement.

FIG. 16D illustrates an example in which each subpixel has a square top surface shape, FIG. 16E illustrates an example in which each subpixel has a rough square top surface shape with rounded corners, and FIG. 16F illustrates an example in which each subpixel has a circular top surface shape.

FIG. 16G and FIG. 16H each illustrate an example in which one pixel 178 is composed of two rows and three columns.

The pixel 178 illustrated in FIG. 16G includes three subpixels (the subpixel 110R, the subpixel 110G, and the subpixel 110B) in the upper row (first row) and one subpixel (a subpixel 110W) in the lower row (second row). In other words, the pixel 178 includes the subpixel 110R in the left column (first column), the subpixel 110G in the center column (second column), the subpixel 110B in the right column (third column), and the subpixel 110W across these three columns.

The pixel 178 illustrated in FIG. 16H includes three subpixels (the subpixel 110R, the subpixel 110G, and the subpixel 110B) in the upper row (first row) and three of the subpixels 110W in the lower row (second row). In other words, the pixel 178 includes the subpixel 110R and the subpixel 110W in the left column (first column), the subpixel 110G and another subpixel 110W in the center column (second column), and the subpixel 110B and another subpixel 110W in the right column (third column). Matching the positions of the subpixels in the upper row and the lower row as illustrated in FIG. 16H enables efficient removal of dust that would be produced in the manufacturing process, for example. Thus, a light-emitting apparatus with high display quality can be provided.

In the pixel 178 illustrated in FIG. 16G and FIG. 16H, stripe arrangement is employed as the layout of the subpixel 110R, the subpixel 110G, and the subpixel 110B, whereby the display quality can be improved.

FIG. 16I illustrates an example where one pixel 178 is composed of three rows and two columns.

The pixel 178 illustrated in FIG. 16I includes the subpixel 110R in the upper row (first row), the subpixel 110G in the center row (second row), the subpixel 110B across the first and second rows, and one subpixel (the subpixel 110W) in the lower row (third row). In other words, the pixel 178 includes the subpixel 110R and the subpixel 110G in the left column (first column), the subpixel 110B in the right column (second column), and the subpixel 110W across these two columns.

In the pixel 178 illustrated in FIG. 16I, so-called S stripe arrangement is employed as the layout of the subpixel 110R, the subpixel 110G, and the subpixel 110B, whereby the display quality can be improved.

The pixel 178 illustrated in FIG. 16A to FIG. 16I consists of four subpixels: the subpixel 110R, the subpixel 110G, the subpixel 110B, and the subpixel 110W. For example, the subpixel 110R can be a subpixel that emits red light, the subpixel 110G can be a subpixel that emits green light, the subpixel 110B can be a subpixel that emits blue light, and the subpixel 110W can be a subpixel that emits white light. Note that at least one of the subpixel 110R, the subpixel 110G, the subpixel 110B, and the subpixel 110W may be a subpixel that emits cyan light, a subpixel that emits magenta light, a subpixel that emits yellow light, or a subpixel that emits near-infrared light.

As described above, the pixel composed of the subpixels each including the light-emitting device can employ any of a variety of layouts in the light-emitting apparatus of one embodiment of the present invention.

This embodiment can be combined with the other embodiments as appropriate. In this specification, in the case where a plurality of structure examples are shown in one embodiment, the structure examples can be combined as appropriate.

### Embodiment 4

In this embodiment, a light-emitting apparatus of one embodiment of the present invention will be described.

The light-emitting apparatus in this embodiment can be a high-resolution light-emitting apparatus. Thus, the light-emitting apparatus of this embodiment can be used for a display portion of a wearable device, for example. Examples of the wearable device include information terminals such as watch-type and bracelet-type information terminals and electronic apparatuses capable of being worn on the head, such as a VR (Virtual Reality) device like a head-mounted display (HMD) and an AR (Augmented Reality) device of glasses-type or the like.

The light-emitting apparatus in this embodiment can be a high-definition light-emitting apparatus or a large-sized light-emitting apparatus. Accordingly, the light-emitting apparatus in this embodiment can be used for a relatively large display portion of, for example, a television device, a desktop or laptop personal computer, a monitor of a computer or the like, digital signage, or a large game machine such as a pachinko machine. The light-emitting apparatus of this embodiment can be used for a relatively small display portion of, for example, a digital camera, a digital video camera, a digital photo frame, a mobile phone, a portable game console, a portable information terminal, and an audio reproducing device.

### [Display Module]

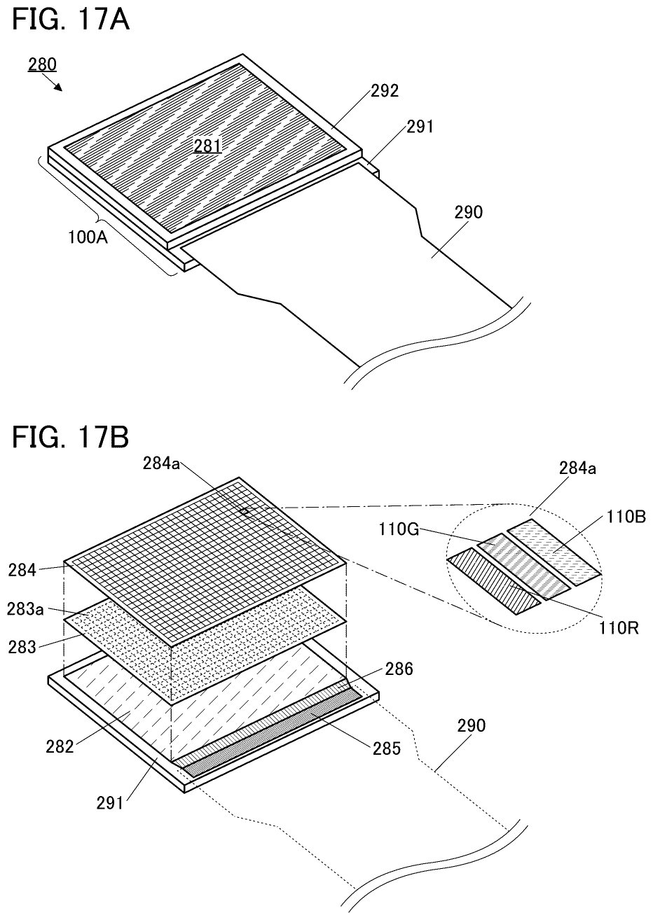

FIG. 17A is a perspective view of a display module 280. The display module 280 includes a light-emitting apparatus 100A and an FPC 290. Note that the light-emitting apparatus included in the display module 280 is not limited to the light-emitting apparatus 100A and may be any of a light-emitting apparatus 100B and a light-emitting apparatus 100C described later.

The display module 280 includes a substrate 291 and a substrate 292. The display module 280 includes a display portion 281. The display portion 281 is a region of the display module 280 where an image is displayed, and is a region where light emitted from pixels provided in a pixel portion 284 described later can be seen.

FIG. 17B is a perspective view schematically illustrating a structure on the substrate 291 side. Over the substrate 291, a circuit portion 282, a pixel circuit portion 283 over the circuit portion 282, and the pixel portion 284 over the pixel circuit portion 283 are stacked. A terminal portion 285 to be connected to the FPC 290 is provided over the substrate 291 in a portion that does not overlap with the pixel portion 284. The terminal portion 285 and the circuit portion 282 are electrically connected to each other through a wiring portion 286 formed of a plurality of wirings.

The pixel portion 284 includes a plurality of pixels 284a arranged periodically. An enlarged view of one pixel 284a is illustrated on the right side in FIG. 17B. The pixel 284a can employ any of the structures described in the above embodiments. FIG. 17B illustrates an example where the pixel 284a has a structure similar to that of the pixel 178 illustrated in FIG. 5.

The pixel circuit portion 283 includes a plurality of pixel circuits 283a arranged periodically.

One pixel circuit 283a is a circuit that controls driving of a plurality of elements included in one pixel 284a. One pixel circuit 283a can be provided with three circuits each of which controls light emission of one light-emitting device. For example, the pixel circuit 283a can include at least one selection transistor, one current control transistor (driving transistor), and a capacitor for one light-emitting device. A gate signal is input to a gate of the selection transistor, and a video signal is input to a source or a drain of the selection transistor. With such a structure, an active-matrix light-emitting apparatus is achieved.

The circuit portion 282 includes a circuit for driving the pixel circuits 283a in the pixel circuit portion 283. For example, one or both of a gate line driver circuit and a source line driver circuit are preferably included. The circuit portion 282 may also include at least one of an arithmetic circuit, a memory circuit, a power supply circuit, and the like.

The FPC 290 functions as a wiring for supplying a video signal, a power supply potential, or the like to the circuit portion 282 from the outside. An IC may be mounted on the FPC 290.

The display module 280 can have a structure in which one or both of the pixel circuit portion 283 and the circuit portion 282 are stacked below the pixel portion 284; hence, the aperture ratio (effective display area ratio) of the display portion 281 can be significantly high. For example, the aperture ratio of the display portion 281 can be greater than or equal to 40% and less than 100%, preferably greater than or equal to 50% and less than or equal to 95%, further preferably greater than or equal to 60% and less than or equal to 95%. Furthermore, the pixels 284a can be arranged extremely densely and thus the display portion 281 can have significantly high resolution. For example, the pixels 284a are preferably arranged in the display portion 281 with a resolution of greater than or equal to 2000 ppi, further preferably greater than or equal to 3000 ppi, still further preferably greater than or equal to 5000 ppi, yet still further preferably greater than or equal to 6000 ppi, and less than or equal to 20000 ppi or less than or equal to 30000 ppi.

Such a display module 280 has extremely high resolution, and thus can be suitably used for a VR device such as a HMD or a glasses-type AR device. For example, even in the case of a structure in which the display portion of the display module 280 is seen through a lens, pixels of the extremely-high-resolution display portion 281 included in the display module 280 are prevented from being recognized when the display portion is enlarged by the lens, so that display providing a high sense of immersion can be performed. Without being limited thereto, the display module 280 can be suitably used for electronic apparatuses including a relatively small display portion. For example, the display module 280 can be suitably used in a display portion of a wearable electronic apparatus, such as a wrist watch.

### [Light-Emitting Apparatus 100A]

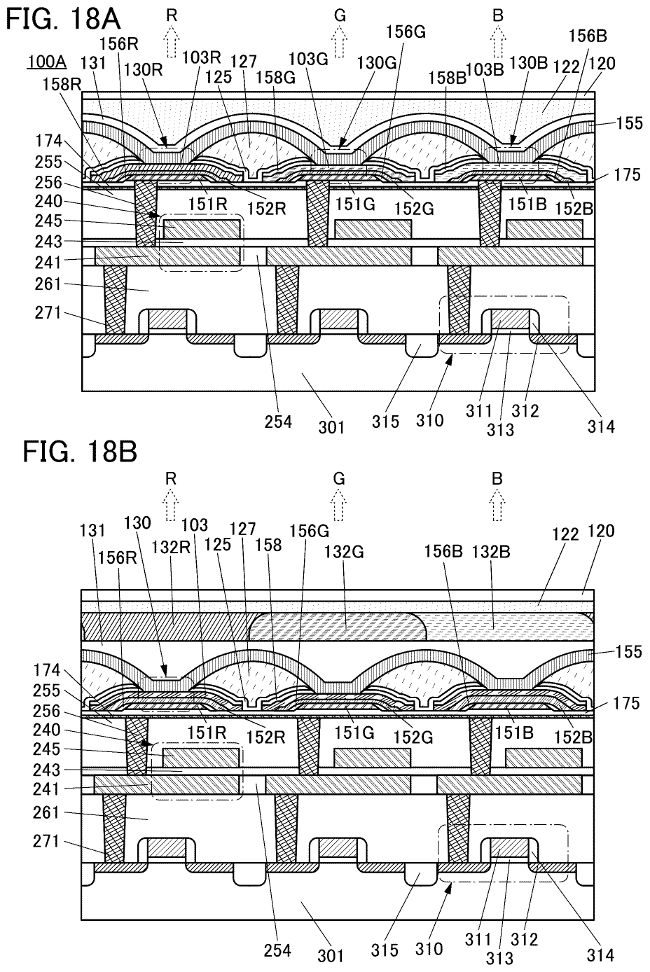

The light-emitting apparatus 100A illustrated in FIG. 18A includes a substrate 301, the light-emitting device 130R, the light-emitting device 130G, the light-emitting device 130B, a capacitor 240, and a transistor 310.

The substrate 301 corresponds to the substrate 291 in FIG. 17A and FIG. 17B. The transistor 310 is a transistor including a channel formation region in the substrate 301. As the substrate 301, a semiconductor substrate such as a single crystal silicon substrate can be used, for example. The transistor 310 includes part of the substrate 301, a conductive layer 311, low-resistance regions 312, an insulating layer 313, and insulating layers 314. The conductive layer 311 functions as a gate electrode. The insulating layer 313 is positioned between the substrate 301 and the conductive layer 311 and functions as a gate insulating layer. The low-resistance region 312 is a region where the substrate 301 is doped with an impurity, and functions as a source and a drain. The insulating layers 314 are provided to cover a side surface of the conductive layer 311.

An element isolation layer 315 is provided between two adjacent transistors 310 to be embedded in the substrate 301.

An insulating layer 261 is provided to cover the transistor 310, and the capacitor 240 is provided over the insulating layer 261.

The capacitor 240 includes a conductive layer 241, a conductive layer 245, and an insulating layer 243 positioned therebetween. The conductive layer 241 functions as one electrode of the capacitor 240, the conductive layer 245 functions as the other electrode of the capacitor 240, and the insulating layer 243 functions as a dielectric of the capacitor 240.

The conductive layer 241 is provided over the insulating layer 261 and is embedded in an insulating layer 254. The conductive layer 241 is electrically connected to one of the source and the drain of the transistor 310 through a plug 271 embedded in the insulating layer 261. The insulating layer 243 is provided to cover the conductive layer 241. The conductive layer 245 is provided in a region overlapping the conductive layer 241 with the insulating layer 243 therebetween.

An insulating layer 255 is provided to cover the capacitor 240, the insulating layer 174 is provided over the insulating layer 255, and the insulating layer 175 is provided over the insulating layer 174. The light-emitting device 130R, the light-emitting device 130G, and the light-emitting device 130B are provided over the insulating layer 175. FIG. 18A illustrates an example where the light-emitting device 130R, the light-emitting device 130G, and the light-emitting device 130B each have a structure similar to the stacked-layer structure illustrated in FIG. 5B. An insulator is provided in a region between adjacent light-emitting devices. In FIG. 18A, for example, the inorganic insulating layer 125 and the insulating layer 127 over the inorganic insulating layer 125 are provided in this region.

The insulating layer 156R is provided to include a region overlapping a side surface of the conductive layer 151R of the light-emitting device 130R. The insulating layer 156G is provided to include a region overlapping a side surface of the conductive layer 151G of the light-emitting device 130G. The insulating layer 156B is provided to include a region overlapping a side surface of the conductive layer 151B of the light-emitting device 130B. The conductive layer 152R is provided to cover the conductive layer 151R and the insulating layer 156R. The conductive layer 152G is provided to cover the conductive layer 151G and the insulating layer 156G. The conductive layer 152B is provided to cover the conductive layer 151B and the insulating layer 156B. The sacrificial layer 158R is positioned over the organic compound layer 103R of the light-emitting device 130R. The sacrificial layer 158G is positioned over the organic compound layer 103G of the light-emitting device 130G. The sacrificial layer 158B is positioned over the organic compound layer 103B of the light-emitting device 130B.

Each of the conductive layer 151R, the conductive layer 151G, and the conductive layer 151B is electrically connected to one of the source and the drain of the corresponding transistor 310 through a plug 256 embedded in the insulating layer 243, the insulating layer 255, the insulating layer 174, and the insulating layer 175, the conductive layer 241 embedded in the insulating layer 254, and the plug 271 embedded in the insulating layer 261. The top surface of the insulating layer 175 and the top surface of the plug 256 are level with or substantially level with each other. Any of a variety of conductive materials can be used for the plugs.

The protective layer 131 is provided over the light-emitting device 130R, the light-emitting device 130G, and the light-emitting device 130B. A substrate 120 is bonded to the protective layer 131 with a resin layer 122. Embodiment 2 can be referred to for the details of the light-emitting device 130 and the components thereover up to the substrate 120. The substrate 120 corresponds to the substrate 292 in FIG. 17A.

FIG. 18B illustrates a modification example of the light-emitting apparatus 100A illustrated in FIG. 18A. The light-emitting apparatus illustrated in FIG. 18B includes a coloring layer 132R, a coloring layer 132G, and a coloring layer 132B, and each of the light-emitting devices 130 includes a region overlapping with one of the coloring layer 132R, the coloring layer 132G, and the coloring layer 132B. In the light-emitting apparatus illustrated in FIG. 18B, the light-emitting device 130 can emit white light, for example. For example, the coloring layer 132R can transmit red light, the coloring layer 132G can transmit green light, and the coloring layer 132B can transmit blue light.

### [Light-Emitting Apparatus 100B]

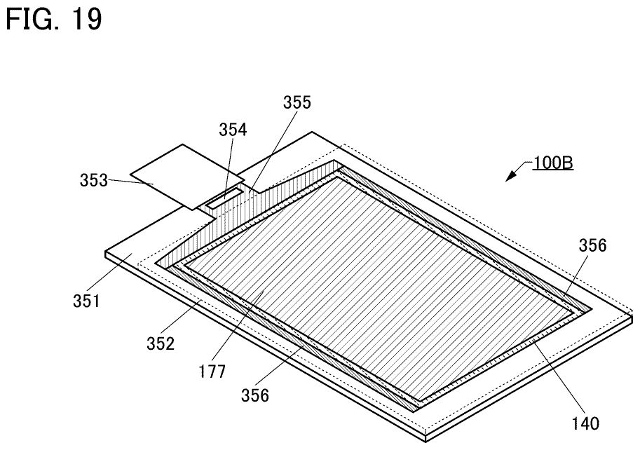

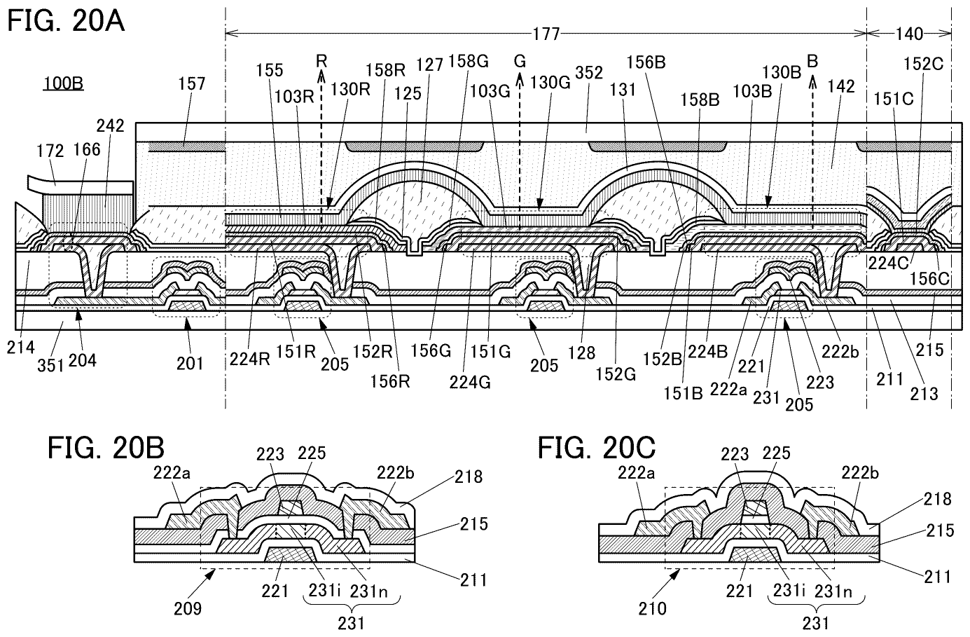

FIG. 19 illustrates a perspective view of the light-emitting apparatus 100B and FIG. 20A illustrates a cross-sectional view of the light-emitting apparatus 100B.

In the light-emitting apparatus 100B, a substrate 352 and a substrate 351 are bonded to each other. In FIG. 19, the substrate 352 is denoted by a dashed line.

The light-emitting apparatus 100B includes the pixel portion 177, the connection portion 140, a circuit 356, a wiring 355, and the like. FIG. 19 illustrates an example in which an IC 354 and an FPC 353 are mounted on the light-emitting apparatus 100B. Thus, the structure illustrated in FIG. 19 can be regarded as a display module including the light-emitting apparatus 100B, the integrated circuit (IC), and the FPC. Here, a light-emitting apparatus in which a substrate is equipped with a connector such as an FPC or mounted with an IC is referred to as a display module.

The connection portion 140 is provided outside the pixel portion 177. The connection portion 140 can be provided along one side or a plurality of sides of the pixel portion 177. The number of connection portions 140 may be one or more. FIG. 19 illustrates an example where the connection portion 140 is provided to surround the four sides of the display portion. In the connection portion 140, a common electrode of a light-emitting device is electrically connected to a conductive layer, so that a potential can be supplied to the common electrode.

As the circuit 356, a scan line driver circuit can be used, for example.

The wiring 355 has a function of supplying a signal and power to the pixel portion 177 and the circuit 356. The signal and power are input to the wiring 355 from the outside through the FPC 353 or from the IC 354.

FIG. 19 illustrates an example in which the IC 354 is provided over the substrate 351 by a COG (chip on glass) method, a COF (chip on film) method, or the like. An IC including a scan line driver circuit, a signal line driver circuit, or the like can be used as the IC 354, for example. Note that the light-emitting apparatus 100B and the display module are not necessarily provided with an IC. Alternatively, the IC may be mounted on the FPC by a COF method, for example.

FIG. 20A illustrates examples of cross sections of part of a region including the FPC 353, part of the circuit 356, part of the pixel portion 177, part of the connection portion 140, and part of a region including an end portion of the light-emitting apparatus 100B.

The light-emitting apparatus 100B illustrated in FIG. 20A includes a transistor 201, a transistor 205, the light-emitting device 130R emitting red light, the light-emitting device 130G emitting green light, and the light-emitting device 130B between the substrate 351 and the substrate 352.

The stacked-layer structure of each of the light-emitting device 130R, the light-emitting device 130G, and the light-emitting device 130B is the same as that illustrated in FIG. 5B except the structure of the pixel electrode. Embodiment 1 and Embodiment 2 can be referred to for the details of the light-emitting devices.

The light-emitting device 130R includes a conductive layer 224R, the conductive layer 151R over the conductive layer 224R, and the conductive layer 152R over the conductive layer 151R. The light-emitting device 130G includes a conductive layer 224G, the conductive layer 151G over the conductive layer 224G, and the conductive layer 152G over the conductive layer 151G. The light-emitting device 130B includes a conductive layer 224B, the conductive layer 151B over the conductive layer 224B, and the conductive layer 152B over the conductive layer 151B. Here, the conductive layer 224R, the conductive layer 151R, and the conductive layer 152R can be collectively referred to as the pixel electrode of the light-emitting device 130R; the conductive layer 151R and the conductive layer 152R excluding the conductive layer 224R can also be referred to as the pixel electrode of the light-emitting device 130R. Similarly, the conductive layer 224G, the conductive layer 151G, and the conductive layer 152G can be collectively referred to as the pixel electrode of the light-emitting device 130G; the conductive layer 151G and the conductive layer 152G excluding the conductive layer 224G can also be referred to as the pixel electrode of the light-emitting device 130G. The conductive layer 224B, the conductive layer 151B, and the conductive layer 152B can be collectively referred to as the pixel electrode of the light-emitting device 130B; the conductive layer 151B and the conductive layer 152B excluding the conductive layer 224B can also be referred to as the pixel electrode of the light-emitting device 130B.

The conductive layer 224R is connected to a conductive layer 222b included in the transistor 205 through an opening provided in an insulating layer 214. The end portion of the conductive layer 151R is positioned outward from the edge portion of the conductive layer 224R. The insulating layer 156R is provided to include a region that is in contact with the side surface of the conductive layer 151R, and the conductive layer 152R is provided to cover the conductive layer 151R and the insulating layer 156R.

The conductive layer 224G, the conductive layer 151G, and the conductive layer 152G and the insulating layer 156G in the light-emitting device 130G and the conductive layer 224B, the conductive layer 151B, and the conductive layer 152B and the insulating layer 156B in the light-emitting device 130B are not described in detail because they are respectively similar to the conductive layer 224R, the conductive layer 151R, and the conductive layer 152R and the insulating layer 156R in the light-emitting device 130R.

The conductive layer 224R, the conductive layer 224G, and the conductive layer 224B each have a depression portion covering an opening provided in the insulating layer 214. A layer 128 is embedded in the depression portion.

The layer 128 has a planarization function for the depressed portions of the conductive layer 224R, the conductive layer 224G, and the conductive layer 224B. The conductive layer 151R that is electrically connected to the conductive layer 224R is provided over the conductive layer 224R and the layer 128 embedded in the depressed portion of the conductive layer 224R. The conductive layer 151G that is electrically connected to the conductive layer 224G is provided over the conductive layer 224G and the layer 128 embedded in the depressed portion of the conductive layer 224G. The conductive layer 151B that is electrically connected to the conductive layer 224B is provided over the conductive layer 224B and the layer 128 embedded in the depressed portion of the conductive layer 224B. Thus, regions over the conductive layer 151R, the conductive layer 151G, and the conductive layer 151B which overlap with the depressed portions of the conductive layer 224R, the conductive layer 224G, and the conductive layer 224B can also be used as the light-emitting regions, whereby the aperture ratio of the pixels can be increased.

The layer 128 may be an insulating layer or a conductive layer. Any of a variety of inorganic insulating materials, organic insulating materials, and conductive materials can be used for the layer 128 as appropriate. Specifically, the layer 128 is preferably formed using an insulating material and is particularly preferably formed using an organic insulating material. The layer 128 can be formed using an organic insulating material usable for the insulating layer 127, for example.

The protective layer 131 is provided over the light-emitting device 130R, the light-emitting device 130G, and the light-emitting device 130B. The protective layer 131 and the substrate 352 are bonded to each other with an adhesive layer 142. The substrate 352 is provided with a light-blocking layer 157. A solid sealing structure, a hollow sealing structure, or the like can be employed to seal the light-emitting device 130. In FIG. 20A, a solid sealing structure is employed, in which a space between the substrate 352 and the substrate 351 is filled with the adhesive layer 142. Alternatively, a hollow sealing structure in which the space is filled with an inert gas (e.g., nitrogen or argon) may be employed. Here, the adhesive layer 142 may be provided not to overlap with the light-emitting device. The space may be filled with a resin different from that of the frame-like adhesive layer 142.

FIG. 20A illustrates an example in which the connection portion 140 includes a conductive layer 224C obtained by processing the same conductive film as the conductive layer 224R, the conductive layer 224G, and the conductive layer 224B, the conductive layer 151C obtained by processing the same conductive film as the conductive layer 151R, the conductive layer 151G, and the conductive layer 151B, and the conductive layer 152C obtained by processing the same conductive film as the conductive layer 152R, the conductive layer 152G, and the conductive layer 152B. In the example illustrated in FIG. 20A, the insulating layer 156C is provided to include a region overlapping with the side surface of the conductive layer 151C.

The light-emitting apparatus 100B has a top-emission structure. Light from the light-emitting device is emitted toward the substrate 352. For the substrate 352, a material having a high visible-light-transmitting property is preferably used. The pixel electrode contains a material that reflects visible light, and the counter electrode (the common electrode 155) contains a material that transmits visible light.

Both of the transistor 201 and the transistor 205 are formed over the substrate 351. These transistors can be fabricated using the same materials in the same steps.

An insulating layer 211, an insulating layer 213, an insulating layer 215, and the insulating layer 214 are provided in this order over the substrate 351. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or more.

A material through which impurities such as water and hydrogen do not easily diffuse is preferably used for at least one of the insulating layers covering the transistors. This is because such an insulating layer can function as a barrier layer. Such a structure can effectively inhibit diffusion of impurities to the transistors from the outside and increase the reliability of the light-emitting apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating layer is suitable as the insulating layer 214 functioning as a planarization layer. Examples of materials that can be used for the organic insulating layer include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating layer and an inorganic insulating layer. The outermost layer of the insulating layer 214 preferably functions as an etching protective layer. This can inhibit formation of a depressed portion in the insulating layer 214 at the time of processing of the conductive layer 224R, the conductive layer 151R, or the conductive layer 152R or the like. Alternatively, a depressed portion may be provided in the insulating layer 214 at the time of processing of the conductive layer 224R, the conductive layer 151R, or the conductive layer 152R or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the light-emitting apparatus of this embodiment. For example, a planar transistor, a staggered transistor, an inverted staggered transistor, or the like can be used. A top-gate transistor or a bottom-gate transistor can be used. Alternatively, gates may be provided above and below a semiconductor layer where a channel is formed.

The structure in which the semiconductor layer where a channel is formed is provided between two gates is used for the transistor 201 and the transistor 205. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and either an amorphous semiconductor or a semiconductor having crystallinity (a microcrystalline semiconductor, a polycrystalline semiconductor, a single crystal semiconductor, or a semiconductor partly including crystal regions) can be used. A semiconductor having crystallinity is preferably used, in which case deterioration of transistor characteristics can be suppressed.

The semiconductor layer of the transistor preferably contains a metal oxide. That is, a transistor including a metal oxide in its channel formation region (hereinafter also referred to as an OS transistor) is preferably used in the light-emitting apparatus of this embodiment.

As examples of the oxide semiconductor having crystallinity, a CAAC (c-axis aligned crystalline)-OS, an nc (nanocrystalline)-OS, and the like can be given.

Alternatively, a transistor including silicon in its channel formation region (a Si transistor) may be used. Examples of silicon include single crystal silicon, polycrystalline silicon, and amorphous silicon. In particular, a transistor containing low-temperature polysilicon (LTPS) in its semiconductor layer (hereinafter also referred to as an LTPS transistor) can be used. The LTPS transistor has high field-effect mobility and excellent frequency characteristics.

With the use of Si transistors such as LTPS transistors, a circuit required to be driven at a high frequency (e.g., a source driver circuit) can be formed on the same substrate as the display portion. This allows for simplification of an external circuit mounted on the light-emitting apparatus and a reduction in costs of parts and mounting costs.

An OS transistor has much higher field-effect mobility than a transistor containing amorphous silicon. In addition, the OS transistor has an extremely low leakage current between a source and a drain in an off state (hereinafter, also referred to as off-state current), and charge accumulated in a capacitor that is connected in series to the transistor can be retained for a long period. Furthermore, the power consumption of the light-emitting apparatus can be reduced with the OS transistor.

To increase the luminance of the light-emitting device included in the pixel circuit, the amount of current fed through the light-emitting device needs to be increased. To increase the current amount, the source-drain voltage of a driving transistor included in the pixel circuit needs to be increased. An OS transistor has a higher breakdown voltage between a source and a drain than a Si transistor; hence, a high voltage can be applied between the source and the drain of the OS transistor. Therefore, when an OS transistor is used as the driving transistor in the pixel circuit, the amount of current flowing through the light-emitting device can be increased, so that the luminance of the light-emitting device can be increased.

When transistors operate in a saturation region, a change in a source-drain current relative to a change in a gate-source voltage can be smaller in an OS transistor than in a Si transistor. Accordingly, when an OS transistor is used as the driving transistor in the pixel circuit, a current flowing between the source and the drain can be set minutely by a change in a gate-source voltage; hence, the amount of current flowing through the light-emitting device can be controlled. Consequently, the number of gray levels expressed by the pixel circuit can be increased.

Regarding saturation characteristics of a current flowing when transistors operate in a saturation region, even in the case where the source-drain voltage of an OS transistor increases gradually, a more stable current (saturation current) can be fed through the OS transistor than through a Si transistor. Thus, by using an OS transistor as the driving transistor, a stable current can be fed through light-emitting devices even when the current-voltage characteristics of the light-emitting devices vary, for example. In other words, when the OS transistor operates in the saturation region, the source-drain current hardly changes with an increase in the source-drain voltage; hence, the luminance of the light-emitting device can be stable.

As described above, by using OS transistors as the driving transistors included in the pixel circuits, it is possible to inhibit black-level degradation, increase the luminance, increase the number of gray levels, and suppress variations in light-emitting devices, for example.

The semiconductor layer preferably contains indium, M(Mis one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor layer. It is preferable to use an oxide containing indium, tin, and zinc. It is preferable to use an oxide containing indium, gallium, tin, and zinc. It is preferable to use an oxide containing indium (In), aluminum (Al), and zinc (Zn) (also referred to as IAZO). It is preferable to use an oxide containing indium (In), aluminum (Al), gallium (Ga), and zinc (Zn) (also referred to as IAGZO).

When the semiconductor layer is an In-M-Zn oxide, the atomic ratio of In is preferably greater than or equal to the atomic ratio of Min the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that the neighborhood of the atomic ratio includes ±30% of an intended atomic ratio.

For example, in the case of describing an atomic ratio of In:Ga:Zn=4:2:3 or a composition in the neighborhood thereof, the case is included in which with the atomic proportion of In being 4, the atomic proportion of Ga is greater than or equal to 1 and less than or equal to 3 and the atomic proportion of Zn is greater than or equal to 2 and less than or equal to 4. In the case of describing an atomic ratio of In:Ga:Zn=5:1:6 or a composition in the neighborhood thereof, the case is included in which with the atomic proportion of In being 5, the atomic proportion of Ga is greater than 0.1 and less than or equal to 2 and the atomic proportion of Zn is greater than or equal to 5 and less than or equal to 7. In the case of describing an atomic ratio of In:Ga:Zn=1:1:1 or a composition in the neighborhood thereof, the case is included in which with the atomic proportion of In being 1, the atomic proportion of Ga is greater than 0.1 and less than or equal to 2 and the atomic proportion of Zn is greater than 0.1 and less than or equal to 2.

The transistors included in the circuit 356 and the transistors included in the pixel portion 177 may have the same structure or different structures. One structure or two or more kinds of structures may be employed for a plurality of transistors included in the circuit 356. Similarly, one structure or two or more kinds of structures may be employed for a plurality of transistors included in the pixel portion 177.

All transistors included in the pixel portion 177 may be OS transistors, or all transistors included in the pixel portion 177 may be Si transistors. Alternatively, some of the transistors included in the pixel portion 177 may be OS transistors and the others may be Si transistors.

For example, when both an LTPS transistor and an OS transistor are used in the pixel portion 177, the light-emitting apparatus can have low power consumption and high driving capability. Note that a structure in which an LTPS transistor and an OS transistor are used in combination is referred to as LTPO in some cases. For example, it is preferable that an OS transistor be used as a transistor functioning as a switch for controlling switching between the conducting state and the non-conducting state of a wiring and an LTPS transistor be used as a transistor for controlling a current.

For example, one transistor included in the pixel portion 177 functions as a transistor for controlling a current flowing through the light-emitting device and can be referred to as a driving transistor. One of a source and a drain of the driving transistor is electrically connected to the pixel electrode of the light-emitting device. An LTPS transistor is preferably used as the driving transistor. In that case, the amount of current flowing through the light-emitting device can be increased in the pixel circuit.

Another transistor included in the pixel portion 177 functions as a switch for controlling selection or non-selection of a pixel and can be referred to as a selection transistor. A gate of the selection transistor is electrically connected to a gate line, and one of a source and a drain thereof is electrically connected to a source line (signal line). An OS transistor is preferably used as the selection transistor. In that case, the gray level of the pixel can be maintained even with an extremely low frame frequency (e.g., lower than or equal to 1 fps); thus, power consumption can be reduced by stopping the driver in displaying a still image.

As described above, the light-emitting apparatus of one embodiment of the present invention can have all of a high aperture ratio, high resolution, high display quality, and low power consumption.

Note that the light-emitting apparatus of one embodiment of the present invention has a structure including the OS transistor and the light-emitting device having a metal maskless (MML) structure. This structure can significantly reduce a leakage current that would flow through a transistor and a leakage current that would flow between adjacent light-emitting devices (sometimes referred to as a horizontal leakage current or a lateral leakage current). Displaying images on the light-emitting apparatus having this structure can bring one or more of image crispness, image sharpness, high color saturation, and a high contrast ratio to the viewer. When a leakage current that would flow through the transistor and a lateral leakage current that would flow between the light-emitting devices are extremely low, leakage of light at the time of black display (black-level degradation) or the like can be minimized.

In particular, in the case where a light-emitting device having the MML structure employs the above-described SBS structure, a layer provided between light-emitting devices (for example, an organic layer shared by the light-emitting devices, also referred to as a common layer) is disconnected; accordingly, side leakage can be eliminated or reduced as much as possible.

FIG. 20B and FIG. 20C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the pair of low-resistance regions 231n, the conductive layer 222b connected to the other of the pair of low-resistance regions 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 20B illustrates an example of the transistor 209 in which the insulating layer 225 covers a top surface and a side surface of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

In the transistor 210 illustrated in FIG. 20C, the insulating layer 225 overlaps with the channel formation region 231i of the semiconductor layer 231 and does not overlap with the low-resistance regions 231n. The structure illustrated in FIG. 20C is obtained by processing the insulating layer 225 with the conductive layer 223 as a mask, for example. In FIG. 20C, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 351 where the substrate 352 does not overlap. In the connection portion 204, the wiring 355 is electrically connected to the FPC 353 through a conductive layer 166 and a connection layer 242. As an example, the conductive layer 166 has a stacked-layer structure of a conductive film obtained by processing the same conductive film as the conductive layer 224R, the conductive layer 224G, and the conductive layer 224B; a conductive film obtained by processing the same conductive film as the conductive layer 151R, the conductive layer 151G, and the conductive layer 151B; and a conductive film obtained by processing the same conductive film as the conductive layer 152R, the conductive layer 152G, and the conductive layer 152B. On the top surface of the connection portion 204, the conductive layer 166 is exposed. Thus, the connection portion 204 and the FPC 353 can be electrically connected to each other through the connection layer 242.

A light-blocking layer 157 is preferably provided on the surface of the substrate 352 on the substrate 351 side. The light-blocking layer 157 can be provided in a region between adjacent light-emitting devices (a region overlapping with the insulating layer 127), in the connection portion 140, and in the circuit 356. A variety of optical members can be arranged on the outer surface of the substrate 352.

A material that can be used for the substrate 120 can be used for the substrate 351 and the substrate 352.

A material that can be used for the resin layer 122 can be used for the adhesive layer 142.

As the connection layer 242, an anisotropic conductive film (ACF), an anisotropic conductive paste (ACP), or the like can be used.

### [Light-Emitting Apparatus 100H]

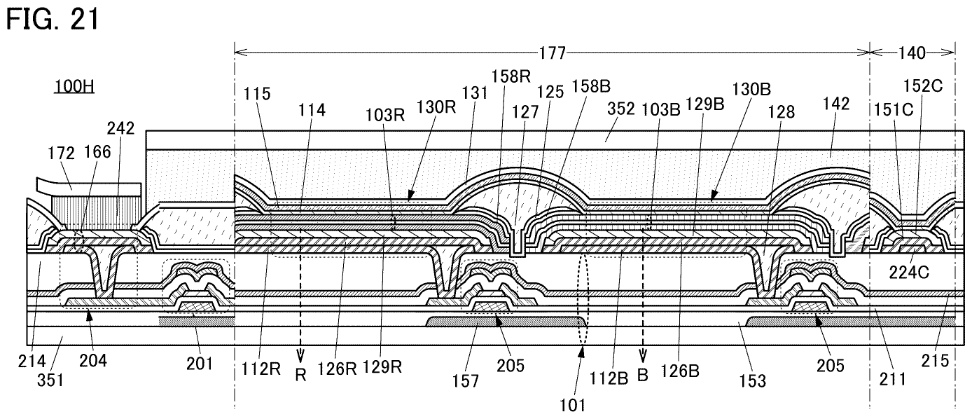

A light-emitting apparatus 100H illustrated in FIG. 21 is different from the light-emitting apparatus 100A illustrated in FIG. 20 mainly in being a bottom-emission light-emitting apparatus.

Light from the light-emitting device is emitted toward the substrate 351. For the substrate 351, a material having a high visible-light-transmitting property is preferably used. By contrast, there is no limitation on the light-transmitting property of a material used for the substrate 352.

The light-blocking layer 157 is preferably formed between the substrate 351 and the transistor 201 and between the substrate 351 and the transistor 205. FIG. 21 illustrates an example in which the light-blocking layer 157 is provided over the substrate 351, an insulating layer 153 is provided over the light-blocking layer 157, and the transistors 201 and 205 and the like are provided over the insulating layer 153.

The light-emitting device 130R includes a conductive layer 112R, a conductive layer 126R over the conductive layer 112R, and a conductive layer 129R over the conductive layer 126R.

The light-emitting device 130B includes a conductive layer 112B, a conductive layer 126B over the conductive layer 112B, and a conductive layer 129B over the conductive layer 126B.

A material having a high visible-light-transmitting property is used for each of the conductive layer 112R, the conductive layer 112B, the conductive layer 126R, the conductive layer 126B, the conductive layer 129R, and the conductive layer 129B. A material that reflects visible light is preferably used for the common electrode 155.

Although not illustrated in FIG. 21, the light-emitting device 130G is also provided.

Although FIG. 21 and the like illustrate an example in which the top surface of the layer 128 includes a flat portion, the shape of the layer 128 is not particularly limited.

### [Light-Emitting Apparatus 100C]

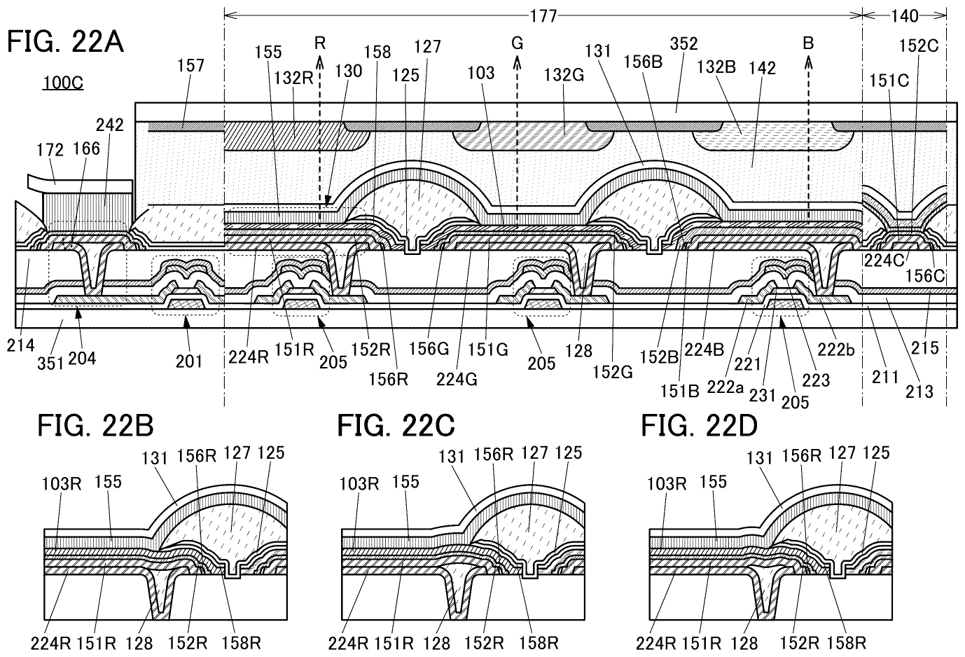

The light-emitting apparatus 100C illustrated in FIG. 22A is a modification example of the light-emitting apparatus 100B illustrated in FIG. 20A and differs from the light-emitting apparatus 100B mainly in including the coloring layer 132R, the coloring layer 132G, and the coloring layer 132B.

In the light-emitting apparatus 100C, the light-emitting device 130 includes a region overlapping with one of the coloring layer 132R, the coloring layer 132G, and the coloring layer 132B. The coloring layer 132R, the coloring layer 132G, and the coloring layer 132B can be provided on a surface of the substrate 352 on the substrate 351 side. The end portions of the coloring layer 132R, the coloring layer 132G, and the coloring layer 132B can overlap the light-blocking layer 157.

In the light-emitting apparatus 100C, the light-emitting device 130 can emit white light, for example. For example, the coloring layer 132R can transmit red light, the coloring layer 132G can transmit green light, and the coloring layer 132B can transmit blue light. Note that in the light-emitting apparatus 100C, the coloring layer 132R, the coloring layer 132G, and the coloring layer 132B may be provided between the protective layer 131 and the adhesive layer 142.

Although FIG. 20A, FIG. 21, and FIG. 22A illustrate an example where the top surface of the layer 128 includes a flat portion, there is no particular limitation on the shape of the layer 128. FIG. 22B to FIG. 22D illustrate variation examples of the layer 128.

As illustrated in FIG. 22B and FIG. 22D, the top surface of the layer 128 can have a shape such that its center and the vicinity thereof are recessed, i.e., a shape including a concave surface, in a cross-sectional view.

As illustrated in FIG. 22C, the top surface of the layer 128 can have a shape such that its center and the vicinity thereof bulge, i.e., a shape including a convex surface, in a cross-sectional view.

The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 224R may be the same or substantially the same, or may be different from each other. For example, the level of the top surface of the layer 128 may be either lower or higher than the level of the top surface of the conductive layer 224R.

FIG. 22B can be regarded as illustrating an example in which the layer 128 fits in the depressed portion of the conductive layer 224R. By contrast, as illustrated in FIG. 22D, the layer 128 may exist also outside the depressed portion of the conductive layer 224R, i.e., the top surface of the layer 128 may extend beyond the depressed portion.

This embodiment can be combined with the other embodiments as appropriate. In this specification, in the case where a plurality of structure examples are shown in one embodiment, the structure examples can be combined as appropriate.

### Embodiment 5

In this embodiment, electronic apparatuses of one embodiment of the present invention will be described.

Electronic apparatuses of this embodiment include the light-emitting apparatus of one embodiment of the present invention in their display portions. The light-emitting apparatus of one embodiment of the present invention is highly reliable and can be easily increased in resolution and definition. Thus, the display device of one embodiment of the present invention can be used for a display portion of a variety of electronic apparatuses.

Examples of electronic apparatuses include a digital camera, a digital video camera, a digital photo frame, a mobile phone, a portable game machine, a portable information terminal, and an audio reproducing device in addition to electronic apparatuses with a relatively large screen, such as a television device, a desktop or laptop personal computer, a monitor of a computer or the like, digital signage, and a large game machine like a pachinko machine.

In particular, the light-emitting apparatus of one embodiment of the present invention can have high resolution, and thus can be favorably used for an electronic apparatus having a relatively small display portion. Examples of such an electronic apparatus include watch-type and bracelet-type information terminal devices (wearable devices) and wearable devices worn on the head, such as a VR device like a head-mounted display, a glasses-type AR device, and an MR (Mixed Reality) device.

The definition of the light-emitting apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. The pixel density (resolution) of the light-emitting apparatus of one embodiment of the present invention is preferably higher than or equal to 100 ppi, further preferably higher than or equal to 300 ppi, still further preferably higher than or equal to 500 ppi, yet still further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a light-emitting apparatus having one or both of high definition and high resolution, the electronic apparatus can provide higher realistic sensation, sense of depth, and the like in personal use such as portable use and home use. There is no particular limitation on the screen ratio (aspect ratio) of the light-emitting apparatus of one embodiment of the present invention. For example, the light-emitting apparatus is compatible with a variety of screen ratios such as 1:1 (a square), 4:3, 16:9, and 16:10.

The electronic apparatus in this embodiment may include a sensor (a sensor having a function of measuring force, displacement, position, speed, acceleration, angular velocity, rotational frequency, distance, light (including infrared rays), liquid, magnetism, temperature, a chemical substance (including odor), sound, time, hardness, electric field, current, voltage, electric power, radiation, flow rate, humidity, gradient, or oscillation; alternatively, a sensor having a function of sensing or detecting odor or light, for example).

The electronic apparatus of this embodiment can have a variety of functions. For example, the electronic apparatus can have a function of displaying a variety of information (e.g., a still image, a moving image, and a text image) on the display portion, a touch panel function, a function of displaying a calendar, date, time, and the like, a function of executing a variety of software (programs), a wireless communication function, and a function of reading out a program or data stored in a recording medium.

### [Wearable Devices]

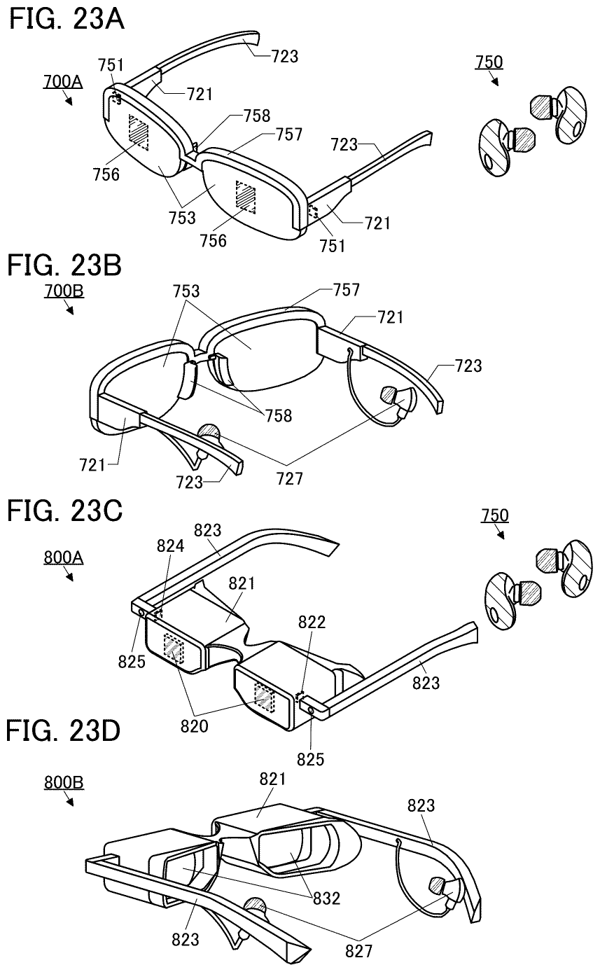

Examples of wearable devices capable of being worn on a head are described with reference to FIG. 23A to FIG. 23D. The wearable devices have at least one of a function of displaying AR contents, a function of displaying VR contents, a function of displaying SR (Substitutional Reality) contents, and a function of displaying MR contents. The electronic apparatus having a function of displaying contents of at least one of AR, VR, SR, and MR enables a user to feel a higher sense of immersion.

An electronic apparatus 700A shown in FIG. 23A and an electronic apparatus 700B shown in FIG. 23B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The light-emitting apparatus of one embodiment of the present invention can be used for the display panels 751. Thus, a highly reliable electronic apparatus is obtained.

The electronic apparatus 700A and the electronic apparatus 700B can each project an image displayed on the display panel 751 onto display regions 756 of the optical members 753. Since the optical members 753 have a light-transmitting property, a user can see images displayed on the display regions, which are superimposed on transmission images seen through the optical members 753. Accordingly, the electronic apparatus 700A and the electronic apparatus 700B are electronic apparatuses capable of AR display.

In the electronic apparatus 700A and the electronic apparatus 700B, a camera capable of capturing images of the front side may be provided as the image capturing portion. Furthermore, when the electronic apparatus 700A and the electronic apparatus 700B are provided with an acceleration sensor such as a gyroscope sensor, the orientation of the user's head can be sensed and an image corresponding to the orientation can be displayed on the display region 756.

The communication portion includes a wireless communication device, and a picture signal, for example, can be supplied by the wireless communication device. Note that instead of the wireless communication device or in addition to the wireless communication device, a connector to which a cable for supplying a video signal and a power supply potential can be connected may be provided.

The electronic apparatus 700A and the electronic apparatus 700B are provided with a battery so that they can be charged wirelessly and/or by wire.

A touch sensor module may be provided in the housing 721. The touch sensor module has a function of detecting touch on the outer surface of the housing 721. A tap operation, a slide operation, or the like by the user can be detected with the touch sensor module, whereby a variety of processing can be executed. For example, processing such as a pause or a restart of a moving image can be executed by a tap operation, and processing such as fast forward and fast rewind can be executed by a slide operation. The touch sensor module is provided in each of the two housings 721, whereby the range of the operation can be increased.

Any of various touch sensors can be applied to the touch sensor module. For example, any of touch sensors of the following types can be used: a capacitive type, a resistive type, an infrared type, an electromagnetic induction type, a surface acoustic wave type, and an optical type. In particular, a capacitive sensor or an optical sensor is preferably used for the touch sensor module.

In the case of using an optical touch sensor, a photoelectric conversion device (also referred to as a photoelectric conversion element) can be used as a light-receiving element. One or both of an inorganic semiconductor and an organic semiconductor can be used for an active layer of the photoelectric conversion device.

An electronic apparatus 800A illustrated in FIG. 23C includes a pair of display portions 820, a housing 821, a communication portion 822, a pair of wearing portions 823, a control portion 824, a pair of image capturing portions 825, and a pair of lenses 832 (not illustrated). Like the electronic apparatus 800A, an electronic apparatus 800B illustrated in FIG. 23D includes the pair of display portions 820 (not illustrated), the housing 821, the communication portion 822 (not illustrated), the pair of wearing portions 823, the pair of image capturing portions 825 (not illustrated), and the pair of lenses 832.

The light-emitting apparatus of one embodiment of the present invention can be used in the display portions 820. Thus, a highly reliable electronic apparatus is obtained.

The display portions 820 are provided at a position inside the housing 821 so as to be seen through the lenses 832. When the pair of display portions 820 display different images, three-dimensional display using parallax can be performed.

The electronic apparatus 800A and the electronic apparatus 800B can be regarded as electronic apparatuses for VR. The user who wears the electronic apparatus 800A or the electronic apparatus 800B can see images displayed on the display portions 820 through the lenses 832.

The electronic apparatus 800A and the electronic apparatus 800B preferably include a mechanism for adjusting the lateral positions of the lenses 832 and the display portions 820 so that the lenses 832 and the display portions 820 are positioned optimally in accordance with the positions of the user's eyes. Moreover, the electronic apparatus 800A and the electronic apparatus 800B each preferably include a mechanism for adjusting focus by changing the distance between the lenses 832 and the display portions 820.

The electronic apparatus 800A or the electronic apparatus 800B can be mounted on the user's head with the wearing portions 823. FIG. 23C illustrates an example in which the wearing portions 823 have a shape like a temple (also referred to as a joint or the like) of glasses; however, one embodiment of the present invention is not limited thereto. The wearing portions 823 can have any shape with which the user can wear the electronic apparatus, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided so as to support a plurality of fields of view, such as a telescope field of view and a wide field of view.

Although an example where the image capturing portion 825 is provided is shown here, a range sensor (hereinafter also referred to as a sensing portion) capable of measuring a distance between the user and an object just needs to be provided. That is, the image capturing portion 825 is one embodiment of the sensing portion. As the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic apparatus 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy video and sound only by wearing the electronic apparatus 800A.

The electronic apparatus 800A and the electronic apparatus 800B may each include an input terminal. To the input terminal, a cable for supplying a video signal from a video output device or the like, power for charging a battery provided in the electronic apparatus, and the like can be connected.

The electronic apparatus of one embodiment of the present invention may have a function of performing wireless communication with earphones 750. The earphones 750 include a communication portion (not illustrated) and have a wireless communication function. The earphones 750 can receive information (e.g., audio data) from the electronic apparatus with the wireless communication function. For example, the electronic apparatus 700A in FIG. 23A has a function of transmitting information to the earphones 750 with the wireless communication function. As another example, the electronic apparatus 800A in FIG. 23C has a function of transmitting information to the earphones 750 with the wireless communication function.

The electronic apparatus may include an earphone portion. The electronic apparatus 700B in FIG. 23B includes earphone portions 727. For example, the earphone portion 727 and the control portion can be connected to each other by wire. Part of a wiring that connects the earphone portions 727 and the control portion may be positioned inside the housing 721 or the wearing portions 723.

Similarly, the electronic apparatus 800B in FIG. 23D includes earphone portions 827. For example, the earphone portion 827 and the control portion 824 can be connected to each other by wire. Part of a wiring that connects the earphone portions 827 and the control portion 824 may be positioned inside the housing 821 or the wearing portions 823. Alternatively, the earphone portions 827 and the wearing portions 823 may include magnets. This is preferable because the earphone portions 827 can be fixed to the wearing portions 823 with magnetic force and thus can be easily housed.

The electronic apparatus may include an audio output terminal to which earphones, headphones, or the like can be connected. The electronic apparatus may include one or both of an audio input terminal and an audio input mechanism. As the audio input mechanism, a sound collecting device such as a microphone can be used, for example. The electronic apparatus may have a function of what is called a headset by including the audio input mechanism.

As described above, both the glasses-type device (e.g., the electronic apparatus 700A and the electronic apparatus 700B) and the goggles-type device (e.g., the electronic apparatus 800A and the electronic apparatus 800B) are preferable as the electronic apparatus of one embodiment of the present invention.

The electronic apparatus of one embodiment of the present invention can transmit information to earphones by wire or wirelessly.

### [Portable Information Terminal]

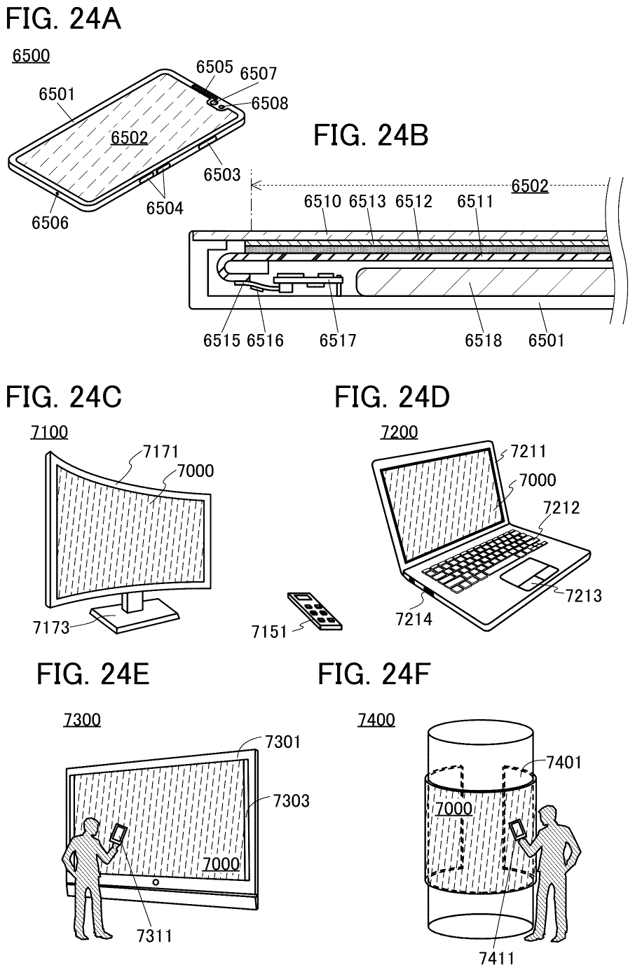

An electronic apparatus 6500 shown in FIG. 24A is a portable information terminal that can be used as a smartphone.

The electronic apparatus 6500 includes a housing 6501, a display portion 6502, a power button 6503, buttons 6504, a speaker 6505, a microphone 6506, a camera 6507, and a light source 6508. The display portion 6502 has a touch panel function.

The light-emitting apparatus of one embodiment of the present invention can be used in the display portion 6502. Thus, a highly reliable electronic apparatus can be obtained.

FIG. 24B is a schematic cross-sectional view including an end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic apparatus can be achieved. Since the display panel 6511 is extremely thin, the battery 6518 with high capacity can be mounted while an increase in thickness of the electronic apparatus is reduced. Moreover, part of the display panel 6511 is folded back so that a connection portion with the FPC 6515 is provided on the back side of a pixel portion, whereby an electronic apparatus with a narrow bezel can be achieved.

### [Television Device]

FIG. 24C shows an example of a television device. In a television device 7100, a display portion 7000 is incorporated in a housing 7171. Here, the housing 7171 is supported by a stand 7173.

The light-emitting apparatus of one embodiment of the present invention can be used in the display portion 7000. Thus, a highly reliable electronic apparatus is obtained.

Operation of the television device 7100 illustrated in FIG. 24C can be performed with an operation switch provided in the housing 7171 and a separate remote control 7151. Alternatively, the display portion 7000 may include a touch sensor, and the television device 7100 may be operated by touch on the display portion 7000 with a finger or the like. The remote control 7151 may be provided with a display portion for displaying information output from the remote control 7151. With operation keys or a touch panel provided in the remote control 7151, channels and volume can be controlled and videos displayed on the display portion 7000 can be operated.

Note that the television device 7100 has a structure in which a receiver and a modem are provided. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

### [Personal Computer]

FIG. 24D shows an example of a laptop personal computer. A laptop personal computer 7200 includes a housing 7211, a keyboard 7212, a pointing device 7213, an external connection port 7214, and the like. In the housing 7211, the display portion 7000 is incorporated.

The light-emitting apparatus of one embodiment of the present invention can be used in the display portion 7000. Thus, a highly reliable electronic apparatus is obtained.

### [Digital Signage]

FIG. 24E and FIG. 24F show examples of digital signage.

Digital signage 7300 shown in FIG. 24E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 24F is digital signage 7400 attached to a cylindrical pillar 7401. The digital signage 7400 includes the display portion 7000 provided along a curved surface of the pillar 7401.

The light-emitting apparatus of one embodiment of the present invention can be used in the display portion 7000 illustrated in each of FIG. 24E and FIG. 24F. Thus, a highly reliable electronic apparatus is obtained.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 24E and FIG. 24F, it is preferable that the digital signage 7300 or the digital signage 7400 be capable of working with an information terminal 7311 or an information terminal 7411 such as a smartphone the user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with the use of the screen of the information terminal 7311 or the information terminal 7411 as an operation means (controller). Thus, an unspecified number of users can join in and enjoy the game concurrently.

### [Watch-Type Terminal]

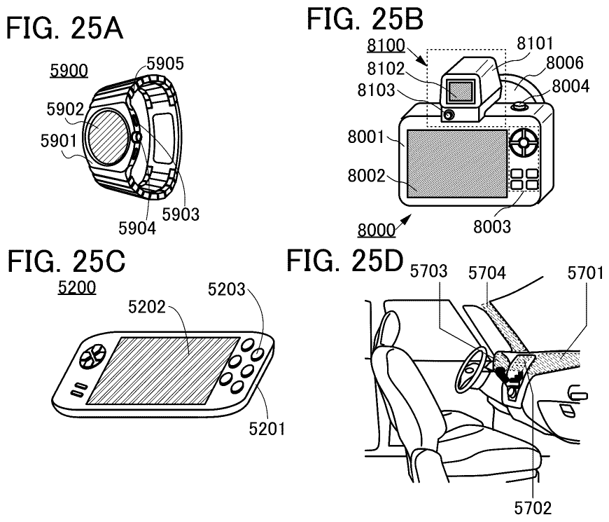

FIG. 25A is an external view of a watch-type information terminal 5900 that is an example of a wearable terminal. The information terminal 5900 includes a housing 5901, a display portion 5902, an operation button 5903, a crown 5904, and a band 5905.

The light-emitting apparatus described in the above embodiment can be applied to the display portion 5902. Thus, the display portion 5902 can visually display functions of a watch, a stop watch, a timer, and the like.

The information terminal 5900 can be used, for example, as an auxiliary tool for the electronic apparatus 6500 such as the smartphone in FIG. 24A. For example, with a structure which enables wireless communication between the information terminal 5900 and the electronic apparatus 6500, an e-mail received by the smartphone, a notification of an SNS, or the like can be displayed on the information terminal 5900.

### [Camera]

FIG. 25B is an external view of a camera 8000 to which a finder 8100 is attached. The camera 8000 includes a housing 8001, a display portion 8002, operation buttons 8003, and a shutter button 8004. In addition, a detachable lens 8006 is attached to the camera 8000. The finder 8100 includes a housing 8101, a display portion 8102, and a button 8103.

Note that the lens 8006 and the housing may be integrated with each other in the camera 8000.

The camera 8000 can take images by the press of the shutter button 8004 or touch on the display portion 8002 functioning as a touch panel.

The housing 8001 includes a mount including an electrode, so that a stroboscope, for example, as well as the finder 8100 can be connected to the housing. Note that the light-emitting apparatus described in the above embodiment may be used as the stroboscope.

The housing 8101 is attached to the camera 8000 with the mount engaging with a mount of the camera 8000. In the finder 8100, a video received from the camera 8000 can be displayed on the display portion 8102.

The button 8103 has a function of a power button.

The display apparatus of one embodiment of the present invention can be used for the display portion 8002 of the camera 8000 and the display portion 8102 of the finder 8100. Note that a finder may be incorporated in the camera 8000.

### [Game Machines]

FIG. 25C is a diagram illustrating the appearance of a portable game machine 5200 which is an example of a game machine. The portable game machine 5200 includes a housing 5201, a display portion 5202, and a button 5203.

An image displayed on the portable game machine 5200 can be output with a display apparatus included in a television device, a personal computer display, a game display, or a head-mounted display.

The portable game machine 5200 with low power consumption can be provided by applying the light-emitting apparatus described in the above embodiment to the portable game machine 5200. Moreover, heat generation from a circuit can be reduced owing to low power consumption; thus, the influence of heat generation on the circuit, a peripheral circuit, and a module can be reduced.

Although FIG. 25C illustrates the portable game machine as an example of a game machine, the electronic apparatus of one embodiment of the present invention is not limited thereto. Examples of the electronic apparatus of one embodiment of the present invention include a stationary game machine, an arcade game machine installed in entertainment facilities (e.g., a game center and an amusement park), and a throwing machine for batting practice installed in sports facilities.

### [Moving Vehicle]

The display apparatus of one embodiment of the present invention can be used around a driver's seat in a car, which is a moving vehicle.

FIG. 25D illustrates a windshield and its vicinity inside a car. FIG. 25D shows a display panel 5701, a display panel 5702, and a display panel 5703 which are attached to a dashboard, and a display panel 5704 attached to a pillar.

The display panel 5701 to the display panel 5703 can display a variety of kinds of information such as navigation information, a speedometer, a tachometer, a mileage, a fuel meter, a gearshift indicator, and air-condition settings, for example. The display content and layout displayed on the display panels can be changed appropriately to suit the user's preferences, so that the design can be improved. The display panel 5701 to the display panel 5703 can also be used as lighting devices.

The display panel 5704 can compensate for the view obstructed by the pillar (blind areas) by showing a video taken by an imaging unit provided for the car body. That is, showing an image taken by an imaging unit provided on the outside of the car body leads to elimination of blind areas and enhancement of safety. In addition, displaying an image to complement a portion that cannot be seen makes it possible for the driver to confirm the safety more naturally and comfortably. The display panel 5704 can also be used as a lighting device.

The display apparatus of one embodiment of the present invention can be used for the display panel 5701 to the display panel 5704, for example.

Although the car is described above as an example of a moving vehicle, the moving vehicle is not limited to a car. Examples of moving vehicles include a train, a monorail train, a ship, and a flying object (e.g., a helicopter, an unmanned aircraft (a drone), an airplane, and a rocket), and these moving vehicles can include the light-emitting apparatus of one embodiment of the present invention.

### [Electronic Apparatus Including Light-Emitting Apparatus Having Flexibility]

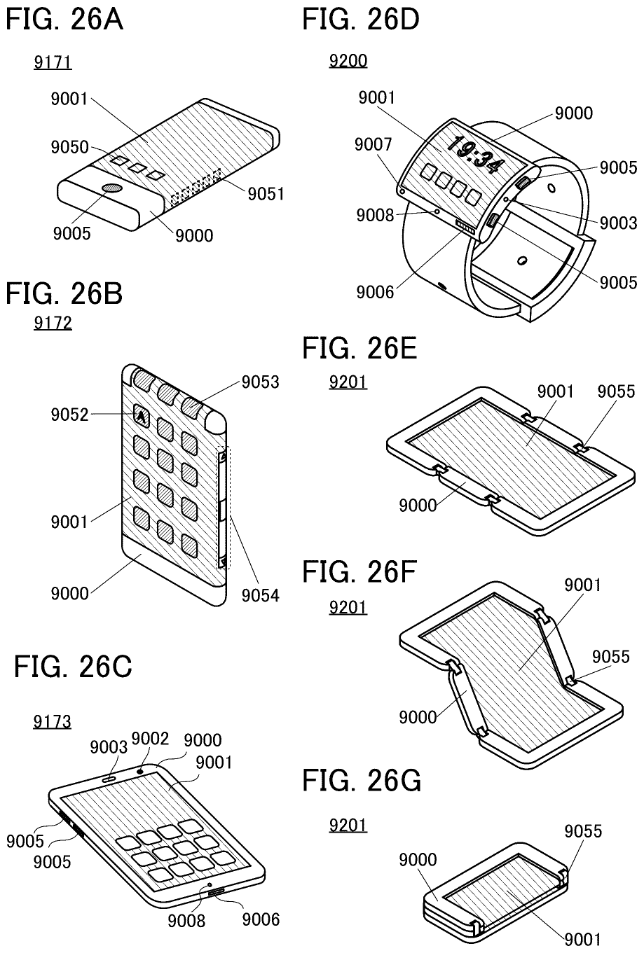

Electronic apparatuses illustrated in FIG. 26A to FIG. 26G include a housing 9000, a display portion 9001, a speaker 9003, operation buttons 9005 (including a power switch or an operation switch), a connection terminal 9006, a sensor 9007 (a sensor having a function of measuring force, displacement, position, speed, acceleration, angular velocity, rotational frequency, distance, light (including infrared rays), liquid, magnetism, temperature, a chemical substance (including odor), sound, time, hardness, electric field, current, voltage, electric power, radiation, flow rate, humidity, gradient, or oscillation; alternatively, a sensor having a function of sensing or detecting odor or light, for example), and a microphone 9008.

Note that a light-emitting apparatus provided with a light-emitting device over a flexible substrate is used for the display portion 9001 of each of the electronic apparatuses illustrated in FIG. 26A to FIG. 26G, for example. Examples of the flexible substrate include a plastic substrate. Examples of the plastic include polyethylene terephthalate (PET), polyethylene naphthalate (PEN), polyether sulfone (PES), and polytetrafluoroethylene (PTFE). Other examples of the flexible substrate include a substrate using a synthetic resin such as an acrylic resin. Other examples of the flexible substrate include a substrate using polypropylene, polyester, polyvinyl fluoride, or polyvinyl chloride as a material. Other examples of the flexible substrate include a substrate using polyamide, polyimide, aramid, an epoxy resin, an inorganic vapor deposition film, or paper as a material.

The electronic apparatuses illustrated in FIG. 26A to FIG. 26G have a variety of functions. For example, the electronic apparatuses can have a function of displaying a variety of information (a still image, a moving image, a text image, and the like) on the display portion, a touch panel function, a function of displaying a calendar, date, time, and the like, a function of controlling processing with use of a variety of software (programs), a wireless communication function, and a function of reading out and processing a program or data stored in a recording medium. Note that the functions of the electronic apparatuses are not limited thereto, and the electronic apparatuses can have a variety of functions. The electronic apparatuses may each include a plurality of display portions. The electronic apparatuses may each be provided with a camera or the like and have a function of taking a still image or a moving image and storing the taken image in a storage medium (an external storage medium or a storage medium incorporated in the camera), a function of displaying the taken image on the display portion, or the like.

The details of the electronic apparatuses illustrated in FIG. 26A to FIG. 26G are described below.

FIG. 26A is a perspective view illustrating a portable information terminal 9171. For example, the portable information terminal 9171 can be used as a smartphone. Note that the portable information terminal 9171 may include the speaker 9003, the connection terminal 9006, and the sensor 9007. The portable information terminal 9171 can display characters and image information on its plurality of surfaces. FIG. 26A illustrates an example where three icons 9050 are displayed. Furthermore, information 9051 indicated by dashed rectangles can be displayed on another surface of the display portion 9001. Examples of the information 9051 include notification of reception of an e-mail, an SNS, an incoming call, or the like. Other examples include the title and sender of an e-mail or an SNS, the date, the time, remaining battery, and the radio field intensity. Alternatively, the icon 9050 or the like may be displayed at the position where the information 9051 is displayed.

FIG. 26B is a perspective view illustrating a portable information terminal 9172. The portable information terminal 9172 has a function of displaying information on three or more surfaces of the display portion 9001. Here, an example in which information 9052, information 9053, and information 9054 are displayed on different surfaces is shown. For example, a user can check the information 9053 displayed in a position that can be observed from above the portable information terminal 9172, with the portable information terminal 9172 put in a breast pocket of his/her clothes. The user can see the display without taking out the portable information terminal 9172 from the pocket and decide whether to answer the call, for example.

FIG. 26C is a perspective view illustrating a tablet terminal 9173. The tablet terminal 9173 is capable of executing a variety of applications such as mobile phone calls, e-mailing, viewing and editing texts, music reproduction, Internet communication, and a computer game. The tablet terminal 9173 includes the display portion 9001, a camera 9002, the microphone 9008, and the speaker 9003 on the front surface of the housing 9000; the operation buttons 9005 as buttons for operation on a side surface of the housing 9000; and the connection terminal 9006 on the bottom surface of the housing 9000. In the case where the tablet terminal 9173 does not need to be folded, the substrate of the light-emitting apparatus used for the display portion 9001 does not necessarily have flexibility.

FIG. 26D is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 26E to FIG. 26G are perspective views illustrating a foldable portable information terminal 9201. FIG. 26E is a perspective view of an opened state of the portable information terminal 9201, FIG. 26G is a perspective view of a folded state thereof, and FIG. 26F is a perspective view of a state in the middle of change from one of FIG. 26E and FIG. 26G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate. In this specification, in the case where a plurality of structure examples are shown in one embodiment, the structure examples can be combined as appropriate.

### REFERENCE NUMERALS

100A: light-emitting apparatus, 100B: light-emitting apparatus, 100C: light-emitting apparatus, 100H: light-emitting apparatus, 101a: anode, 101b: anode, 101: anode, 102a: cathode, 102b: cathode, 102: cathode, 103a: organic compound layer, 103B: organic compound layer, 103b: organic compound layer, 103Bf: organic compound film, 103G: organic compound layer, 103Gf: organic compound film, 103R: organic compound layer, 103Rf: organic compound film, 103: organic compound layer, 104: common layer, 110B: subpixel, 110G: subpixel, 110R: subpixel, 110W: subpixel, 110: subpixel, 111a: hole-injection layer, 111b: hole-injection layer, 111: hole-injection layer, 112: hole-transport layer, 112a: hole-transport layer, 112b: hole-transport layer, 112B: conductive layer, 112R: conductive layer, 113: light-emitting layer, 113a: light-emitting layer, 113b: light-emitting layer, 114: electron-transport layer, 114a: electron-transport layer, 114b: electron-transport layer, 115: electron-injection layer, 116a: layer, 116b: layer, 116: layer, 117a: charge-generation region, 117b: charge-generation region, 117: charge-generation region, 118a: electron-relay region, 118b: electron-relay region, 118: electron-relay region, 119a: electron-injection buffer region, 119b: electron-injection buffer region, 119: electron-injection buffer region, 120: substrate, 122: resin layer, 124a: pixel, 124b: pixel, 125f: inorganic insulating film, 125: inorganic insulating layer, 126B: conductive layer, 126R: conductive layer, 127a: insulating layer, 127f: insulating film, 127: insulating layer, 128: layer, 129B: conductive layer, 129R: conductive layer, 130A: light-emitting device, 130a: light-emitting device, 130aUSD: light-emitting device, 130bUSD: light-emitting device, 130aA: light-emitting device, 130aAUSD: light-emitting device, 130bAUSD: light-emitting device, 130B: light-emitting device, 130b: light-emitting device, 130bA: light-emitting device, 130G: light-emitting device, 130R: light-emitting device, 130USD: light-emitting device, 130USDA: light-emitting device, 130: light-emitting device, 131: protective layer, 132B: coloring layer, 132G: coloring layer, 132R: coloring layer, 140: connection portion, 141: region, 142: adhesive layer, 1511: conductive layer, 151_2: conductive layer, 151_3: conductive layer, 151B: conductive layer, 151C: conductive layer, 151f: conductive film, 151G: conductive layer, 151R: conductive layer, 151: conductive layer, 152_1: conductive layer, 152_2: conductive layer, 152_3: conductive layer, 152B: conductive layer, 152C: conductive layer, 152f: conductive film, 152G: conductive layer, 152R: conductive layer, 152: conductive layer, 153: insulating layer, 155: common electrode, 156B: insulating layer, 156C: insulating layer, 156f: insulating film, 156G: insulating layer, 156R: insulating layer, 156: insulating layer, 157: light-blocking layer, 158B: sacrificial layer, 158Bf: sacrificial film, 158G: sacrificial layer, 158Gf: sacrificial film, 158R: sacrificial layer, 158Rf: sacrificial film, 158: sacrificial layer, 159B: mask layer, 159Bf: mask film, 159G: mask layer, 159Gf: mask film, 159R: mask layer, 159Rf: mask film, 166: conductive layer, 171: insulating layer, 172: conductive layer, 173: insulating layer, 174: insulating layer, 175: insulating layer, 176: plug, 177: pixel portion, 178: pixel, 179: conductive layer, 190B: resist mask, 190G: resist mask, 190R: resist mask, 191: resist mask, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 224B: conductive layer, 224C: conductive layer, 224G: conductive layer, 224R: conductive layer, 225: insulating layer, 231i: channel formation region, 231n: low-resistance region, 231: semiconductor layer, 240: capacitor, 241: conductive layer, 242: connection layer, 243: insulating layer, 245: conductive layer, 254: insulating layer, 255: insulating layer, 256: plug, 261: insulating layer, 271: plug, 280: display module, 281: display portion, 282: circuit portion, 283a: pixel circuit, 283: pixel circuit portion, 284a: pixel, 284: pixel portion, 285: terminal portion, 286: wiring portion, 290: FPC, 291: substrate, 292: substrate, 301: substrate, 310: transistor, 311: conductive layer, 312: low-resistance region, 313: insulating layer, 314: insulating layer, 315: element isolation layer, 351: substrate, 352: substrate, 353: FPC, 354: IC, 355: wiring, 356: circuit, 501a: light-emitting unit, 501b: light-emitting unit, 501: light-emitting unit, 700A: electronic apparatus, 700B: electronic apparatus, 721: housing, 723: wearing portion, 727: earphone portion, 750: earphone, 751: display panel, 753: optical member, 756: display region, 757: frame, 758: nose pad, 800A: electronic apparatus, 800B: electronic apparatus, 820: display portion, 821: housing, 822: communication portion, 823: wearing portion, 824: control portion, 825: image capturing portion, 827: earphone portion, 832: lens, 1000: light-emitting apparatus, 5201: housing, 5202: display portion, 5203: button, 5701: display panel, 5702: display panel, 5703: display panel, 5704: display panel, 5901: housing, 5902: display portion, 5903: operation button, 6500: electronic apparatus, 6501: housing, 6502: display portion, 6503: power button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7151: remote control, 7171: housing, 7173: stand, 7200: laptop personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 8000: camera, 8001: housing, 8002: display portion, 8003: operation button, 8006: lens, 8101: housing, 8102: display portion, 8103: button, 9000: housing, 9001: display portion, 9002: camera, 9003: speaker, 9005: operation button, 9006: connection terminal, 9007: sensor, 9008: microphone, 9050: icon, 9051: information, 9052: information, 9053: information, 9054: information, 9055: hinge, 9171: portable information terminal, 9172: portable information terminal, 9173: tablet terminal, 9200: portable information terminal, 9201: portable information terminal

1. A light-emitting device comprising:
a light-emitting layer, a first layer, and a second layer between an anode and a cathode,
wherein the light-emitting layer is provided between the anode and the first layer,
wherein the second layer is provided between the first layer and the cathode,
wherein the light-emitting layer comprises a light-emitting substance,
wherein the first layer is a mixed layer comprising a first organic compound and a second organic compound,
wherein the first organic compound has strong basicity with pKₐ greater than or equal to 8,
wherein the second organic compound has an electron-transport property,
wherein a LUMO level of the first organic compound is higher than a LUMO level of the second organic compound, and
wherein the second layer comprises a first hole-transport organic compound and a first material having an acceptor property with respect to the first hole-transport organic compound.

2. A light-emitting device comprising:
a light-emitting layer, a first layer, a second layer, and a third layer between an anode and a cathode,
wherein the light-emitting layer is provided between the anode and the first layer,
wherein the second layer is provided between the first layer and the cathode,
wherein the third layer is provided between the first layer and the second layer,
wherein the light-emitting layer comprises a light-emitting substance,
wherein the first layer is a mixed layer comprising a first organic compound and a second organic compound,
wherein the first organic compound has strong basicity with pKₐ greater than or equal to 8,
wherein the second organic compound has an electron-transport property,
wherein a LUMO level of the first organic compound is higher than a LUMO level of the second organic compound,
wherein the second layer comprises a first hole-transport organic compound and a first material having an acceptor property with respect to the first hole-transport organic compound, and
wherein the third layer comprises a material having a LUMO level higher than or equal to −4.30 eV and lower than or equal to −3.00 eV.

3. The light-emitting device according to claim 1,
wherein a HOMO level of the first organic compound is higher than a HOMO level of the second organic compound.

4. The light-emitting device according to claim 1,
wherein the second layer is a mixed layer of the first hole-transport organic compound and the first material.

5. The light-emitting device according to claim 1,
wherein the second layer is a stack of a layer comprising the first hole-transport organic compound and a layer comprising the first material.

6. The light-emitting device according to claim 5 comprising:
the layer comprising the first hole-transport organic compound between the layer comprising the first material and the cathode.

7. The light-emitting device according to claim 12,
wherein the second layer and the cathode are in contact with each other.

8. The light-emitting device according to claim 1,
wherein the second organic compound has a π-electron deficient heteroaromatic ring.

9. The light-emitting device according to claim 1, comprising a fourth layer between the anode and the light-emitting layer,
wherein the fourth layer comprises a second hole-transport organic compound and a second material having an acceptor property with respect to the second hole-transport organic compound.

10. The light-emitting device according to claim 1,
wherein the first organic compound has a higher LUMO level than the second organic compound by 0.05 eV or more.

11. The light-emitting device according to claim 1,
wherein the first organic compound has a higher LUMO level than the second organic compound by 0.05 eV or more, and the first organic compound has a higher HOMO level than the second organic compound by 0.05 eV or more.

12. The light-emitting device according to claim 1,
wherein the LUMO level of the first organic compound is higher than or equal to −2.50 eV and lower than or equal to −1.00 eV.

13. The light-emitting device according to claim 1,
wherein the LUMO level of the first organic compound is higher than or equal to −2.50 eV and lower than or equal to −1.00 eV, and
wherein a HOMO level of the first organic compound is higher than or equal to −5.7 eV and lower than or equal to −4.8 eV.

14. The light-emitting device according to claim 1,
wherein the LUMO level of the first organic compound is higher than or equal to −2.50 eV and lower than or equal to −1.00 eV, and
wherein the LUMO level of the second organic compound is higher than or equal to −3.25 eV and lower than or equal to −2.50 eV.

15. The light-emitting device according to claim 1,
wherein the LUMO level of the first organic compound is higher than or equal to −2.50 eV and lower than or equal to −1.00 eV,
wherein the LUMO level of the second organic compound is higher than or equal to −3.25 eV and lower than or equal to −2.50 eV,
wherein a HOMO level of the first organic compound is higher than or equal to −5.7 eV and lower than or equal to −4.8 eV, and
wherein a HOMO level of the second organic compound is higher than or equal to −6.5 eV and lower than or equal to −5.7 eV.

16. The light-emitting device according to claim 1,
wherein the second organic compound is a material having basicity with an acid dissociation constant pKₐ greater than or equal to 4 and less than or equal to 8.

17. The light-emitting device according to claim 1,
wherein the first organic compound does not have an electron-donating property with respect to the second organic compound.

18. The light-emitting device according to claim 1,
wherein the mixed layer comprising the first organic compound and the second organic compound has spin density lower than or equal to 1×10¹⁷ spins/cm³ measured by an electron spin resonance method.
